(19) United States
(12) Patent Application Publication
(10) Pub. No.: US 2026/0198178 A1
(43) Pub. Date: Jul. 9, 2026

(54) ELECTRONIC DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Hajime KIMURA, Atsugi, Kanagawa (JP); Atsushi MIYAGUCHI, Hadano, Kanagawa (JP); Yoshiaki OIKAWA, Atsugi, Kanagawa (JP)

(21) Appl. No.: 19/132,899

(22) PCT Filed: Nov. 27, 2023
(86) PCT No.: PCT/IB2023/061898

§ 371 Date: May 27, 2025

(30) Foreign Application Priority Data
Dec. 2, 2022 (JP) 2022-193246
Jan. 26, 2023 (JP) 2023-010421

(51) Int. Cl. H10K 59/121; G04G 17/04; G09G 3/3233

(52) U.S. Cl. CPC H10K 59/1213; G09G 3/3233; G04G 17/045; G09G 2300/0426; G09G 2300/0852; G09G 2310/08; G09G 2330/021

(57) ABSTRACT

An electronic device with a novel structure is provided. The electronic device includes a semiconductor device, and the semiconductor device has a structure where a first element layer, a second element layer, and a third element layer are stacked. The first element layer includes a first transistor that includes a semiconductor layer containing silicon in a channel formation region. The second element layer includes a second transistor that includes a semiconductor layer containing a metal oxide in a channel formation region. The third element layer includes a light-emitting device. The first element layer includes an arithmetic circuit including a scan flip-flop. The second element layer includes a backup circuit electrically connected to the scan flip-flop and a pixel circuit electrically connected to the light-emitting device.

### TECHNICAL FIELD

In this specification, an electronic device, a display system including the electronic device, a semiconductor device included in the electronic device, and the like are described.

Note that one embodiment of the present invention is not limited to the above technical field. Examples of the technical field of one embodiment of the present invention disclosed in this specification and the like include a semiconductor device, a display apparatus, a light-emitting apparatus, a power storage device, a storage device, an electronic device, a lighting device, an input device, an input/output device, a driving method thereof, and a manufacturing method thereof.

### BACKGROUND ART

Wearable electronic devices that perform mobile communication or the like have been widely used. For example, an arm-worn electronic device may include a variety of sensors, a CPU for controlling the sensors, a memory for storing data, and the like in addition to a display (e.g., see Patent Document 1).

In such electronic devices, techniques for improving the performance of the semiconductor devices have been actively developed to process a large volume of data at high speed. As a technique for achieving high performance, what is called an SoC (System on Chip) is given in which an accelerator such as a GPU (Graphics Processing Unit) and a CPU (Central Processing Unit) are tightly coupled.

Furthermore, there has been a proposal for an integrated structure of a display device and a semiconductor device adopting an SoC incorporating CPU or the like (see Patent Document 2, for example). In an electronic device including a semiconductor device having higher performance by adopting an SoC, heat generation of the CPU and an increase in power consumption become problems. Thus, power gating or the like is performed by saving data of a scan flip-flop of the CPU in a backup circuit, whereby a structure in which an increase in power consumption and heat generation are inhibited without a lowering in performance becomes effective.

### REFERENCE

### Patent Document

[Patent Document 1] PCT International Publication No. 2016/036472
[Patent Document 2] PCT International Publication No. 2022/118141

### SUMMARY OF THE INVENTION

### Problems to be Solved by the Invention

A semiconductor device with performance improved by adopting an SoC is constructed with transistors in stacked element layers so that downsizing and higher performance are achieved. In order to achieve higher performance, an increase in the number of element layers to be stacked becomes a problem. Furthermore, with an increase in the number of element layers to be stacked, power consumption becomes a problem. Performance improvement of the semiconductor device and demand for an increase in power consumption or downsizing of the semiconductor device have a trade-off relationship. That is, it has been difficult to achieve both performance improvement of the semiconductor device and reduction in power consumption or size of the semiconductor device.

An object of one embodiment of the present invention is to provide a novel electronic device and the like. Another object of one embodiment of the present invention is to provide an electronic device and the like with a novel structure which include a semiconductor device having higher performance by adopting an SoC and which enables a reduction in size of the semiconductor device. Another object of one embodiment of the present invention is to provide an electronic device and the like with a novel structure which include a semiconductor device having higher performance by adopting an SoC and in which heat generation and an increase in power consumption can be inhibited. Another object of one embodiment of the present invention is to provide an electronic device and the like with a novel structure in which both performance improvement of a semiconductor device and reduction in power consumption or heat generation of the semiconductor device can be achieved. Another object of one embodiment of the present invention is to provide an electronic device and the like with a novel structure that are highly convenient.

The description of a plurality of objects does not preclude the existence of each object. One embodiment of the present invention does not need to achieve all the objects described as examples. Furthermore, objects other than those listed are apparent from description of this specification, and such objects can be objects of one embodiment of the present invention.

### Means for Solving the Problems

One embodiment of the present invention is an electronic device including a semiconductor device that has a structure where a first element layer, a second element layer, and a third element layer are stacked. The first element layer includes a first transistor including a semiconductor layer containing silicon in a channel formation region; the second element layer includes a second transistor including a semiconductor layer containing a metal oxide in a channel formation region; and the third element layer includes a light-emitting device. The first element layer includes an arithmetic circuit including a scan flip-flop, and the second element layer includes a backup circuit electrically connected to the scan slip-flop and a pixel circuit electrically connected to the light-emitting device.

One embodiment of the present invention is an electronic device including a semiconductor device that has a structure where a first element layer, a second element layer, and a third element layer are stacked. The first element layer includes a first transistor including a semiconductor layer containing silicon in a channel formation region; the second element layer includes a second transistor including a semiconductor layer containing a metal oxide in a channel formation region; and the third element layer includes a light-emitting device. The first element layer includes an arithmetic circuit including a scan flip-flop and a first driver circuit for driving a pixel circuit electrically connected to the light-emitting device. The second element layer includes a backup circuit electrically connected to the scan flip-flop, the pixel circuit, and a second driver circuit for driving the pixel circuit.

One embodiment of the present invention is an electronic device including a semiconductor device that has a structure where a first element layer, a second element layer, a third element layer, and a fourth element layer are stacked. The first element layer includes a first transistor including a semiconductor layer containing silicon in a channel formation region; the second element layer includes a second transistor including a first semiconductor layer containing a metal oxide in a channel formation region; the third element layer includes a third transistor including a second semiconductor layer containing a metal oxide in a channel formation region; and the fourth element layer includes a light-emitting device. The first element layer includes an arithmetic circuit including a scan flip-flop and a first driver circuit for driving a pixel circuit electrically connected to the light-emitting device. The second element layer includes a backup circuit electrically connected to the scan flip-flop and a second driver circuit for driving the pixel circuit. The third element layer includes the pixel circuit.

In the electronic device of any of the embodiments of the present invention, the backup circuit preferably has a function of retaining data stored in the scan flip-flop in a state where supply of power supply voltage is stopped when the arithmetic circuit is in a non-activated state.

In the electronic device of any of the embodiments of the present invention, the second transistor and the third transistor preferably have different shapes from each other.

In the electronic device of any of the embodiments of the present invention, the second transistor and the third transistor preferably have different channel lengths and different channel widths from each other.

In the electronic device of any of the embodiments of the present invention, the metal oxide preferably contains In, Ga, and Zn.

Note that other embodiments of the present invention will be shown in the description of the following embodiments and the drawings.

### Effect of the Invention

One embodiment of the present invention can provide an electronic device and the like with a novel structure. Another embodiment of the present invention can provide an electronic device and the like with a novel structure which include a semiconductor device having performance improved by adopting an SoC and which enables a reduction in size of the semiconductor device. Another embodiment of the present invention can provide an electronic device and the like with a novel structure which include a semiconductor device having performance improved by adopting an SoC and which can inhibit heat generation and an increase in power consumption. Another embodiment of the present invention can provide an electronic device and the like with a novel structure in which both performance improvement of a semiconductor device and reduction in power consumption or heat generation of the semiconductor device can be achieved. Another embodiment of the present invention can provide an electronic device and the like with a novel structure that is highly convenient.

The description of a plurality of effects does not preclude the existence of other effects. In addition, one embodiment of the present invention does not necessarily achieve all the effects described as examples. In one embodiment of the present invention, other objects, effects, and novel features are apparent from the description of this specification and the drawings.

### BRIEF DESCRIPTION OF THE DRAWINGS

FIG. 1A and FIG. 1B are diagrams illustrating a structure example of a semiconductor device.

FIG. 2 is a diagram illustrating a structure example of a semiconductor device.

FIG. 3 is a diagram illustrating a structure example of a semiconductor device.

FIG. 4A and FIG. 4B are diagrams illustrating a structure example of a semiconductor device.

FIG. 5 is a timing chart illustrating a structure example of a semiconductor device.

FIG. 6A and FIG. 6B are diagrams illustrating a structure example of a semiconductor device.

FIG. 7A and FIG. 7B are diagrams illustrating a structure example of a semiconductor device.

FIG. 8A and FIG. 8B are diagrams illustrating a structure example of a semiconductor device.

FIG. 9 is a diagram illustrating a structure example of a semiconductor device.

FIG. 10 is a diagram illustrating a structure example of a semiconductor device.

FIG. 11 is a diagram illustrating a structure example of a semiconductor device.

FIG. 12A to FIG. 12C are diagrams illustrating a structure example of a transistor.

FIG. 13A to FIG. 13C are diagrams illustrating a structure example of a transistor.

FIG. 14A and FIG. 14B are schematic cross-sectional views illustrating a structure example of a transistor.

FIG. 15A and FIG. 15B are schematic cross-sectional views each illustrating a structure example of a transistor.

FIG. 16A is a schematic top view illustrating a structure example of a semiconductor device. FIG. 16B to FIG. 16D are schematic cross-sectional views illustrating the structure example of the semiconductor device.

FIG. 17A and FIG. 17B are circuit diagrams illustrating structure examples of a semiconductor device.

FIG. 18 is a layout diagram illustrating a structure example of a semiconductor device.

FIG. 19 is a circuit diagram illustrating a configuration example of a semiconductor device.

FIG. 20A to FIG. 20D are circuit diagrams each illustrating a configuration example of a pixel circuit.

FIG. 21A and FIG. 21B are circuit diagrams each illustrating a configuration example of a pixel circuit.

FIG. 22A and FIG. 22B are circuit diagrams each illustrating a configuration example of a pixel circuit.

FIG. 23 is a circuit diagram illustrating a configuration example of a pixel circuit.

FIG. 24 is a schematic cross-sectional view illustrating a structure example of a semiconductor device.

FIG. 25A to FIG. 25C are schematic cross-sectional views each illustrating a structure example of a semiconductor device.

FIG. 26 is a schematic cross-sectional view illustrating a structure example of a semiconductor device.

FIG. 27 is a schematic cross-sectional view illustrating a structure example of a semiconductor device.

FIG. 28 is a schematic cross-sectional view illustrating a structure example of a semiconductor device.

FIG. 29 is a schematic cross-sectional view illustrating a structure example of a semiconductor device.

FIG. 30 is a schematic cross-sectional view illustrating a structure example of a semiconductor device.

FIG. 31A is a schematic top view illustrating a structure example of a semiconductor device. FIG. 31B to FIG. 31D are schematic cross-sectional views illustrating a structure example of a semiconductor device.

FIG. 32 is a schematic cross-sectional view illustrating a structure example of a semiconductor device.

FIG. 33 is a schematic cross-sectional view illustrating a structure example of a semiconductor device.

FIG. 34 is a schematic cross-sectional view illustrating a structure example of a semiconductor device.

FIG. 35 is a schematic cross-sectional view illustrating a structure example of a semiconductor device.

FIG. 36 is a schematic cross-sectional view illustrating a structure example of a semiconductor device.

FIG. 37A and FIG. 37B are diagrams illustrating a structure example of a display module.

FIG. 38A to FIG. 38E are diagrams illustrating structure examples of an electronic device.

FIG. 39A to FIG. 39G are structure examples of electronic devices.

### MODE FOR CARRYING OUT THE INVENTION

Embodiments will be described below with reference to the drawings. The embodiments can be implemented with many different modes, and it will be readily appreciated by those skilled in the art that modes and details can be changed in various ways without departing from the spirit and scope thereof. Thus, the present invention should not be interpreted as being limited to the following description of the embodiments.

In the drawings, the size, the layer thickness, or the region is sometimes exaggerated for clarity. Therefore, the size, the layer thickness, or the region is not limited to the illustrated scale. Note that the drawings schematically illustrate ideal examples, and embodiments of the present invention are not limited to shapes, values, and the like illustrated in the drawings.

Furthermore, unless otherwise specified, off-state current in this specification and the like refers to drain current of a transistor in an OFF state (also referred to as a non-conduction state or a cutoff state). Unless otherwise specified, an off state in an n-channel transistor refers to a state where a voltage V_{gs} between its gate and source is lower than a threshold voltage Vₜₕ (in a p-channel transistor, higher than Vₜₕ).

In this specification and the like, a metal oxide is an oxide of a metal in a broad sense. Metal oxides are classified into an oxide insulator, an oxide conductor (including a transparent oxide conductor), an oxide semiconductor (also simply referred to as OS), and the like. For example, in the case where a metal oxide is used for an active layer of a transistor, the metal oxide is referred to as an oxide semiconductor in some cases. That is, in the case where an OS transistor is stated, the OS transistor can also be referred to as a transistor including a metal oxide or an oxide semiconductor.

### Embodiment 1

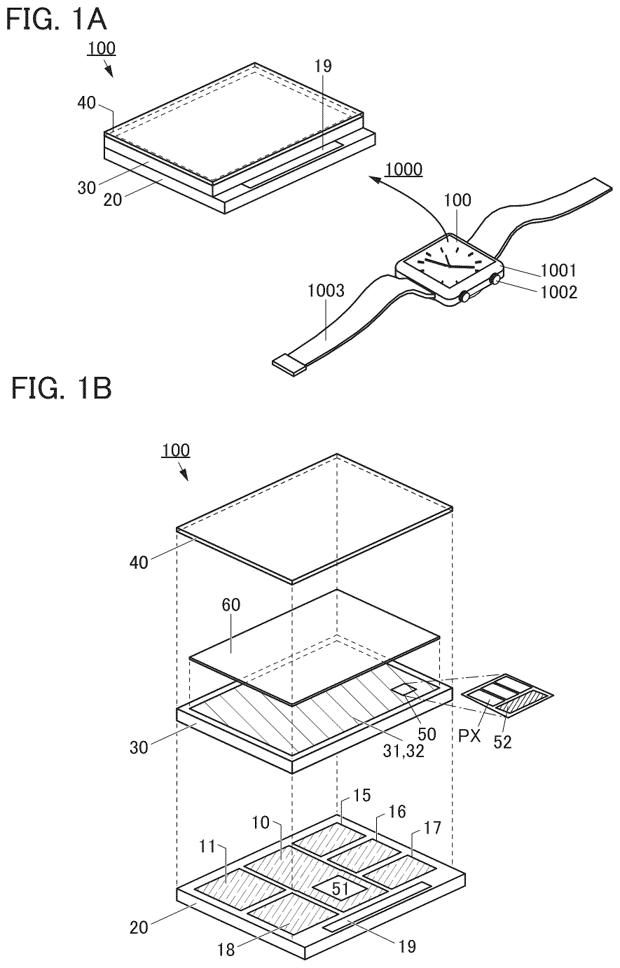

Structure examples of a semiconductor device included in an electronic device according to one embodiment of the present invention will be described with reference to FIG. 1A to FIG. 11.

### <Structure Example 1 of Semiconductor Device>

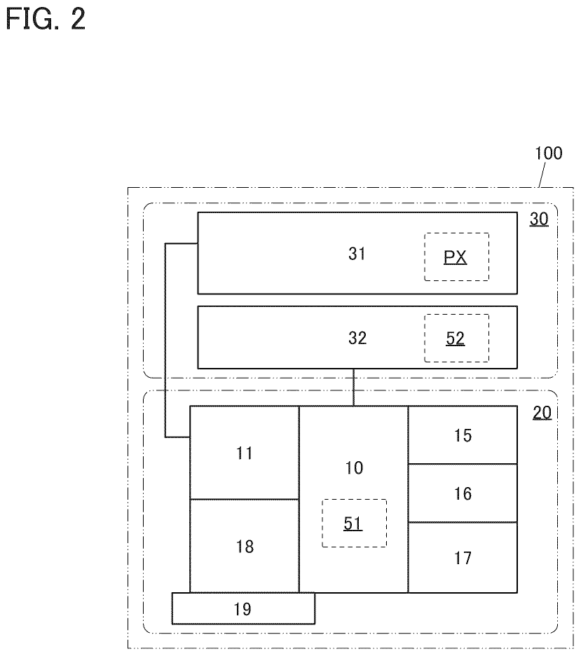

FIG. 1A is a perspective view of a semiconductor device 100 included in an electronic device 1000 according to one embodiment of the present invention. FIG. 1B is a perspective view illustrating a structure of the semiconductor device 100. FIG. 2 is a block diagram illustrating a structure of the semiconductor device.

The electronic device 1000 illustrated in FIG. 1A is a watch-type electronic device. In the electronic device 1000, the semiconductor device 100 is incorporated in a housing 1001 provided with an operation portion 1002 and a band 1003. The electronic device 1000 has a structure in which a battery, a sensor (not illustrated), and the like are incorporated as well as the semiconductor device 100. Note that the electronic device 1000 illustrated in FIG. 1A has a function of what is called a Smartwatch (registered trademark).

The electronic device 1000 capable of adopting the semiconductor device 100 can be potentially configured as a display portion for an information terminal such as a smartphone, a laptop PC, or a tablet PC, besides Smartwatch or a bracelet-type information terminal (wearable terminal); a wearable device capable of being worn on a head, such as a device for VR, like a head-mounted display, and a glasses-type device for AR; or the like.

The semiconductor device 100 illustrated in FIG. 1A includes an element layer 30 over an element layer 20 and a sealing substrate 40 over the element layer 30. An element layer 60 (not illustrated) is provided between the sealing substrate 40 and the element layer 30. In the semiconductor device 100 illustrated in FIG. 1B, the element layer 20, the element layer 30, the element layer 60, the sealing substrate 40, and the like, which are illustrated in FIG. 1A, are apart from each other.

As illustrated in FIG. 1A and FIG. 1B, the element layer 20 includes a terminal portion 19. As illustrated in FIG. 1B, the element layer 20 includes an arithmetic circuit 10 and a driver circuit 11 in a region overlapping with the element layer 30. FIG. 1B also illustrates a sensor circuit 15, a communication circuit 16, a control circuit 17, and an input/output circuit 18 as examples of functional circuits included in the element layer 20.

Note that the functional circuit included in the element layer 20 does not necessarily include all of the circuits, and may include another component. For example, the functional circuit may include a power supply circuit and/or a power management circuit for controlling power supply disruption. The functional circuit may also include DSP (Digital Signal Processor) and/or FPGA (Field Programmable Gate Array), for example. The functional circuit may also include a super-resolution circuit or the like, for example. The super-definition circuit has a function of upconverting image data with a lower definition than that of the display portion. The super-definition circuit has a function of downconverting image data with a higher definition than that of the display portion.

The arithmetic circuit 10, the driver circuit 11, and other functional circuits included in the element layer 20 are preferably formed using Si CMOS, that is, transistors containing silicon in their channel formation regions (Si transistors). In other words, the element layer 20 is a layer including Si transistors. When the element layer 20 is formed using Si transistors, circuits required to operate at high speed, such as the arithmetic circuit 10 and the driver circuit 11, can be provided in the element layer 20.

For the Si transistors, the use of silicon having high crystallinity, such as single crystal silicon or polycrystalline silicon, is particularly preferable because high field-effect mobility can be achieved and higher-speed operation is possible.

The element layer 30 is a layer including an OS transistor, i.e., a transistor containing an oxide semiconductor in a channel formation region. With this structure, the element layer 30 including OS transistors can be stacked over the element layer 20. The element layer 30 includes a plurality of regions 50. In the region 50, a pixel circuit PX and a backup circuit 52 are provided.

The pixel circuit PX is a circuit for driving a light-emitting device provided in the element layer 60 over the element layer 30 so that display in a display portion 31 is controlled. The pixel circuit PX correspond to a pixel circuit included in each subpixel for performing color display. The element layer 60 over the pixel circuit PX is provided with a light-emitting element (not illustrated).

An OS transistor has a characteristic of an extremely low off-state current. Thus, when the OS transistor is used as a transistor provided in the pixel circuit PX, image data written to the pixel circuit PX can be retained for a long period. Thus, the frequency of image data rewriting can be reduced, and power consumption can be reduced.

The backup circuit 52 has a function of retaining electric charge for a long time. The backup circuit 52 is electrically connected to a plurality of scan flip-flops 51 included in the arithmetic circuit 10. The backup circuit 52 can retain electric charge corresponding to data retained in the scan flip-flop 51. The backup circuit 52 can be a circuit functioning as a memory having a function of retaining electric charge for a long time when the OS transistor is turned off. When being formed using OS transistors, the backup circuit 52 can be provided in the element layer 30 where the pixel circuit PX is placed. When the display portion 31 and a storage portion 32 are placed in the same layer, the storage portion 32 can be placed utilizing a region of the element layer 30 where the display portion 31 is not provided. With this structure, the storage portion 32 can be placed to fill a region where the display portion 31 is not provided in the element layer 30. Thus, the backup circuit 52 in the storage portion 32 can be placed without reducing the display quality, e.g., without narrowing the area of the display portion 31.

In the element layer 30, the pixel circuit PX is provided in the display portion 31, and the backup circuit 52 is provided in the storage portion 32. In a block diagram illustrated in FIG. 2, the display portion 31 including the pixel circuit PX and the storage portion 32 including the backup circuit 52 are illustrated. FIG. 1B illustrates a state where a region including the pixel circuits PX and the backup circuit 52 is placed in the entire element layer 30. Thus, in FIG. 1B, the display portion 31 and the storage portion 32 are illustrated to be in the same region. With this structure, the area of the display portion 31 and the area of the storage portion 32 can be large, so that the layout flexibility of the pixel circuit PX and the backup circuit 52 can be increased.

Note that although the display portion 31 and the storage portion 32 are illustrated to be in the same region in FIG. 1B, they may be arranged in different regions. Specifically, the backup circuit 52 provided in the region 50 in FIG. 1B may be provided outside the region 50. Alternatively, the display portion 31 and the storage portion 32 may be placed separately in different layers that are a plurality of element layers 30. With this structure, the display portion 31 and the storage portion 32 can be placed to overlap with each other as the pixel circuit arrangement, and the density per unit area can be increased.

The element layer 60 includes a light-emitting device (not illustrated) such as an organic EL element. Light emission of the light-emitting device is controlled by the pixel circuits PX included in the subpixels for performing color display. Thus, the element layer 60 can also be regarded as part of the display portion 31. Note that three subpixels each control the amount or the like of red light, green light, or blue light. Note that the emission colors controlled by the three subpixels are not limited to a combination of red (R), green (G), and blue (B) and may be cyan (C), magenta (M), and yellow (Y). In addition, the three subpixels do not necessarily have the same area size. In the case where luminous efficiency, reliability, or the like varies depending on the emission color, the subpixel area size may be changed depending on the emission color.

Note that in the following description, the light-emitting device is not limited to an organic EL element and can be a self-luminous light-emitting device such as an LED (light emitting diode), a micro LED, a QLED (quantum-dot light-emitting diode), or a semiconductor laser.

In this specification and the like, the term “element” can be replaced with the term “device” in some cases. For example, a display element and a light-emitting element can be rephrased as a display device and a light-emitting device, respectively.

The arithmetic circuit 10 is a circuit having a function of performing arithmetic processing. The arithmetic circuit 10 corresponds to a circuit that processes image data, such as a CPU or a GPU. The arithmetic circuit 10 includes a CPU core and a cache memory, for example. A CPU core included in the arithmetic circuit 10 includes the scan flip-flop 51. The scan flip-flop 51 has a function of retaining data included in the arithmetic circuit 10 and sequentially outputting the data in response to a clock signal or the like. The scan flip-flop 51 has a structure electrically connected to the backup circuit 52 provided in the element layer 30. With this structure, data included in the scan flip-flop 51 can be output (backed up) to the backup circuit 52, and data retained in the backup circuit 52 can be input (recovered) to the scan flip-flop 51.

Note that the scan flip-flop 51 in arithmetic circuit 10 is composed of a circuit including a transistor which includes a semiconductor layer containing silicon in a channel formation region (Si transistor), that is, Si CMOS. Meanwhile, the backup circuit 52 includes an OS transistor. The backup circuit 52 including the OS transistor can function as memory having a function of retaining electric charge for a long time when the OS transistor is in an off state. When the semiconductor device 100 has such a structure that the backup circuit 52 is provided to be electrically connected to the scan flip-flop 51 in the arithmetic circuit 10, sleep power of the electronic device 1000 in a sleep mode (power consumed during a non-display period) can be significantly reduced, so that convenience can be increased even with a small amount of battery capacity.

When the storage portion 32 including the backup circuit 52 is provided in the element layer 30 and the scan flip-flop 51 included in the arithmetic circuit 10 is provided in the element layer 20, the backup circuit 52 and the scan flip-flop 51 can be placed to overlap with each other. When the arithmetic circuit 10 and the storage portion 32 are provided to overlap with each other, the connection distance (wiring length) between the arithmetic circuit 10 and the storage portion 32 can be extremely shortened. As a result, the wiring resistance and the parasitic capacitance are reduced, and thus time taken for charging and discharging can be reduced and high-speed driving of data transmission and reception can be achieved. Moreover, power consumption can be reduced. Furthermore, the size and weight of the electronic device can be reduced.

The driver circuit 11 is electrically connected to the display portion 31 included in the element layer 30 and has a function of supplying image data and a selection signal to the display portion 31. A driver circuit for supplying a selection signal to the display portion 31 is referred to as a gate driver circuit or a scan line driver circuit in some cases. A driver circuit for supplying image data to the display portion 31 is referred to as a source driver circuit or a signal line driver circuit in some cases. For the driver circuit 11, any of a variety of circuits such as a shift register, a level shifter, an inverter, a latch, an analog switch, or a logic circuit can be used as a functional circuit.

The sensor circuit 15 has a function of obtaining information on one or more of the senses of sight, hearing, touch, taste, and smell of a human. Specifically, the sensor circuit 15 has at least one of functions of sensing or measuring force, displacement, position, speed, acceleration, angular velocity, rotational frequency, distance, light, magnetism, temperature, sound, time, electric field, current, voltage, electric power, radiation, humidity, gradient, oscillation, a smell, and infrared rays. The sensor circuit 15 may have a function other than those functions.

The communication circuit 16 has a wireless or wired communication function. In particular, the communication circuit 16 preferably has a wireless communication function, in which case the number of parts such as a connection cable can be decreased.

In the case where the communication circuit 16 has a wireless communication function, the communication circuit 16 can perform communication via an antenna. As a communication protocol or a communication technology, a communication standard such as LTE (Long Term Evolution), GSM (Global System for Mobile Communication: registered trademark), EDGE (Enhanced Data Rates for GSM Evolution), CDMA2000 (Code Division Multiple Access 2000), or W-CDMA (registered trademark), or an IEEE communication standard such as Wi-Fi (registered trademark), Bluetooth (registered trademark), or ZigBee (registered trademark) can be used.

The communication circuit 16 can perform input/output of information by connecting the semiconductor device 100 to another device via a computer network such as the Internet, which is an infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network).

The control circuit 17 has a function of controlling the operation of the functional circuits provided in the element layer 20 on the basis of a signal from a circuit processing image data, such as the arithmetic circuit 10.

The input/output circuit 18 has a function of distributing signals supplied to the semiconductor device 100 through the terminal portion 19 to the circuits such as the control circuit 17. In addition, the input/output circuit 18 has a function of distributing signals supplied to the semiconductor device 100 through the communication circuit 16 to the circuits such as the control circuit 17.

The input/output circuit 18 has a function of outputting signals to the outside through the terminal portion 19. The input/output circuit 18 has function of outputting signals to the outside through the communication circuit 16.

An FPC (Flexible printed circuits) or the like is electrically connected to the terminal portion 19. Thus, the element layer 30 and the sealing substrate 40 are not formed in a region overlapping with the terminal portion 19.

In the electronic device 1000 including the semiconductor device 100 illustrated in FIG. 1A, other electronic components such as a battery and a sensor as well as the semiconductor device 100 are stored in a limited volume of the housing 1001. In the semiconductor device 100, the backup circuit 52 is provided to be electrically connected to the scan flip-flop 51 in the arithmetic circuit 10, whereby power gating of the arithmetic circuit 10 can be achieved. Thus, the sleep power of the electronic device 1000 in a sleep mode (power consumed during a non-display period) can be significantly reduced; thus, the convenience of the electronic device 1000 can be increased even with a small amount of battery capacity.

### <Structure Example of Arithmetic Circuit 10>

An example of the arithmetic circuit 10 including a CPU core capable of power gating is described.

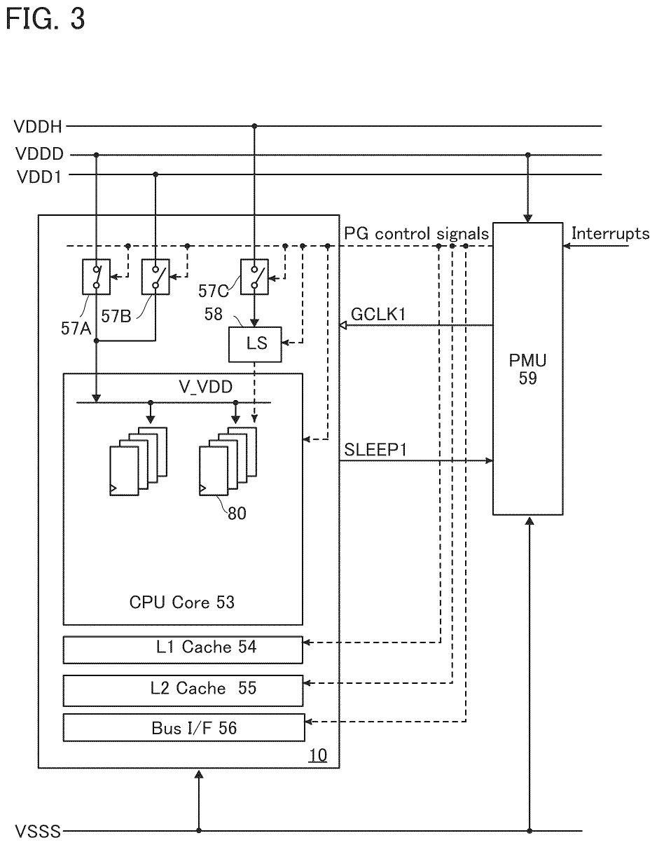

FIG. 3 illustrates a configuration example of the arithmetic circuit 10. The arithmetic circuit 10 includes the CPU core 53, an L1 (level 1) cache memory device (L1 Cache) 54, an L2 cache memory device (L2 Cache) 55, a bus interface portion (Bus I/F) 56, power switches 57A to 57C, and a level shifter (LS) 58. The CPU core 53 includes a flip-flop 80.

Through the bus interface portion 56, the CPU core 53, the L1 cache memory device 54, and the L2 cache memory device 55 are mutually connected to one another in the arithmetic circuit 10 illustrated in FIG. 3.

A PMU (Power Management Unit) 59 illustrated in FIG. 3 generates a clock signal GCLK1 and a variety of PG (power gating) control signals in response to signals such as an interrupt signal (Interrupts) input from the outside and a signal SLEEP1 output from the arithmetic circuit 10. The clock signal GCLK1 and the PG control signal are input to the arithmetic circuit 10. The PG control signal controls the power switches 57A to 57C and the flip-flop 80.

The power switches 57A and 57B illustrated in FIG. 3 control supply of voltages VDDD and VDD1 to a virtual power supply line V_VDD (hereinafter referred to as a V_VDD line), respectively. The power switch 57C controls the supply of the voltage VDDH to the V_VDD line. Voltage VSSS is input to the arithmetic circuit 10 and the PMU 59 without passing through the power switches. The voltage VDDD is input to the PMU 59 without passing through the power switches.

The voltages VDDD and VDD1 illustrated in FIG. 3 are drive voltages for a CMOS circuit included in the arithmetic circuit 10. The voltage VDD1 is lower than the voltage VDDD and is drive voltage in a sleep mode. The voltage VDDH is drive voltage for an OS transistor of the backup circuit 52 and is higher than the voltage VDDD.

The L1 cache memory device 54, the L2 cache memory device 55, and the bus interface portion 56, illustrated in FIG. 3, each include at least one power domain capable of power gating. The power domain capable of power gating is provided with one or more power switches. These power switches are controlled by the PG control signal.

The flip-flop 80 illustrated in FIG. 3 has a structure including the scan flip-flop connected to the backup circuit. The flip-flop 80 is described below.

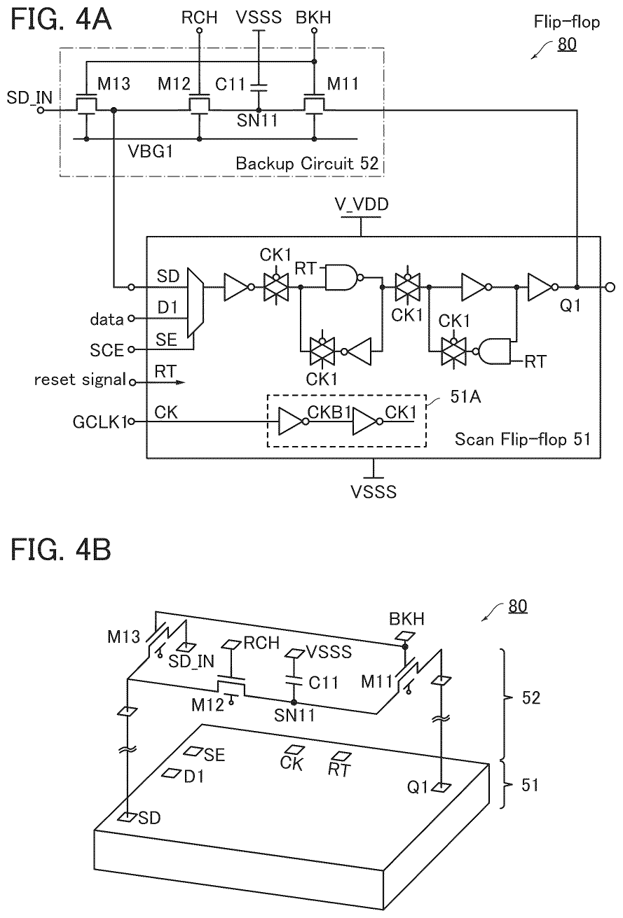

FIG. 4A shows a circuit configuration example of the flip-flop (Flip-flop) 80. The flip-flop 80 includes the scan flip-flop 51 and the backup circuit (Backup Circuit) 52.

The scan flip-flop 51 illustrated in FIG. 4A includes nodes D1, Q1, SD, SE, RT, and CK and a clock buffer circuit 51A.

The node D1 illustrated in FIG. 4A is a data input node, the node Q1 is a data output node, and the node SD is a scan test data input node. The node SE is a signal SCE input node. The node CK is a clock signal GCLK1 input node. The clock signal GCLK1 is input to the clock buffer circuit 51A. Respective analog switches in the scan flip-flop 51 are connected to nodes CK1 and CKB1 of the clock buffer circuit 51A. The node RT is a reset signal input node.

The signal SCE illustrated in FIG. 4A is a scan enable signal, which is generated in the PMU 59. The PMU 59 generates signals BK and RC. A level shifter 58 level-shifts the signals BK and RC to generate signals BKH and RCH. The signals BK and RC are a backup signal and a recovery signal.

The circuit configuration of the scan flip-flop 51 is not limited to that in FIG. 4A. A flip-flop prepared in a standard circuit library can be employed.

The backup circuit 52 illustrated in FIG. 4A includes a node SD_IN and a node SN11, transistors M11 to M13, and a capacitor C11.

The node SD_IN illustrated in FIG. 4A is a scan test data input node and is connected to the node Q1 of the scan flip-flop 51. The node SN11 is a retention node of the backup circuit 52. The capacitor C11 is a storage capacitor for retaining the voltage of the node SN11.

The transistor M11 illustrated in FIG. 4A controls electrical continuity between the node Q1 and the node SN11. The transistor M12 controls electrical continuity between the node SN11 and the node SD. The transistor M13 controls electrical continuity between the node SD_IN and the node SD. The on/off states of the transistors M11 and M13 are controlled by a signal BKH, and the on/off state of the transistor M12 is controlled by a signal RCH.

The transistors M11 to M13 illustrated in FIG. 4A are OS transistors, like transistors included in the pixel circuit PX. The transistors M11 to M13 have back gates in the illustrated structure. In the illustrated example, the back gates of the transistors M11 to M13 are connected to a power supply line for supplying the voltage VBG1.

At least the transistors M11 and M12 provided in the element layer 30 are preferably OS transistors. Because of extremely low off-state current, which is a feature of the OS transistor, a decrease in the voltage of the node SN11 can be suppressed and almost no electric power is consumed to retain data; therefore, the backup circuit 52 has a nonvolatile characteristic. Data is rewritten by charging and discharging of the capacitor C11; hence, there is theoretically no limitation on rewrite cycles of the backup circuit 52, and data can be written and read out with low energy.

All of the transistors in the backup circuit 52 are extremely preferably OS transistors. The backup circuit 52 can be stacked over the scan flip-flop 51 formed with a silicon CMOS circuit.

The number of elements in the backup circuit 52 illustrated in FIG. 4A is much smaller than the number of elements in the scan flip-flop 51; hence, there is no need to change the circuit configuration and layout of the scan flip-flop 51 in order to stack the backup circuit 52. That is, the backup circuit 52 is a backup circuit that has very broad utility. In addition, the backup circuit 52 can be provided to overlap with a region where the scan flip-flop 51 is formed; thus, even when the backup circuit 52 is incorporated, the area overhead of the flip-flop 80 can be zero. Therefore, the backup circuit 52 is provided in the flip-flop 80, whereby power gating of the CPU core 53 is enabled. Since the less energy is necessary for the power gating, highly efficient power gating can be performed by the CPU core 53.

When the backup circuit 52 is provided, parasitic capacitance due to the transistor M11 is added to the node Q1. However, the parasitic capacitance is lower than parasitic capacitance generated by a logic circuit connected to the node Q1; therefore, there is no influence of the parasitic capacitance on the operation of the scan flip-flop 51. That is, even when the backup circuit 52 is provided, the performance of the flip-flop 80 does not substantially decrease.

The CPU core 53 can be set to be in a clock gating state, a power gating state, or a resting state as a low power consumption state (non-operation state). The PMU 59 selects the low power consumption mode of the CPU core 53 on the basis of the interrupt signal, the signal SLEEP1, and the like. For example, in the case of transition from a normal operation state to a clock gating state, the PMU 59 stops generation of the clock signal GCLK1.

For example, in the case of transition from a normal operation state to a resting state, the PMU 59 performs voltage and/or frequency scaling. For example, when the voltage scaling is performed, the PMU 59 turns off the power switch 57A and turns on the power switch 57B to input the voltage VDD1 to the CPU core 53. The voltage VDD1 is voltage at which data in the scan flip-flop 51 is not lost. When the frequency scaling is performed, the PMU 59 reduces the frequency of the clock signal GCLK1.

In the case where the CPU core 53 transitions from a normal operation state to a power gating state, data in the scan flip-flop 51 is backed up to the backup circuit 52. When the CPU core 53 is returned from the power gating state to the normal operation state, recovery operation of writing back data in the backup circuit 52 to the scan flip-flop 51 is performed.

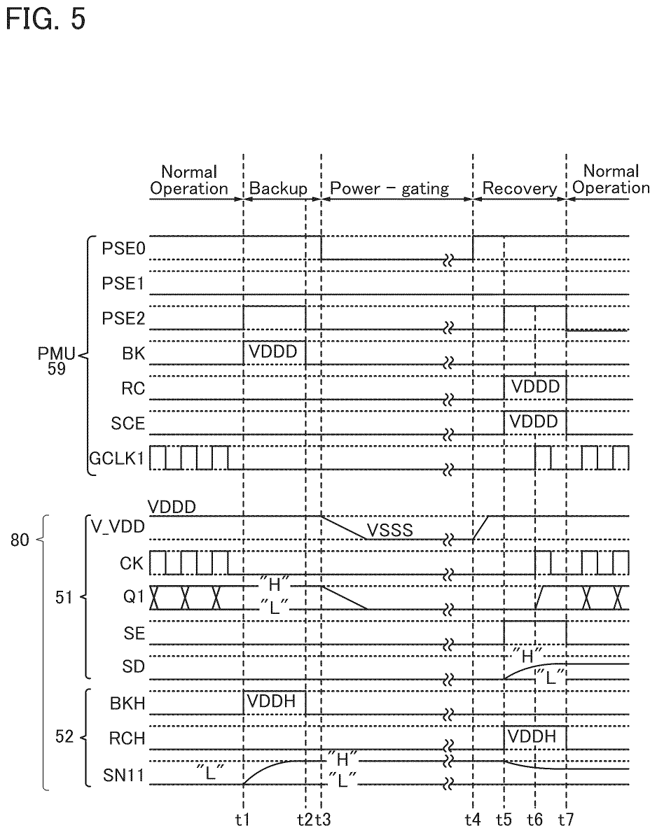

FIG. 5 illustrates an example of the power gating sequence of the CPU core 53. Note that in FIGS. 5, t1 to t7 represent the time. Signals PSE0 to PSE2 are control signals of the power switches 57A to 57C, which are generated in the PMU 59. When the signal PSE0 is at “H”/“L”, the power switches 57A to 57C are on/off. The same applies to the signals PSE1 and PSE2.

Before Time t1, the CPU core 53 is in the normal operating state (Normal Operation). The power switch 57A is on, and the voltage VDDD is input to the CPU core 53. The scan flip-flop 51 performs the normal operation. At this time, the level shifter 58 does not need to be operated; thus, the power switch 57C is off and the signals SCE, BK, and RC are each at “L”. The node SE is at “L”; thus, the scan flip-flop 51 stores data in the node D1. Note that in the example of FIG. 5, the node SN11 of the backup circuit 52 is at “L” at Time t1.

Backup operation is described. At Time t1 of operation, the PMU 59 stops the clock signal GCLK1 and sets the signals PSE2 and BK at “H”. The level shifter 58 becomes active and outputs the signal BKH at “H” to the backup circuit 52.

The transistor M11 in the backup circuit 52 is turned on, and data in the node Q1 of the scan flip-flop 51 is written to the node SN11 of the backup circuit 52. When the node Q1 of the scan flip-flop 51 is at “L”, the node SN11 remains at “L”, whereas when the node Q1 is at “H”, the node SN11 becomes “H”.

The PMU 59 sets the signals PSE2 and BK at “L” at Time 2 and sets the signal PSE0 at “L at Time t3. The state of the CPU core 53 transitions to a power gating state at Time t3. Note that at the timing when the signal BK falls, the signal PSE0 may fall.

Power-gating operation is described. When the signal PSE0 is set to “L, the data in the node Q1 is lost because the voltage of the V_VDD line decreases. The node SN11 keeps retaining the data in the node Q1 at Time t3.

Recovery operation is described. When the PMU 59 sets the signal PSE0 at “H” at Time t4, the power gating state transitions to a recovery state. Charging of the V_VDD line starts, and the PMU 59 sets the signals PSE2, RC, and SCE at “H” in a state where the voltage of the V_VDD line becomes VDDD (at Time t5).

The transistor M12 is turned on, and charge in the capacitor C11 is distributed to the node SN11 and the node SD. When the node SN11 is at “H”, the voltage of the node SD increases. The node SE is at “H”, and thus, data in the node SD is written to a latch circuit on the input side of the scan flip-flop 51. When the clock signal GCLK1 is input to the node CK at Time 6, data in the latch circuit on the input side is written to the node Q1. That is, data in the node SN11 is written to the node Q1.

When the PMU 59 sets the signals PSE2, SCE, and RC at “L” at Time t7, the recovery operation is terminated.

The backup circuit 52 using an OS transistor is extremely suitable for normally-off computing because both dynamic and static power consumption are low. Even when the flip-flop 80 is mounted, a decrease in the performance and an increase in the dynamic power of the CPU core 53 can be made hardly to occur.

Note that the CPU core 53 may include a plurality of power domains capable of power gating. In the plurality of power domains, one or more power switches for controlling voltage input are provided. In addition, the CPU core 53 may include one or more power domains where power gating is not performed. For example, the power domain where power gating is not performed may be provided with a power gating control circuit for controlling the flip-flop 80 and the power switches 57A to 57C.

Note that the application of the flip-flop 80 is not limited to the arithmetic circuit 10. In an arithmetic device, the flip-flop 80 can be used as a register provided in a power domain capable of power gating.

Accordingly, the arithmetic circuit 10 including the scan flip-flop electrically connected to the backup circuit 52 can retain data even when supply of power supply voltage is stopped.

Thus, the power gating of the arithmetic circuit 10 can be performed and power consumption can be reduced greatly. The backup circuit 52 can be provided to be stacked with a circuit including Si transistors, such as the scan flip-flop 51. Consequently, the backup circuit can be provided without increasing in the circuit area.

### <Structure Example 2 of Semiconductor Device>

Next, a variation of the semiconductor device which is different from the semiconductor device 100 with the above structure example is described. The repeated description of the components denoted by the same reference numerals as those in the above semiconductor device 100 is omitted in some cases.

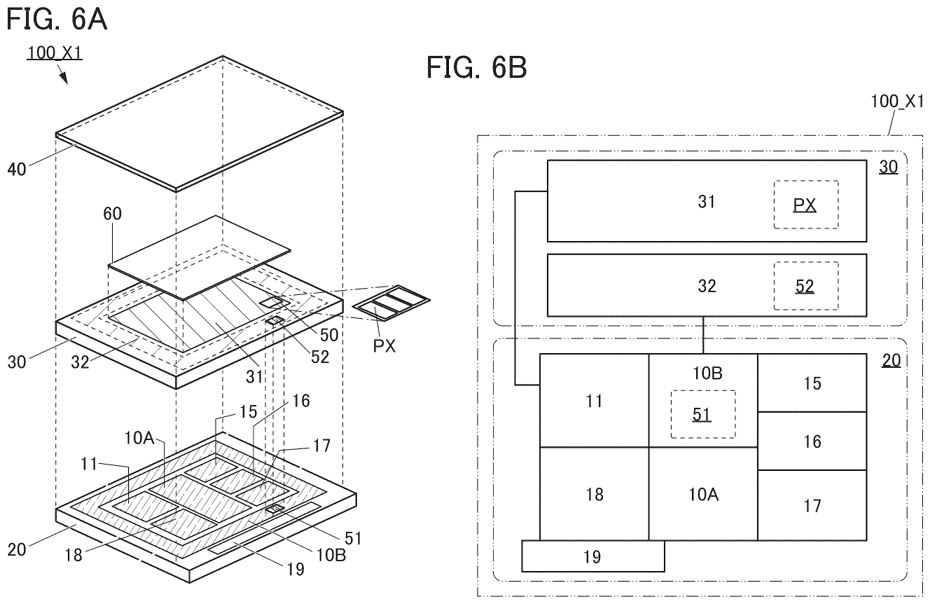

FIG. 6A is a perspective view for illustrating a structure of a semiconductor device 100_X1. FIG. 6B is a block diagram illustrating a structure of the semiconductor device 100_X1.

The semiconductor device 100_X1 illustrated in FIG. 6A and FIG. 6B is different from the semiconductor device 100 in that a plurality of arithmetic circuits, that is, arithmetic circuits 10A and 10B, are included in the element layer 20. The arithmetic circuit 10B provided in the element layer 20 is placed in a region corresponding to the periphery of the element layer 20. In the element layer 30, the storage portion 32 provided with the backup circuit 52 is placed in the periphery of the element layer 30, that is, placed in a region different from the display portion 31. The storage portion 32 provided with the backup circuit 52 is electrically connected to the scan flip-flop 51 included in the arithmetic circuit 10B.

With this structure, the plurality of backup circuits 52 included in the storage portion 32 can be placed directly over the plurality of scan flip-flops 51 included in the arithmetic circuit 10B. Thus, a wiring for electrically connecting the scan flip-flop 51 and the backup circuit 52 can be further shortened. Thus, the wiring resistance and the parasitic capacitance can be lowered, and the operation speed of the semiconductor device 100_X1 can be increased. Furthermore, power consumption of the semiconductor device 100_X1 is reduced.

The storage portion 32 including the backup circuit 52 is placed in the peripheral portion of the display portion 31, whereby the display portion of the electronic device including the semiconductor device 100 can be provided in a region covered with the housing, for example. Therefore, the storage portion 32 can be placed utilizing a region of the element layer 30 where the display portion 31 is not provided, so that the storage portion 32 can be placed without lowering the display quality of the display portion 31.

The semiconductor device 100_X1 illustrated in FIG. 6A and FIG. 6B can have such a structure that the pixel circuit PX is placed but the backup circuit 52 is not placed in the region 50 provided in the display portion 31. In addition, the element layer 60 including a light-emitting device is not placed over the storage portion 32 included in the element layer 30.

This structure can increase the density per unit area of the pixel circuit PX in the display portion 31. Thus, the display quality of the semiconductor device 100_X1 can be increased. Furthermore, since the area where the light-emitting device is provided can be reduced, cost reduction can be achieved.

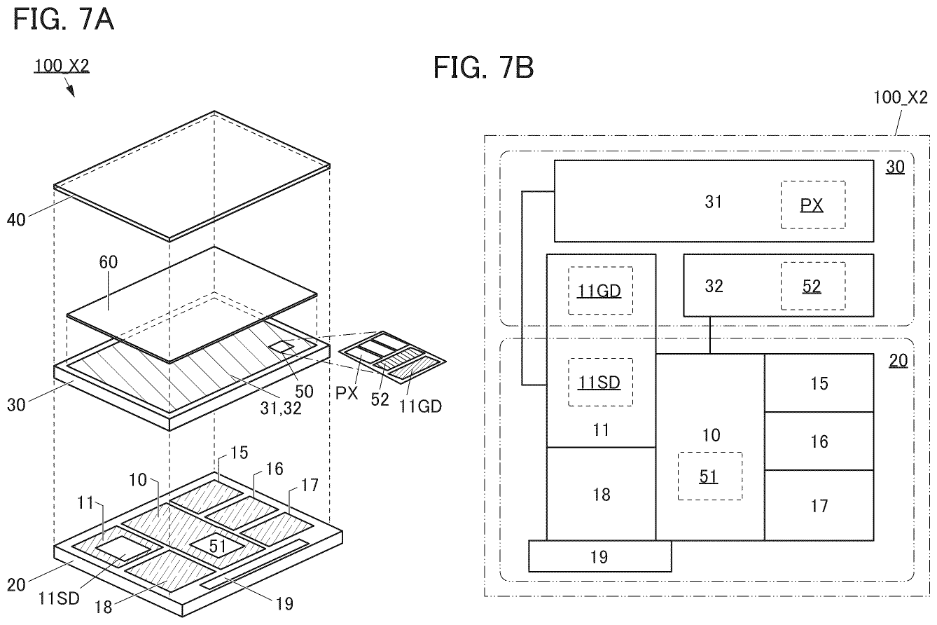

FIG. 7A is a perspective view for illustrating a structure of a semiconductor device 100_X2. FIG. 7B is a block diagram illustrating a structure of the semiconductor device 100_X2.

The semiconductor device 100_X2 illustrated in FIG. 7A and FIG. 7B is different from the semiconductor device 100 in that the driver circuit 11 includes a driver circuit 11GD that is placed in the element layer 30 and a driver circuit 11SD that is placed in the element layer 20. The driver circuit 11GD is a driver circuit functioning as a gate driver circuit or a scan line driver circuit. The driver circuit 11SD is a circuit functioning as a source driver circuit or a signal line driver circuit. The driver circuit 11GD functioning as a gate driver circuit can operate at a lower speed than the driver circuit 11SD functioning as a source driver circuit, and thus can be provided in the element layer 30 including OS transistors. When part of the driver circuit 11GD provided in the element layer 30 is placed in the region 50, the distributed arrangement of the driver circuit 11GD in the element layer 30 (the region where the display portion 31 or the storage portion 32 is provided) becomes possible.

With this structure, the transistors included in the driver circuit 11GD can be dispersedly arranged in the element layer 30; thus, the driver circuit 11GD can be arranged in accordance with the shape of the display portion 31. Thus, the display portion 31 can have also a shape with good designability such as a circular shape or an elliptical shape, as well as a rectangular shape.

### <Structure Example 3 of Semiconductor Device>

Next, a variation of the semiconductor device which is different from the semiconductor device 100 with the above structure is described. The repeated description of the components denoted by the same reference numerals as those in the semiconductor device 100 is omitted in some cases.

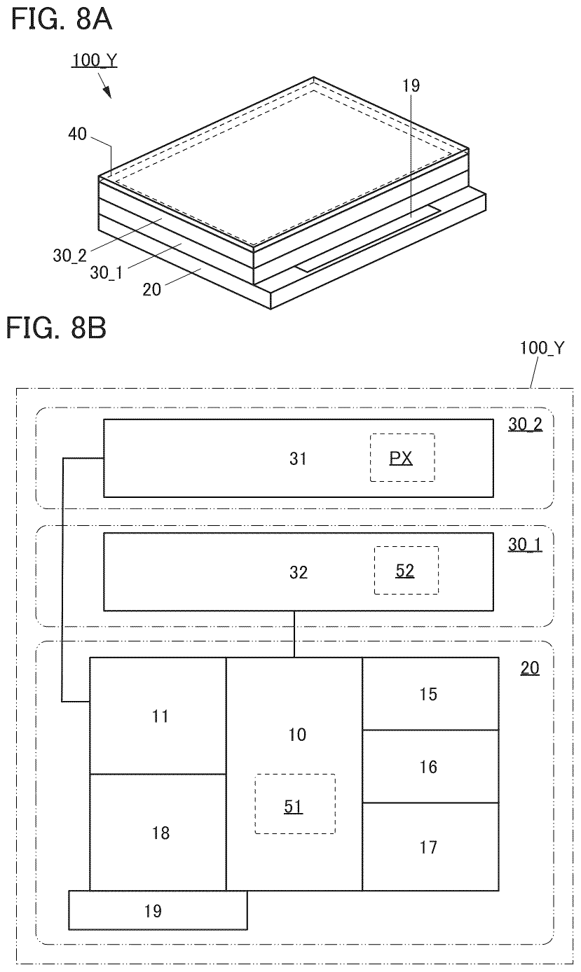

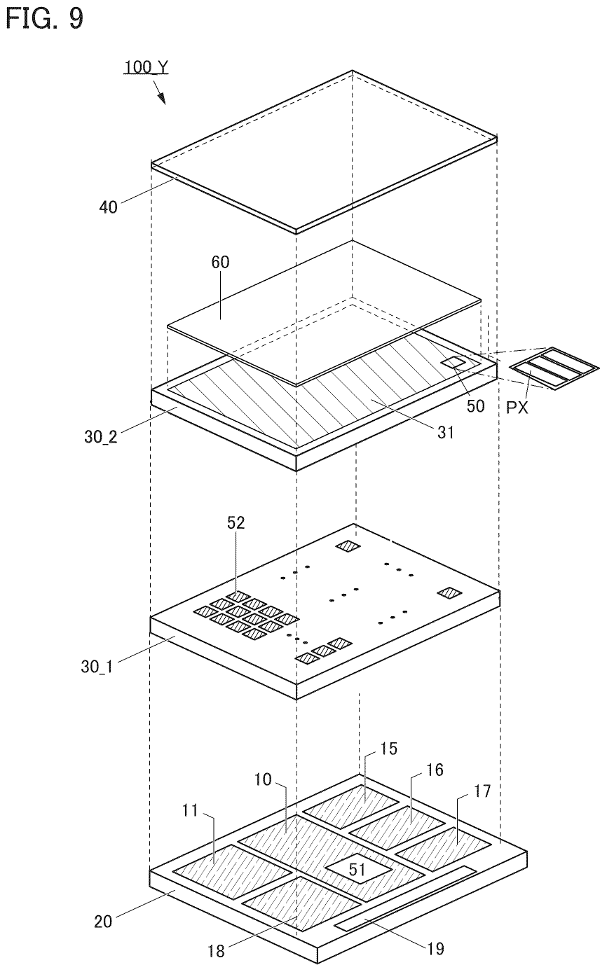

FIG. 8A is a perspective view of a semiconductor device 100_Y of one embodiment of the present invention. FIG. 8B is a block diagram illustrating a structure of the semiconductor device 100_Y. FIG. 9 is a perspective view for illustrating a structure of the semiconductor device 100_Y.

The semiconductor device 100_Y illustrated in FIG. 8A and FIG. 8B is different from the semiconductor device 100 in that the element layer 30 is composed of a plurality of element layers, that is, element layers 30_1 and 30_2. As illustrated in FIG. 8A, the semiconductor device 100_Y includes the element layer 30_1 over the element layer 20, the element layer 30_2 over the element layer 30_1, and the sealing substrate 40 over the element layer 30_2. The element layer 60 (not illustrated) is provided between the sealing substrate 40 and the element layer 30_2. The semiconductor device 100_Y illustrated in FIG. 8B includes the element layer 30_1 that includes the storage portion 32 including the backup circuit 52 and the element layer 30_2 that includes the display portion 31 including the pixel circuit PX. FIG. 9 illustrates the element layer 20, the element layer 30_1, the element layer 30_2, the element layer 60, the sealing substrate 40, and the like apart from each other.

With this structure including the element layer 30_1 and the element layer 30_2, element layers including transistors having different transistor characteristics can be stacked. With use of the element layer 30_1 and the element layer 30_2, element layers including transistors with different shapes can be stacked. With use of the element layer 30_1 and the element layer 30_2, element layers including transistors with different transistor sizes, such as a channel length and a channel width, can be stacked.

For example, the element layer 30_1 can be an element layer including a transistor with a high driving frequency in order to enhance the performance of the backup circuit 52, and the element layer 30_2 can be an element layer including a transistor with a high withstand voltage in order to increase the performance of the pixel circuit PX. Thus, the semiconductor device 100_Y1 can be a semiconductor device that can achieve higher performance.

### <Structure Example 4 of Semiconductor Device>

Next, a variation of the semiconductor device which is different from the semiconductor devices 100, 100_X1, 100_X2, and 100_Y with the above structures is described. The description of the components denoted by the same reference numerals as those in the semiconductor devices 100 and 100_Y is not repeated in some cases.

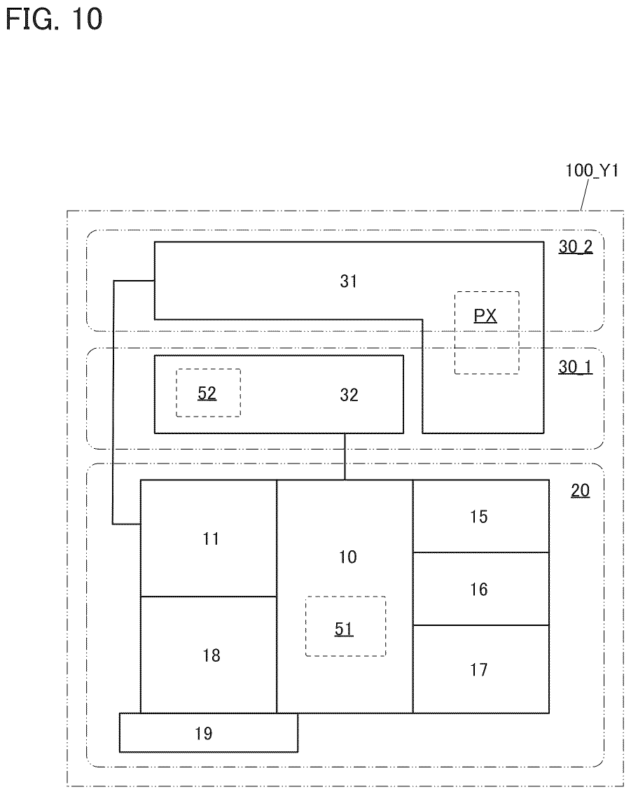

FIG. 10 is a block diagram illustrating a structure of a semiconductor device 100_Y1. The semiconductor device 100_Y1 illustrated in FIG. 10 is different from the semiconductor device 100_Y illustrated in FIG. 9 in that at least part of the pixel circuit PX is provided in the element layer 30_1 as well as in the element layer 30_2.

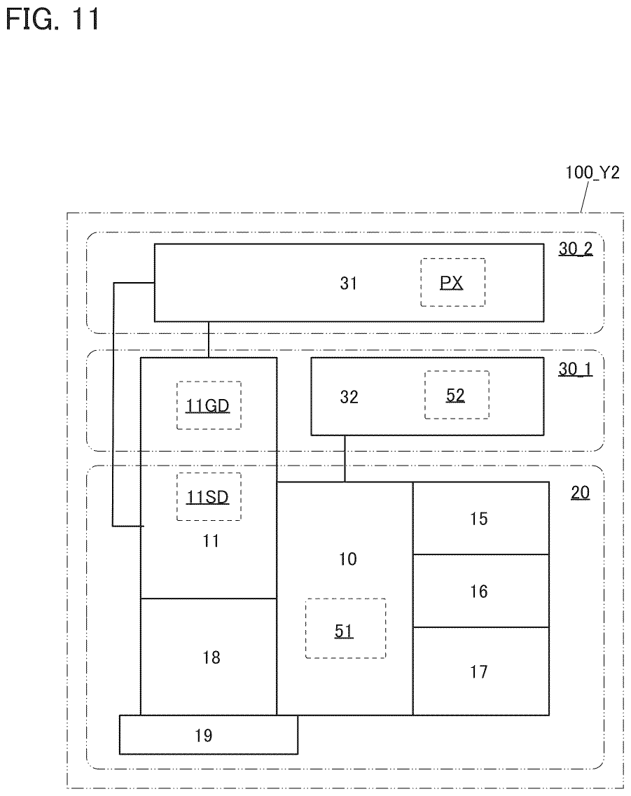

FIG. 11 is a block diagram illustrating a structure of a semiconductor device 100_Y2.

The semiconductor device 100_Y2 illustrated in FIG. 11 is different from the semiconductor device 100_Y illustrated in FIG. 9 in that the driver circuit 11GD that is part of the driver circuit 11 is provided in the element layer 30_1 as well as in the element layer 20.

In terms of OS transistors provided in the element layer 30_1 and the element layer 30_2, when the element layer 30_2 that is the upper layer is provided with the pixel circuit PX, transistors (driving transistors) are preferably placed in the element layer 30_2 to be connected to a pixel electrode of the light-emitting device in the element layer 60 above the element layer, and other kinds of transistors are preferably provided in the element layer 30_1. With this structure, the transistor size provided in the element layer 30_2 can be increased, so that the amount of current flowing through the light-emitting device can be increased.

In terms of OS transistors provided in the element layer 30_1 and the element layer 30_2, when the element layer 30_2 that is the upper layer is provided with the pixel circuit PX, transistors (driving transistors) are preferably placed in the element layer 30_2 to control the amount of current flowing through the light-emitting device, and other kinds of transistors are preferably provided in the element layer 30_1. The transistor structure as the above structure is designed so as to have a back gate electrode and a longer channel length of the transistor, in which case the controllability of the transistor can be increased.

In the case where transistors functioning as switches are placed in the element layer 30_1 in the above-described structure such that the driving transistors are placed in the element layer 30_2, the transistor provided in the element layer 30_1 preferably has a transistor structure described in <Structure example 1 of transistor> in Embodiment 2. Note that the transistor structure described in <Structure example 1 of transistor> in Embodiment 2 can be provided in the same layer as that provided with the transistor having a back gate electrode.

A wiring connected to the gates of the transistors in the pixel circuit PX are positioned above the element layer 30_1 and the element layer 30_2.

When the driver circuit 11GD is provided in the element layer 30_1 or the element layer 30_2, the driver circuit 11GD and the pixel circuit PX are preferably provided in the same layer. When one driver circuit 11GD is provided in both the element layer 30_1 and the element layer 30_2, a clock signal line and a power supply line are formed using wirings of the driver circuit 11GD shared by the element layer 30_1 and the element layer 30_2.

One embodiment of the present invention can provide a novel electronic device and the like. Another embodiment of the present invention can provide an electronic device and the like with a novel structure which include a semiconductor device having performance improved by adopting an SoC and which enables a reduction in size of the semiconductor device. Another embodiment of the present invention can provide an electronic device and the like with a novel structure which include a semiconductor device having performance improved by adopting an SoC and in which heat generation and an increase in power consumption can be inhibited. Another embodiment of the present invention can provide an electronic device and the like with a novel structure in which both performance improvement of a semiconductor device and reduction in power consumption or heat generation of the semiconductor device can be achieved. Another embodiment of the present invention can provide an electronic device and the like with a novel structure that are highly convenient.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For example, the configurations, structures, methods, and the like described in this embodiment can be used in an appropriate combination with any of the configurations, structures, methods, and the like described in the other embodiments and the like.

### Embodiment 2

This embodiment will describe a structure example of a transistor that can be used for the element layer 30 (element layers 30_1 and 30_2) included in the semiconductor device 100 described in Embodiment 1.

### <Structure Example 1 of Transistor>

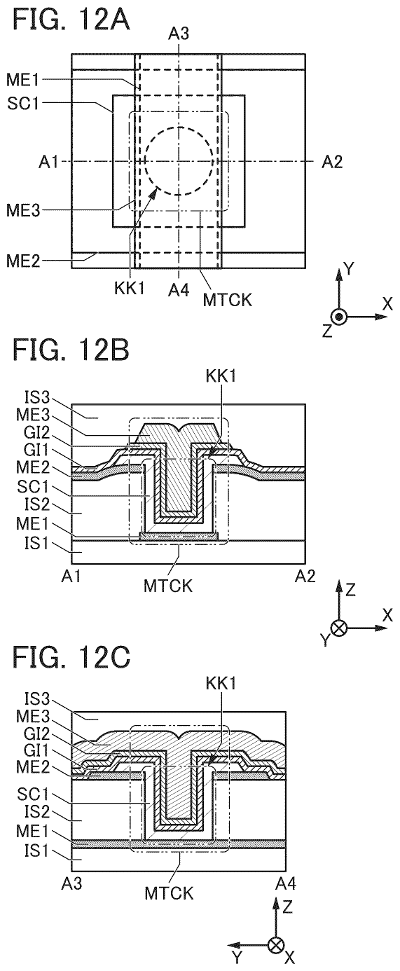

FIG. 12A to FIG. 12C illustrate an example of a semiconductor device (showing, for example, a pixel circuit or a driver circuit) including a transistor MTCK. Specifically, FIG. 12A is a schematic plan view of the transistor MTCK. FIG. 12B is a schematic cross-sectional view corresponding to a portion taken along dashed-dotted line A1-A2 shown in FIG. 12A. FIG. 12C is a schematic cross-sectional view corresponding to a portion taken along dashed-dotted line A3-A4 in FIG. 12A.

In FIG. 12A to FIG. 12C, the direction along the dashed-dotted line A1-A2 is the X direction and the direction along the dashed-dotted line A3-A4 is the Y direction. Furthermore, the direction perpendicular to both the X direction and the Y direction is referred to as the Z direction. The X direction and the Y direction can be perpendicular to each other. The definition of the X direction, the Y direction, and the Z direction applies to some of the following drawings and does not apply to other drawings. In the description of the schematic plan view in FIG. 12A and the like, the right side is referred to as the X direction, the left side is referred to as the −X direction, the upper side is referred to as the Y direction, and the lower side is referred to as the −Y direction in some cases. In the description of the schematic cross-sectional view in FIG. 12B and the like, the right side is referred to as the X direction, the left side is referred to as the −X direction, the upper side is referred to as the Z direction, and the lower side is referred to as the −Z direction in some cases. In the description of the schematic cross-sectional view in FIG. 12C, the right side is referred to as the −Y direction, the left side is referred to as the Y direction, the upper side is referred to as the Z direction, and the lower side is referred to as the −Z direction in some cases.

The transistor MTCK illustrated in FIG. 12A to FIG. 12C includes an insulator IS1 to an insulator IS3, an insulator GI1, an insulator GI2, a conductor ME1 to a conductor ME3, and a semiconductor SC1.

The insulator IS1 functions as a base film above which a source, a drain, and a channel formation region of the transistor MTCK are provided, for example. For the insulator IS1, silicon oxide, silicon oxynitride, silicon nitride oxide, or silicon nitride may be used, for example. For the insulator IS1, for example, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for example, a resin can be used for the insulator IS1. A material combined with any of the above insulating materials as appropriate may be used for the insulator IS1.

The conductor ME1 is a conductor (sometimes referred to as a terminal, a wiring, or the like) functioning as one of a source and a drain in the transistor MTCK. The conductor ME2 is a conductor (sometimes referred to as a terminal, a wiring, or the like) functioning as the other of the source and the drain in the transistor MTCK.

Note that in FIG. 12A to FIG. 12C, the conductor ME1 is provided to extend in the Y direction as a wiring, for example. The conductor ME2 is provided to extend in the X direction as a wiring, for example.

For each of the conductor ME1, the conductor ME2, and the conductor ME3, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum or an alloy containing two or more selected from the above metal elements as components or an alloy combining two or more selected from the above metal elements. Alternatively, for the conductive film ME1, for example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. As the conductor, a semiconductor having high electrical conductivity, typified by polycrystalline silicon containing an impurity element (e.g., phosphorus or arsenic), or silicide (e.g., nickel silicide) may be used.

A plurality of conductive films formed using any of the above materials may be stacked. For example, a stacked-layer structure combining a material containing the above-described metal element and a conductive material containing oxygen may be employed. Specific examples of the stacked-layer structure of the conductive film include a stacked-layer structure of indium oxide and a metal film containing ruthenium. In addition, a stacked-layer structure combining a material containing the above-described metal element and a conductive material containing nitrogen may be employed. Furthermore, a stacked-layer structure combining a material containing the above-described metal element, a conductive material containing oxygen, and a conductive material containing nitrogen may be employed.

The insulator IS2 functions as an interlayer film that separates the source and the drain of the transistor MTCK, for example. Any of the materials that can be used for the insulator IS1 can be used as the insulating film IS2, for example. In the case where the semiconductor SC1 is a metal oxide functioning as an oxide semiconductor, for example, silicon oxide, silicon oxynitride, and porous silicon oxide are preferably used. These materials are capable of easily forming a region containing oxygen that is released by heating, so that the released oxygen can be supplied to the metal oxide. This reduces the carrier concentration of the metal oxide at the interface of the semiconductor SC1 in contact with the insulator IS2 and in the vicinity of the interface, whereby the interface of the semiconductor SC1 and the vicinity of the interface are i-type or substantially i-type. Accordingly, the interface of the semiconductor SC1 and the vicinity of the interface can function as the channel formation region of the transistor MTCK.

For example, the semiconductor SC1 can be a metal oxide functioning as an oxide semiconductor. In this case, the transistor MTCK is an OS transistor. The metal oxide preferably contains at least indium or zinc, for example. In particular, indium and zinc are preferably contained. In addition to them, an element M is preferably contained. As the element M, one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, magnesium, cobalt, and antimony can be used. In particular, the element M is preferably one or more of aluminum, gallium, yttrium, and tin. The element M further preferably contains one or both of gallium and tin. When the semiconductor SC1 is a metal oxide functioning as an oxide semiconductor, it is preferably formed by an ALD (Atomic Layer Deposition) method. As illustrated in FIG. 12B and FIG. 12C, when the semiconductor SC1 is formed in a region having a step, an ALD method enables favorable coverage.

In the case where a metal oxide functioning as an oxide semiconductor is used as the semiconductor SC1, microwave treatment is preferably performed in an oxygen-containing atmosphere during or after the deposition of the metal oxide to reduce the impurity concentration in the metal oxide. Note that specific examples of impurities include hydrogen and carbon. The microwave treatment can increase the crystallinity of the metal oxide in some cases. Here, the microwave treatment refers to, for example, treatment using an apparatus including a power source that generates high-density plasma with the use of a microwave.

It is preferable to use a metal oxide layer having crystallinity as the semiconductor SC1. For example, a metal oxide layer having a CAAC (c-axis aligned crystal) structure, a polycrystalline structure, a nano-crystal (nc) structure, or the like can be used. With use of the metal oxide layer having crystallinity as the semiconductor SC1, the density of defect states in the semiconductor SC1 can be reduced, which enables the semiconductor device to have high reliability.

For example, an In—Ga—Zn oxide is preferably used for the semiconductor SC1. The In—Ga—Zn oxide is preferably a metal oxide with a composition of In:Ga:Zn=1:1:1 [atomic ratio] or in the neighborhood thereof, a composition of In:Ga:Zn=4:2:3 [atomic ratio] or in the neighborhood thereof, or a composition of In:Ga:Zn=3:1:2 [atomic ratio] or in the neighborhood thereof, in particular. For another example, an In—Zn oxide is preferably used for the semiconductor film SC1. The In—Zn oxide is further preferably a metal oxide with a composition of In:Zn=4:1 [atomic ratio] or in the neighborhood thereof, in particular.

The semiconductor SC1 preferably has a stacked-layer structure of a plurality of oxide layers that differ in the atomic ratio of metal atoms. For example, a first metal oxide and a second metal oxide formed over the first metal oxide are assumed as the metal oxide. In the case where each metal oxide contains at least indium (In) and the element M, the proportion of the number of atoms of the element M contained in the first metal oxide to the number of atoms of all elements that constitute the first metal oxide is preferably higher than the proportion of the number of atoms of the element M contained in the second metal oxide to the number of atoms of all elements that constitute the second metal oxide. In addition, the atomic ratio of the element M to In in the first metal oxide is preferably higher than the atomic ratio of the element M to In in the second metal oxide.

Specifically, as the first metal oxide, a metal oxide with a composition of In:Ga:Zn=1:3:4 [atomic ratio] or in the neighborhood thereof, a composition of In:Ga:Zn=1:3:2 [atomic ratio] or in the neighborhood thereof, or a composition of In:Ga:Zn=1:1:0.5 [atomic ratio] or in the neighborhood thereof can be used. As the second metal oxide, a metal oxide with In:Ga:Zn=1:1:1 [atomic ratio] or a composition in the neighborhood thereof, In:Ga:Zn=4:2:3 [atomic ratio] or a composition in the neighborhood thereof, or In:Ga:Zn=3:1:2 [atomic ratio] or a composition in the neighborhood thereof is used. Note that the neighborhood of the composition includes ±30% of an intended atomic ratio.

In this case, the second metal oxide serves as a main carrier path. When the first metal oxide has the above structure, the density of defect states at the interface between the first metal oxide and the second metal oxide can be made low. Thus, the influence of interface scattering on carrier conduction is small, and the transistor can have a high on-state current and high frequency characteristics.

In a region of the insulator IS2 where the transistor MTCK is provided, an opening KK1 whose side surface is substantially perpendicular to the X-Y plane (the taper angle is greater than or equal to 70° and less than or equal to 110°) is formed. The semiconductor SC1 including the channel formation region of the transistor MTCK is provided to be in contact with the conductor ME1 and the conductor ME2 through the opening KK1.

In the transistor MTCK, the insulator GI1 is provided over the semiconductor SC1. Specifically, the insulator GI1 is positioned above and overlaps with the channel formation region included in the semiconductor SC1 in the plan view. Furthermore, in the transistor MTCK, the insulator GI2 is provided over the insulator GI1. Thus, the insulator GI1 and the insulator GI2 function as a gate insulating film of the transistor MTCK.

Thus, for the insulator GI1 and the insulator GI2, a single layer or a stacked layer using an insulator containing what is called a high-k material, such as aluminum oxide, hafnium oxide, tantalum oxide, zirconium oxide, lead zirconate titanate (PZT), strontium titanate (SrTiO₃), or (Ba,Sr)TiO₃ (BST) is preferably used. Alternatively, for the insulator GI1 and the insulator GI2, as an insulator having a high dielectric constant, an oxide containing aluminum and hafnium, an oxynitride containing aluminum and hafnium, an oxide containing silicon and hafnium, an oxynitride containing silicon and hafnium, or a nitride containing silicon and hafnium may be used.

In the transistor MTCK, the conductor ME3 is provided over the insulator GI2 to fill the opening KK1. The conductor ME3 is a conductor (sometimes referred to as a terminal, a wiring, or the like) functioning as a gate in the transistor MTCK.

In FIG. 12A to FIG. 12C, the conductor ME3 is provided to extend in the Y direction as a wiring, for example.

The insulator IS3 is a film functioning as an interlayer film, for example. The insulator IS3 preferably includes an insulating material with a low dielectric constant. The use of an insulating material with a low dielectric constant for the interlayer film can reduce the parasitic capacitance between wirings.

Any of the materials that can be used as the insulator IS1 can be used for the insulator IS3, for example.

As described above, in the transistor MTCK illustrated in FIG. 12A to FIG. 12C, the conductor ME1 functioning as one of the source and the drain is positioned below the insulator IS2 functioning as an interlayer film, and the conductor ME2 functioning as the other of the source and the drain is positioned above the insulator IS2. Thus, the channel formation region of the transistor MTCK is provided along the opening of the insulator IS2.

As illustrated in FIGS. 12A to 12C, when the channel formation region of the transistor is provided along the side surface of the opening of the insulator functioning as an interlayer film, the transistor formation area can be smaller than that in the case where the channel formation region of the transistor is provided along the X-Y plane. Thus, when a circuit is formed using the transistor MTCK, the area of the circuit can be small. As a result, the semiconductor device including the circuit or a display apparatus can be downsized.

Since the gate insulating film of the transistor MTCK includes the insulator GI2, the gate insulating film of the transistor MTCK is increased in thickness by the insulator GI2. In the case where the gate insulating film of the transistor has a large thickness, the gradient of voltage between the gate and the channel formation region of the semiconductor of the transistor can be made low, so that the resistance to the gate potential can be increased. Meanwhile, in the case where the gate insulating film of the transistor has a small thickness, a structure without the insulator GI2 may be employed. In that case, a change in electric field applied from the gate to the channel formation region of the semiconductor becomes faster when the gate potential is changed; thus, the driving frequency of the transistor without the insulator GI2 can be increased.

That is, the transistor MTCK functions as a transistor well withstanding a high gate potential (i.e., a high gate-source voltage or a high gate-drain voltage in some cases) when the insulator GI2 is included, and functions as a transistor with a high driving frequency when the insulator GI2 is not included. Note that the transistor MTCK sometimes functions as a transistor well withstanding a high source potential or a high drain potential. After the insulator GI1 is formed, the insulator GI2 is formed over the insulator GI1 in the region where the transistor MTCK is formed, whereby a transistor with a thick gate insulating film and a transistor with a thin gate insulating film can be separately formed.

The thickness of the insulator GI2 formed after the insulator GI1 is provided can be determined at the step of forming the insulator GI2. That is, the thickness of the gate insulating film of the transistor MTCK can be adjusted even after the insulator GI1 is provided in some cases.

### <Structure Example 2 of Transistor>

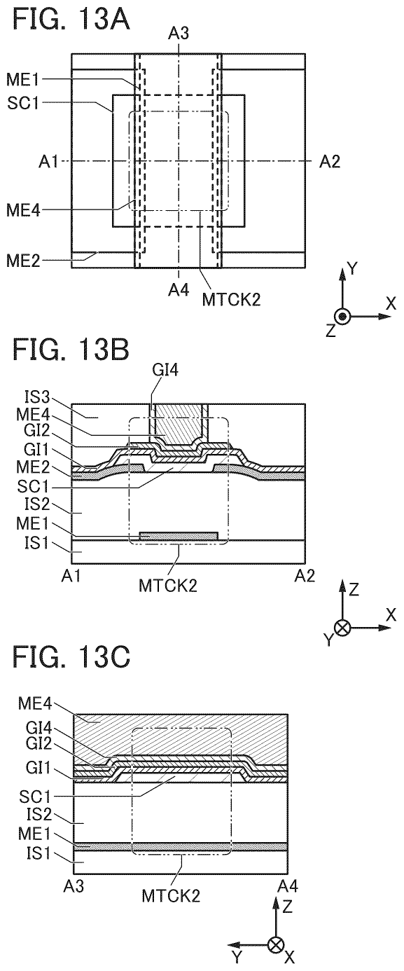

A transistor MTCK2 illustrated in FIG. 13A to FIG. 13C is a variation of the transistor MTCK in FIG. 12A to FIG. 12C, and a channel formation region of the transistor MTCK2 is formed along the direction of the dashed-dotted line A1-A2 (the X direction in the X-Z plane in FIG. 13B).

The transistor MTCK2 illustrated in FIG. 13A to FIG. 13C includes a conductor ME4 functioning as a gate electrode, one of a pair of conductors ME2 functioning as one of a source electrode and a drain electrode, the other of the pair of conductors ME2 functioning as the other of the source electrode and the drain electrode, and a semiconductor SC1 including a channel formation region. The transistor MTCK2 has a structure in which the gate electrode is positioned above the channel formation region and the semiconductor SC1 is over and in contact with the conductor ME2; thus, the transistor MTCK2 is referred to as a TGTC (Top Gate Top Contact) transistor in some cases.

The transistor MTCK2 illustrated in FIG. 13A to FIG. 13C also includes the conductor ME1 functioning as a back gate electrode. Like the gate electrode, the back gate electrode has a function of generating an electric field in the semiconductor SC1. In particular, the back gate electrode enables the number of carriers in the semiconductor SC1 to be changed depending on a potential applied to the back gate electrode, and as a result, the threshold voltage of the transistor MTCK2 can be changed.

In the case where the conductor ME1 functions as a back gate electrode in the transistor MTCK2 illustrated in FIG. 13A to FIG. 13C, the insulator IS2 functions as a gate insulating film in the transistor MTCK2. In that case, the insulator IS2 can be formed using any of the materials usable for the insulator GI1 or the insulator GI2.

In order to distinguish the gate insulating film (the insulator IS2) positioned above the conductor ME1 and below the semiconductor SC1 from the gate insulating film (the insulator GI1 and the insulator GI2) positioned above the semiconductor SC1 and below the conductor ME4, the former is referred to as a second gate insulating film or a back gate insulating film, and the latter is referred to as a first gate insulating film in some cases.

Note that the transistor MTCK2 illustrated in FIG. 13A to FIG. 13C has a structure including the insulator GI1 and the insulator GI2 as the gate insulating film. Thus, it can be said that the transistor MTCK2 withstands high gate voltages.

Meanwhile, the gate insulating films of the transistors MTCK2 in FIG. 13A to FIG. 13C do not necessarily include the insulator GI2.

In the transistor MTCK2 illustrated in FIG. 13A to FIG. 13C, the conductor ME4 functioning as a first gate electrode is embedded in an opening provided in the insulator IS3.

As a method for manufacturing the transistor MTCK2, the insulator IS3 is formed over the insulator GI1 and the insulator GI2 in the manufacturing process of the transistor MTCK2, for example. After that, an opening is formed in a region of the insulator IS3 overlapping with the conductor ME1, the semiconductor SC1, and the insulator GI2, and an insulator GI4 and the conductor ME4 are formed in this order in the opening. Then, planarization treatment such as a CMP method is performed and polishing is performed until the insulator IS3 is exposed; as a result, the transistor MTCK2 can be completed.

Like the insulator GI1 and the insulator GI2, an insulating film GI4 functions as part of the gate insulating film of the transistor MTCK2. Thus, the insulating film GI4 can be formed using any of the materials usable for the insulator GI1 or the insulator GI2. Since the insulator GI4 is formed on the side surface of the opening in the insulator IS3, an ALD method enabling high coverage is preferably used for the formation of the insulator GI4.

The insulator GI4 functions as a film that prevents diffusion of impurities such as oxygen contained in the insulator IS3 into the conductor ME4 and oxidation of the conductor ME4, for example. That is, the insulator GI4 functions as a barrier insulating film. Note that in the case where it is not needed to prevent the diffusion of impurities from the insulator IS3 into the conductor ME4, the insulator GI4 is not necessarily provided in the transistor MTCK2.

The conductor ME4 is a conductor functioning as a gate electrode of the transistor MTCK2. Thus, the conductor ME4 can be formed using any of the materials usable for the conductor ME3, for example.

In the above method for manufacturing the transistor MTCK2, the conductor ME4 functioning as the gate electrode is formed in a self-aligned manner to fill the opening formed in the insulator IS3. The transistor MTCK2 in which the gate electrode is formed in a self-aligned manner to fill the opening is referred to as a TGSA FET (Trench Gate Self Aligned FET) in some cases.

Note that the transistor MTCK2 illustrated in FIG. 13A to FIG. 13C has a structure in which the gate insulating film includes the insulator GI1 and the insulator GI2. Thus, it can be said that the transistor MTCK2 has high tolerance to gate voltages. When the transistor MTCK2 in FIG. 13A to FIG. 13C does not include the insulator GI2, the gate insulating film can be thinned, so that the transistor can have a high driving frequency.

### <Structure Example 3 of Transistor>

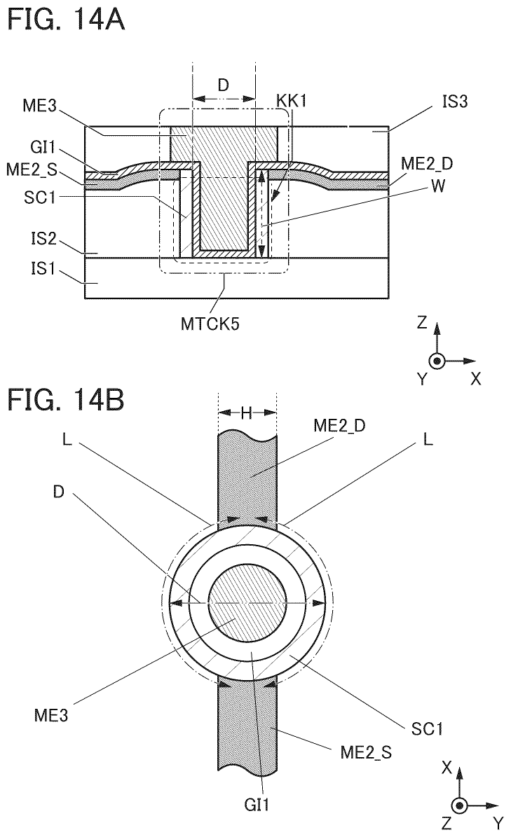

FIG. 14A is a cross-sectional view of a transistor MTCK5, along the X-Z plane, having a structure different from that in FIG. 12B. FIG. 14B is a cross-sectional view taken along the X-Y plane.

The transistor MTCK5 is different from the transistor MTCK mainly in that the conductor ME1 is not included, conductors ME2_S and ME2_D are included instead of the conductor ME2, and the semiconductor SC1 has a different shape. The conductor ME2_S functions as a source electrode, and the conductor ME2_D functions as a drain electrode.

The semiconductor SC1 has a circular shape in the plan view. The semiconductor SC1 includes a region in contact with the side surface of the conductor ME2_S, a region in contact with the side surface of the conductor ME2_D, and a region in contact with the side surface of the insulator IS2 in the opening KK1. Here, the semiconductor SC1 is not in contact with the top surfaces of the conductors ME2_S and ME2_D. The semiconductor SC1 having such a shape can be formed through processing with anisotropic etching, for example. Note that as illustrated in FIG. 12B, the semiconductor SC1 may be in contact with the top surface of the conductor ME2.

As illustrated in FIG. 14B, the widths H of the conductor ME2_S and the conductor ME2_D are smaller than the maximum width D of the opening KK1. In this case, the circumferential direction of the opening KK1 corresponds to the channel length direction of the transistor MTCK5. Here, since the semiconductor SC1 has a circular shape, two kinds of current paths (i.e., channels) from the conductor ME2_S to the conductor ME2_D exist. Note that the semiconductor SC1 does not necessarily have a circular shape and may be in contact with both the conductor ME2_S and the conductor ME2_D.

The channel length can be controlled by the shape and size of the opening KK1. For example, in the case where an increase in the channel length is assumed, the perimeter L of the opening KK1 should be long. Although this embodiment describes the example where the opening KK1 has a circular shape in the plan view, the present invention is not limited thereto. For example, the opening KK1 can have an elliptical shape or a quadrangular shape with rounded corners besides the circular shape in the plan view. Alternatively, a regular polygonal shape such as a regular triangular shape, a square shape, or a regular pentagonal shape or a polygonal shape other than the regular polygonal shape may be employed. By employing a concave polygonal shape in which at least one interior angle is greater than 180°, such as a star polygonal shape, the channel length can be increased. Alternatively, an elliptical shape, a polygonal shape with rounded corners, a closed curve in which a straight line and a curve are combined, or the like can be employed. In that case, the maximum width of the opening KK1 is preferably calculated as appropriate in accordance with the shape of the uppermost portion of the opening KK1. For example, in the case where the opening portion is square or rectangular in the plan view, the maximum width of the opening KK1 may be the length of a diagonal line of the uppermost portion of the opening KK1. Note that the channel length of the transistor MTCK5 is the distance along the perimeter direction of the opening KK1 as described above, so that current flows in the lateral direction. Furthermore, it can be said that the transistor MTCK5 includes a component making current flow also in the thickness direction of the conductor ME2_S and the conductor ME2_D, i.e., in the height direction (vertical direction); thus, the transistor of one embodiment of the present invention can be referred to as a VLFET (Vertical Lateral Field Effect Transistor).

As illustrated in FIG. 14A, the height of the semiconductor SC1 corresponds to the channel width W of the transistor MTCK5. Thus, the channel width W of the transistor MTCK5 can be controlled by the thickness of the insulator IS2. Accordingly, the channel width of the transistor MTCK5 can be extremely minute below the light exposure limit of photolithography.

The transistor MTCK has an extremely small channel length and can have a large channel width, so that a high on-state current can be achieved. Meanwhile, the transistor MTCK5 has an extremely small channel width and can have a large channel length, so that an appropriate on-state current can be obtained and the transistor design is facilitated. The transistor MTCK and the transistor MTCK5 can be formed, with manufacturing steps some of which are shared, separately over the same substrate. For example, the transistor MTCK5 can be used as a driving transistor for controlling current flowing through the light-emitting device, and the transistor MTCK can be used as a transistor functioning as a switch. Furthermore, since the transistor MTCK and the transistor MTCK5 can be combined to form a driver circuit, the semiconductor device can have higher functionality and higher reliability.

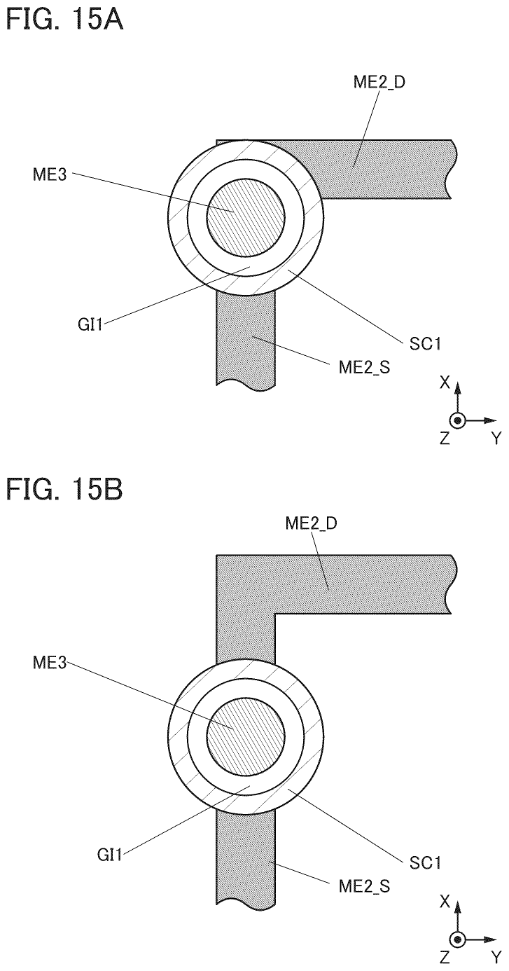

Although FIG. 14B illustrates the arrangement example where the conductor ME2_S and the conductor ME2_D face each other in the plan view, one embodiment of the present invention is not limited thereto. For example, as illustrated in FIG. 15A, the conductor ME2_S and the conductor ME2_D may be placed to be orthogonal to each other. Alternatively, as illustrated in FIG. 15B, the conductor ME2_S and the conductor ME2_D may be placed to face each other and be orthogonal to each other. The arrangements illustrated in FIG. 15A and FIG. 15B can increase layout flexibility, so that a semiconductor device with a high degree of integration can be provided.

### <Structure Example 4 of Transistor>

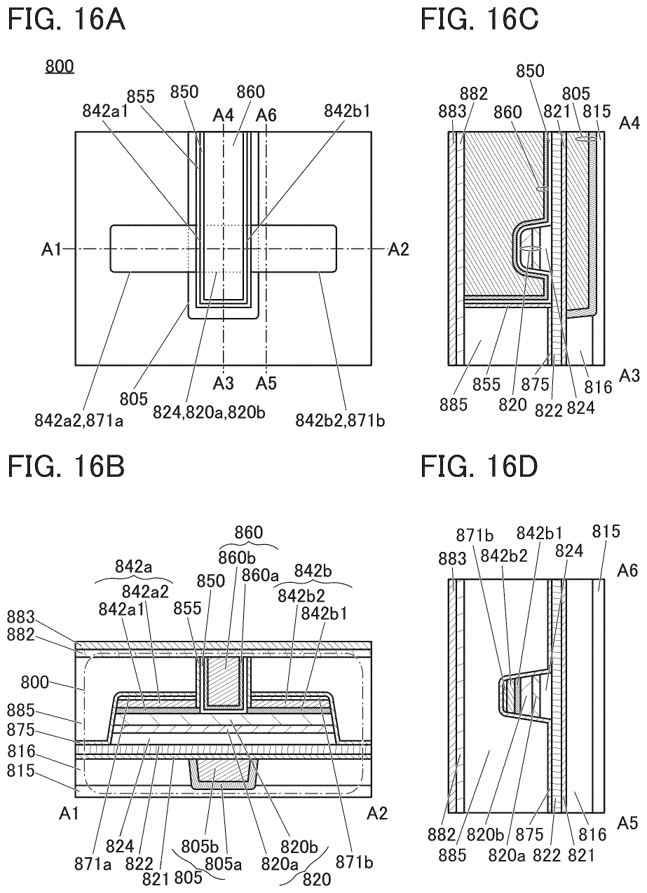

FIG. 16A is a top view of a transistor 800 having a structure different from the above structure example. FIG. 16B is a cross-sectional view taken along the dashed-dotted line A1-A2 in FIG. 16A. FIG. 16B is also a cross-sectional view of the transistor 800 in the channel length direction. FIG. 16C is a cross-sectional view taken along the dashed-dotted line A3-A4 in FIG. 16A. FIG. 16C is also a cross-sectional view of the transistor 800 in the channel width direction. FIG. 16D is a cross-sectional view taken along the dashed-dotted line A5-A6 in FIG. 16A. FIG. 16D is also a cross-sectional view of the transistor 800 in the channel width direction. Note that for clarity of the drawing, some components are not illustrated in the top view of FIG. 16A.

The transistor 800 includes a conductor 805 (a conductor 805a and a conductor 805b) provided to be embedded in an insulator 816; an insulator 821 over the insulator 816 and the conductor 805; an insulator 822 over the insulator 821; an insulator 824 over the insulator 822; an oxide 820 (an oxide 820a and an oxide 820b) over the insulator 824; a conductor 842a (a conductor 842a1 and a conductor 842a2) and a conductor 842b (a conductor 842b1 and a conductor 842b2) over the oxide 820; an insulator 871a over the conductor 842a; an insulator 871b over the conductor 842b; an insulator 850 over the oxide 820; and a conductor 860 (a conductor 860a and a conductor 860b) over the insulator 850.

An insulator 875 is provided over the insulators 871a and 871b, and an insulator 885 is provided over the insulator 875. An insulator 855, the insulator 850, and the conductor 860 are placed in an opening provided in the insulator 885 and the insulator 875. An insulator 882 is provided over the insulator 885 and the conductor 860. An insulator 883 is provided over the insulator 882. An insulator 815 is provided below the insulator 816 and the conductor 805. The insulator 855 is provided between the insulator 850 and the conductor 842a2, the conductor 842b2, the insulator 871a, the insulator 871b, the insulator 875, and the insulator 885.

Note that the insulator 815, the insulator 816, the conductor 805, the insulator 821, the insulator 822, the insulator 824, the oxide 820, the conductor 842a, the conductor 842b, the insulator 871a, the insulator 871b, the insulator 875, the insulator 885, the insulator 855, the insulator 850, the conductor 860, the insulator 882, and the insulator 883 may each have a single-layer structure or a stacked-layer structure.

The oxide 820 includes a region functioning as a channel formation region of the transistor 800. The conductor 860 includes a region functioning as a first gate electrode (an upper gate electrode) of the transistor 800. The insulator 850 includes a region functioning as a first gate insulator of the transistor 800. The conductor 805 includes a region functioning as a second gate electrode (a lower gate electrode) of the transistor 800. The insulator 824, the insulator 822, and the insulator 821 each include a region functioning as a second gate insulator of the transistor 800.

The conductor 842a includes a region functioning as one of a source electrode and a drain electrode of the transistor 800. The conductor 842b includes a region functioning as the other of the source electrode and the drain electrode of the transistor 800.

The oxide 820 preferably includes the oxide 820a over the insulator 824 and the oxide 820b over the oxide 820a. Including the oxide 820a under the oxide 820b makes it possible to inhibit diffusion of impurities into the oxide 820b from components formed below the oxide 820a.

Note that the oxide 820 is not limited to having a two-layer structure of the oxide 820a and the oxide 820b. The oxide 820 may have a single-layer structure of the oxide 820b or a stacked-layer structure of three or more layers, for example.

The oxide 820b includes the channel formation region of the transistor 800 and a source region and a drain region provided to sandwich the channel formation region. At least part of the channel formation region overlaps with the conductor 860. The source region overlaps with the conductor 842a, and the drain region overlaps with the conductor 842b. Note that the source region and the drain region can be interchanged with each other.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

The source region and the drain region have a large amount of oxygen vacancies or a high concentration of an impurity such as hydrogen, nitrogen, or a metal element, and thus are each a low-resistance region with a high carrier concentration. In other words, the source region and the drain region are each an n-type region (low-resistance region) having a higher carrier concentration than the channel formation region.

Note that the channel formation region, the source region, and the drain region may each be formed not only in the oxide 820b but also in the oxide 820a.

In the oxide 820, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

An oxide semiconductor is preferably used for the oxide 820 (the oxide 820a and the oxide 820b).

The oxide 820 preferably has a stacked-layer structure of a plurality of oxide layers with different chemical compositions. For example, the atomic ratio of the element M to a metal element that is a main component in the metal oxide used for the oxide 820a is preferably greater than the atomic ratio of the element M to a metal element that is a main component in the metal oxide used for the oxide 820b. Moreover, the atomic ratio of the element M to In in the metal oxide used for the oxide 820a is preferably greater than the atomic ratio of the element M to In in the metal oxide used for the oxide 820b. With this structure, impurities and oxygen can be inhibited from diffusing into the oxide 820b from the components formed below the oxide 820a.

Furthermore, the atomic ratio of In to the element M in the metal oxide used for the oxide 820b is preferably greater than the atomic ratio of In to the element M in the metal oxide used for the oxide 820a. With this structure, the transistor 800 can have a high on-state current and excellent frequency characteristics.

When the oxide 820a and the oxide 820b include a common element as the main component besides oxygen, the density of defect states at the interface between the oxide 820a and the oxide 820b can be decreased. Thus, the influence of interface scattering on carrier conduction is reduced, and the transistor 800 can have a high on-state current and high frequency characteristics.

Specifically, for the oxide 820a, a metal oxide with a composition of In:M:Zn=1:3:2 [atomic ratio] or in the neighborhood thereof, a composition of In:M:Zn=1:3:4 [atomic ratio] or in the neighborhood thereof, or a composition of In:M:Zn=1:1:0.5 [atomic ratio] or in the neighborhood thereof can be used. For the oxide 820b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Gallium is preferably used as the element M. In the case where a single layer of the oxide 820b is provided as the oxide 820, a metal oxide that can be used for the oxide 820a may be used for the oxide 820b. The compositions of the metal oxides that can be used for the oxide 820a and the oxide 820b are not limited to the above. For example, the composition of the metal oxide that can be used for the oxide 820a may be applied to the oxide 820b. Similarly, the composition of the metal oxide that can be used for the oxide 820b may be applied to the oxide 820a.

When the metal oxide is deposited by a sputtering method, the above atomic ratio is not limited to the atomic ratio of the deposited of the metal oxide and may be the atomic ratio of a sputtering target used for depositing the metal oxide.

The oxide 820b preferably has crystallinity. It is particularly preferable to use a CAAC-OS for the oxide 820b.

When an oxide having crystallinity, such as a CAAC-OS, is used for the oxide 820b, oxygen extraction from the oxide 820b by the source electrode or the drain electrode can be inhibited. This can reduce oxygen extraction from the oxide 820b even when heat treatment is performed; thus, the transistor 800 is stable with respect to high temperatures in the manufacturing process (what is called thermal budget).

Examples of materials that can be used for the conductors included in the transistor 800 include the above-described materials that can be used for the conductor ME1 to the conductor ME3. A typical example is described below.

The conductor 842a has a stacked structure of the conductor 842a1 and the conductor 842a2 over the conductor 842a1, and the conductor 842b has a stacked structure of the conductor 842b1 and the conductor 842b2 over the conductor 842b1. The conductor 842a1 and the conductor 842b1 in contact with the oxide 820b are preferably conductors that are not easily oxidized, such as metal nitride. Thus, the conductor 842a and the conductor 842b can be prevented from being oxidized excessively by oxygen contained in the oxide 820b. The conductor 842a2 and the conductor 842b2 are preferably conductors having higher conductivity than the conductor 842a1 and the conductor 842b1, such as a metal layer. Accordingly, the conductor 842a and the conductor 842b can each function as a wiring or an electrode with high conductivity.

For example, tantalum nitride or titanium nitride can be used for the conductor 842a1 and the conductor 842b1, and tungsten can be used for the conductor 842a2 and the conductor 842b2.

The opening formed in the insulator 885 and the insulator 875 overlap with a region between the conductor 842a2 and the conductor 842b2. In the plan view, the side surface of the opening in the insulator 885 is aligned or substantially aligned with the side surface of the conductor 842a2 and the side surface of the conductor 842b2. The conductor 842a1 and the conductor 842b1 are formed to partly extend toward the inside of the opening. A part of the top surface of the conductor 842a1 is in contact with the conductor 842a2, and a part of the top surface of the conductor 842b1 is in contact with the conductor 842b2. Thus, the insulator 855 is in contact with another part of the top surface of the conductor 842a1, another part of the top surface of the conductor 842b1, and the side surface of the conductor 842a2, and the side surface of the conductor 842b2 in the opening. The insulator 850 is in contact with the top surface of the oxide 820, the side surface of the conductor 842a1, the side surface of the conductor 842b1, and the side surface of the insulator 855.

The insulator 855 is preferably an insulator that is not easily oxidized, such as nitride. By anisotropic etching, the insulator 855 is formed in a sidewall shape to be in contact with the sidewall of the opening formed in the insulator 885 and the like (here, the sidewall of the opening corresponds to, for example, the side surface of the insulator 885 or the like). The insulator 855 is formed in contact with the side surface of the conductor 842a2 and the side surface of the conductor 842b2 and has a function of protecting the conductor 842a2 and the conductor 842b2. In order to supply oxygen to the oxide 820b, heat treatment in an atmosphere containing oxygen is preferably performed after the separation into the conductor 842a1 and the conductor 842b1 and before the formation of the insulator 850. At this time, since the insulator 855 is formed in contact with the side surface of the conductor 842a2 and the side surface of the conductor 842b2, excessive oxidation of the conductor 842a2 and the conductor 842b2 can be prevented. The insulator 855 can be formed using silicon nitride, for example.

An insulator containing oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor 800. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, in the oxide semiconductor, the channel formation region is preferably an i-type or substantially i-type region with a reduced carrier concentration, whereas the source region and the drain region are preferably n-type regions with high carrier concentrations. That is, the amounts of oxygen vacancies and V_{O}H in the channel formation region of the oxide semiconductor are preferably reduced. Supply of an excess amount of oxygen to the source region and the drain region and excessive reduction in the amount of V_{O}H in the source region and the drain region are preferably inhibited. In addition, a structure in which conductivity of the conductor 860, the conductor 842a, the conductor 842b, and the like is less likely to be reduced is preferably employed. For example, oxidation of the conductor 860, the conductor 842a, the conductor 842b, and the like is preferably inhibited. Note that hydrogen in the oxide semiconductor can form V_{O}H; thus, the hydrogen concentration needs to be reduced in order to reduce the amount of V_{O}H.

The transistor 800 has a structure in which the hydrogen concentration in the channel formation region is reduced, oxidation of the conductor 842a, the conductor 842b, and the conductor 860 is inhibited, and a reduction in the hydrogen concentration in the source region and the drain region is inhibited.

The insulator 850 in contact with the channel formation region of the oxide 820b preferably has a function of capturing or fixing hydrogen. Thus, the hydrogen concentration in the channel formation region of the oxide 820b can be reduced. Accordingly, V_{O}H in the channel formation region can be reduced, so that the channel formation region can be an i-type or substantially i-type region.

The insulator 850 functions as a gate insulator. The insulator 850 is provided in the opening formed in the insulator 885, together with the insulator 855 and the conductor 860. The thickness of the insulator 850 is preferably thin for miniaturization of the transistor 800. The thickness of each layer included in the insulator 850 is preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet still further preferably greater than or equal to 1.0 nm and less than 5.0 nm, yet still further preferably greater than or equal to 1.0 nm and less than or equal to 3.0 nm. Each of the layers included in the insulator 850 at least partly includes a region with the above-described thickness.

To form the insulator 850 having a small thickness, an ALD method is preferably used for deposition. Furthermore, in the case where the insulator 850 and the insulator 855 are provided in the opening in the insulator 885 and the like, an ALD method is preferably employed. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because it enables film formation at a lower temperature.

The thickness of the insulator 855 is preferably greater than or equal to 0.5 nm and less than or equal to 20 nm, further preferably greater than or equal to 0.5 nm and less than or equal to 10 nm, still further preferably greater than or equal to 0.5 nm and less than or equal to 3 nm. When the insulator 855 has a thickness in the above range, excessive oxidation of the conductor 842a2 and the conductor 842b2 can be inhibited. In this case, at least part of the insulator 855 may have a region with the above-described thickness. When the thickness of the insulator 855 is set excessively large, the time for depositing the insulator 855 by an ALD method is long, which decreases the productivity; for this reason, the thickness of the insulator 855 is preferably in the above range.

A structure in which hydrogen is inhibited from entering the transistor 800 and the like is preferably employed for the semiconductor device illustrated in FIG. 16A and the like. For example, an insulator having a function of inhibiting diffusion of hydrogen is preferably provided to cover one or both of the upper portion and the lower portion of the transistor 800 and the like. Accordingly, each of the insulator 815, the insulator 821, the insulator 822, the insulator 882, and the insulator 883 preferably includes an insulator having a function of inhibiting diffusion of oxygen and impurities such as water and hydrogen. Examples of the insulator include aluminum oxide, magnesium oxide, hafnium oxide, zirconium oxide, oxide containing aluminum and hafnium (hafnium aluminate), oxide containing hafnium and zirconium (hafnium zirconium oxide), gallium oxide, indium gallium zinc oxide, silicon nitride, and silicon nitride oxide. For example, silicon nitride, which has a higher hydrogen barrier property, is preferably used for the insulator 883 and the insulator 821. For example, the insulator 882 preferably includes aluminum oxide or the like, which has a function of capturing or fixing hydrogen well. For example, hafnium oxide, which has high capability of capturing or fixing hydrogen and is a high permittivity (high-k) material, is preferably used for the insulator 822. With such a structure where the transistor 800 is surrounded by upper and lower insulators having a function of inhibiting diffusion of oxygen and impurities such as water and hydrogen, excess oxygen and hydrogen can be inhibited from diffusing into the oxide semiconductor. Thus, the semiconductor device can have improved electrical characteristics and reliability.

Here, it is preferable that a region of the insulator 875 not overlapping with the oxide 820 be in contact with the insulator 822, a side end portion of the insulator 875 be in contact with the insulator 855, and an upper end portion of the insulator 855 and upper end portion of the insulator 850 be in contact with the insulator 882. With the above structure, in a region sandwiched between the insulator 883 and the insulator 821, the insulator 885 is isolated from the oxide 820 by the insulator 875, and the insulator 885 is separated from the insulator 850 by the insulator 855. Accordingly, diffusion of impurities contained in the insulator 885, such as water and hydrogen, into the oxide 820 and the insulator 850 can be inhibited. Hydrogen contained in the insulator 850 can be captured and fixed in the insulator 882. With such a structure, the amount of hydrogen diffusing into the oxide semiconductor can be further reduced. Thus, the semiconductor device can have improved electrical characteristics and reliability.

In the transistor 800, the conductor 805 is placed to overlap with the oxide 820 and the conductor 860. Here, the conductor 805 is preferably provided to be embedded in an opening portion formed in the insulator 816. Moreover, the conductor 805 is preferably provided to extend in the channel width direction as illustrated in FIG. 16A and FIG. 16C. With such a structure, the conductor 805 functions as a wiring when a plurality of transistors are provided.

As illustrated in FIG. 16B and FIG. 16C, the conductor 805 preferably includes the conductor 805a and the conductor 805b. The conductor 805a is provided in contact with the bottom surface and the sidewall of the opening portion. The conductor 805b is provided to fill a depressed portion that is defined by the conductor 805a and formed along the opening portion. Here, the top surface of the conductor 805 is level or substantially level with the top surface of the insulator 816.

When the conductor 805a is formed using a conductive material having a function of inhibiting diffusion of hydrogen, impurities such as hydrogen contained in the conductor 805b can be prevented from diffusing into the oxide 820 through the insulator 816 and the like. When a conductive material having a function of inhibiting diffusion of oxygen is used for the conductor 805a, the conductivity of the conductor 805b can be inhibited from being lowered because of oxidation. Examples of the conductive material having a function of inhibiting diffusion of oxygen include titanium, titanium nitride, tantalum, tantalum nitride, ruthenium, and ruthenium oxide. The conductor 805a can have a single-layer structure or a stacked-layer structure of the above conductive material. For example, the conductor 805a preferably contains titanium nitride.

The conductor 805b is preferably formed using a conductive material containing tungsten, copper, or aluminum as its main component. For example, the conductor 805b preferably contains tungsten.

The conductor 805 can function as the second gate electrode. In that case, by changing a potential applied to the conductor 805 not in conjunction with but independently of a potential applied to the conductor 860, the threshold voltage (Vₜₕ) of the transistor 800 can be controlled. In particular, by applying a negative potential to the conductor 805, Vₜₕ of the transistor 800 can be higher, and its off-state current can be reduced. Thus, a drain current at the time when a potential applied to the conductor 860 is 0 V can be lower in the case where a negative potential is applied to the conductor 805 than in the case where the negative potential is not applied to the conductor 805.

The electrical resistivity of the conductor 805 is designed in consideration of the potential applied to the conductor 805, and the thickness of the conductor 805 is set in accordance with the electrical resistivity. The thickness of the insulator 816 is substantially equal to the thickness of the conductor 805. Here, the conductor 805 and the insulator 816 are preferably as thin as possible in the allowable range of the design of the conductor 805. When the thickness of the insulator 816 is reduced, the absolute amount of impurities such as hydrogen contained in the insulator 816 can be reduced, inhibiting diffusion of the impurities into the oxide 820.

The insulator 824 that is in contact with the oxide 820 preferably includes silicon oxide or silicon oxynitride, for example. Accordingly, oxygen can be supplied from the insulator 824 to the oxide 820, so that oxygen vacancies can be reduced.

The insulator 884 is preferably processed into an island shape in the same manner as the oxide 820. Thus, in the case where a plurality of the transistors 800 are provided, the insulators 884 having substantially the same size are provided for the respective transistors 800. Accordingly, substantially the same amount of oxygen is supplied from the insulator 884 to the oxide 820 in the transistors 800. This can reduce variations in electrical characteristics of the transistors 800 in the substrate plane. Note that the structure is not limited to this, and it is possible not to pattern the insulator 884 as in the case of the insulator 822.

A conductive material that is less likely to be oxidized or a conductive material having a function of inhibiting diffusion of oxygen is preferably used for each of the conductor 842a, the conductor 842b, and the conductor 860. Examples of the conductive material include a conductive material containing nitrogen and a conductive material containing oxygen. Thus, a decrease in the conductivity of the conductor 842a, the conductor 842b, and the conductor 860 can be inhibited.

The insulator 871a and the insulator 871b are inorganic insulators functioning as etching stoppers in the processing into the conductor 842a2 and the conductor 842b2 and protecting the conductor 842a2 and the conductor 842b2. Since the insulator 871a and the insulator 871b are respectively in contact with the conductor 842a and the conductor 842b, the insulator 871a and the insulator 871b are preferably inorganic insulators that are less likely to oxidize the conductors 842a and 842b. The insulator 871a and the insulator 871b preferably have a stacked-layer structure of a nitride insulator and an oxide insulator, for example.

Note that in this specification and the like, a transistor structure where a channel formation region is electrically surrounded by at least the electric field of a first gate electrode is referred to as a surrounded channel (S-channel) structure. The S-channel structure disclosed in this specification and the like is different from a Fin-type structure or a planar structure. Meanwhile, the S-channel structure disclosed in this specification and the like can be regarded as a kind of the Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect does not easily occur can be provided.

When the transistor 800 has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. When the transistor 800 has the S-channel structure, the GAA structure, or the LGAA structure, the channel formation region that is formed at the interface between the oxide 820 and the gate insulator or in the vicinity of the interface can be formed in the entire bulk of the oxide 820. Accordingly, the density of a current flowing through the transistor can be increased, which can be expected to increase the on-state current of the transistor or increase the field-effect mobility of the transistor.

In this embodiment, the insulator 824 with an island shape is provided. Accordingly, as illustrated in FIG. 16C, at least part of the bottom surface of the conductor 860 can be positioned lower than the bottom surface of the oxide 820b. Thus, the conductor 860 can be provided to face the top surface and the side surface of the oxide 820b, so that an electric field of the conductor 860 can be applied to the top surface and the side surface of the oxide 820b. When the insulator 824 with an island shape is provided in this manner, the transistor 800 can have an S-channel structure.

The conductor 860 preferably includes the conductor 860a and the conductor 860b placed over the conductor 860a. For example, the conductor 860a is preferably placed to cover the bottom surface and the side surface of the conductor 860b. In this case, a conductive material that is less likely to be oxidized or a conductive material having a function of inhibiting diffusion of oxygen is preferably used for the conductor 860a. When the conductor 860a has a function of inhibiting diffusion of oxygen, the conductivity of the conductor 860b can be inhibited from being lowered because of oxidation due to oxygen contained in the insulator 885 or the like. As the conductive material having a function of inhibiting diffusion of oxygen, for example, titanium, titanium nitride, tantalum, tantalum nitride, ruthenium, or ruthenium oxide is preferably used.

As the conductor 860b, a conductor having high conductivity is preferably used. For example, a conductive material containing tungsten, copper, or aluminum as its main component can be used as the conductor 860b. The conductor 860b may have a stacked-layer structure; for example, a stacked-layer structure of the conductive material and titanium or titanium nitride may be employed.

The insulator 816 and the insulator 885 each preferably have a lower permittivity than the insulator 822. When a material with a low permittivity is used for an interlayer film, parasitic capacitance generated between wirings can be reduced.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For example, the configurations, structures, methods, and the like described in this embodiment can be used in an appropriate combination with any of the configurations, structures, methods, and the like described in the other embodiments and the like.

### Embodiment 3

In this embodiment, a circuit configuration applicable to the shift register included in the driver circuit 11GD described above in Embodiment 1 will be described.

### <Pulse Output Circuit>

First, a configuration example of a pulse output circuit included in the shift register included in the driver circuit 11GD is described. The pulse output circuit has a function of retaining a start pulse signal and outputting a retained signal in accordance with a clock signal. The pulse output circuit is a circuit that outputs a pulse for one row (one column). The pulse output circuit is referred to as a storage circuit in some cases.

### «Configuration Example of Pulse Output Circuit»

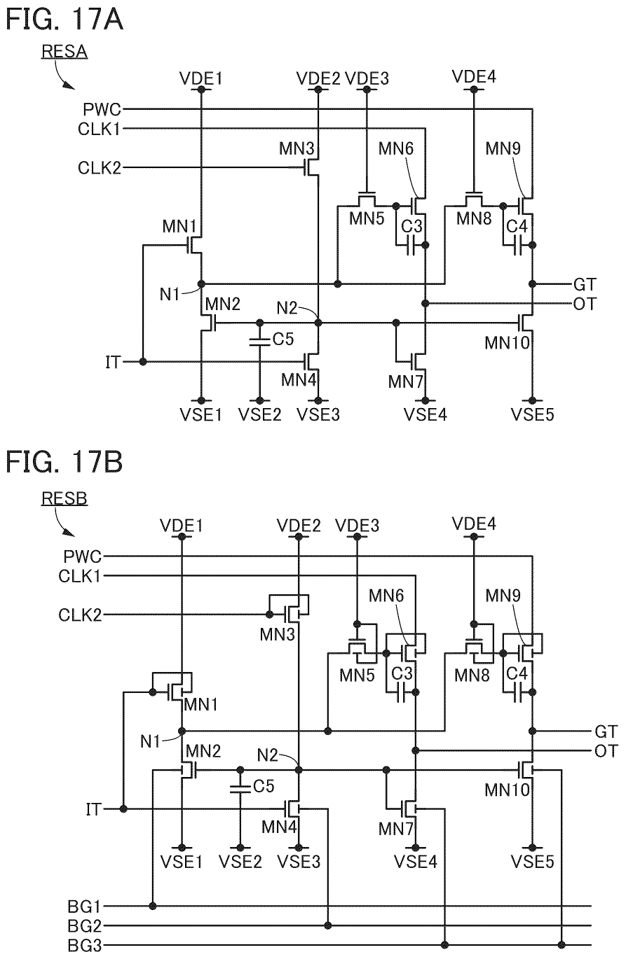

FIG. 17A illustrates an example of a circuit configuration of a pulse output circuit RESA that can be used for the pulse output circuit included in the driver circuit 11GD.

The pulse output circuit RESA includes a transistor MN1 to a transistor MN10 and a capacitor C3 to a capacitor C5, for example. As illustrated in FIG. 17A, the pulse output circuit RESA is a single-polarity circuit (which means a circuit formed of transistors having one conductivity) that does not include p-channel transistors but includes n-channel transistors.

The pulse output circuit RESA includes a terminal IT functioning as an input terminal or an output terminal, a terminal CLK1, a terminal CLK2, a terminal PWC, a terminal GT, and a terminal OT.

In the case where a moving image is smoothly displayed on the display portion 31 including the pixel circuit PX in the semiconductor device 100, the frame frequency of the display portion 31 is preferably increased. Therefore, to increase the frame frequency, a transistor with high driving frequency is preferably used for the shift register included in the driver circuit 11GD. That is, as each of the transistor MN1 to the transistor MN10, the transistor MTCK or the transistor MTCK2 without the insulator GI2, which is described in Embodiment 2, is preferably used.

A gate of the transistor MN1 is electrically connected to the terminal IT, and a first terminal of the transistor MN1 is electrically connected to a wiring VDE1. A gate of the transistor MN3 is electrically connected to the terminal CLK2, and a first terminal of the transistor MN3 is electrically connected to a wiring VDE2. A gate of the transistor MN2 is electrically connected to a second terminal of the transistor MN3, a first terminal of the transistor MN4, a gate of the transistor MN7, a gate of the transistor MN10, and a first terminal of the capacitor C5; a first terminal of the transistor MN2 is electrically connected to a second terminal of the transistor MN1, a first terminal of the transistor MN5, and a first terminal of the transistor MN8; and a second terminal of the transistor MN2 is electrically connected to a wiring VSE1. A gate of the transistor MN4 is electrically connected to the terminal IT, and a second terminal of the transistor MN4 is electrically connected to a wiring VSE3.

A gate of the transistor MN5 is electrically connected to a wiring VDE3, and a second terminal of the transistor MN5 is electrically connected to a gate of the transistor MN6 and a first terminal of the capacitor C3. A first terminal of the transistor MN6 is electrically connected to the terminal CLK1, and a second terminal of the transistor MN6 is electrically connected to a first terminal of the transistor MN7, a second terminal of the capacitor C3, and the terminal OT. A second terminal of the transistor MN7 is electrically connected to a wiring VSE4.

A gate of the transistor MN8 is electrically connected to a wiring VDE4, and the second terminal the transistor MN8 is electrically connected to a gate of the transistor MN9 and a first terminal of the capacitor C4. A first terminal of the transistor MN9 is electrically connected to the terminal PWC, and a second terminal of the transistor MN9 is electrically connected to a first terminal of the transistor MN10, a second terminal of the capacitor C4, and the terminal GT. A second terminal of the transistor MN10 is electrically connected to a wiring VSE5.

The terminal IT is a terminal corresponding to a first input terminal of the pulse output circuit.

The terminal CLK1, the terminal CLK2, and the terminal PWC correspond to a second input terminal of the pulse output circuit.

In particular, wirings electrically connected to the terminal CLK1 and the terminal CLK2 and a wiring electrically connected to the terminal PWC function as wirings for supplying a pulse potential. The pulse widths of the pulse potentials supplied from the wiring electrically connected to the terminal CLK1 or the terminal CLK2 and the wiring electrically connected to the terminal PWC may be different from each other.

The terminal OT is a terminal corresponding to a first output terminal of the pulse output circuit.

The terminal GT is a terminal corresponding to a second output terminal of the pulse output circuit.

Each of the wiring VDE1 to the wiring VDE4 functions as a wiring for supplying a constant potential, for example. The constant potential can be a high-level potential or the like. Note that the wiring VDE1 to the wiring VDE4 may supply the same constant potential or different constant potentials. Alternatively, two or more of the wiring VDE1 to the wiring VDE4 may supply the same constant potential, and the other wiring(s) may supply a potential different from the constant potential. Furthermore, the two or more of the wiring VDE1 to the wiring VDE4 which supply the same constant potential may be a single wiring. For example, in the case where the wiring VDE1 and the wiring VDE2 supply the same constant potential, the wiring VDE1 and the wiring VDE2 may be a single wiring.

One or more of the wiring VDE1 to the wiring VDE4 may supply a variable potential, instead of a constant potential.

Each of the wiring VSE1 to the wiring VSE5 functions as a wiring supplying a constant potential, for example. The constant potential can be, for example, a low-level potential, the ground potential, or a negative potential. Note that the wiring VSE1 to the wiring VSE5 may supply the same constant potential or different constant potentials. Alternatively, two or more of the wiring VSE1 to the wiring VSE5 may supply the same constant potential, and the other wiring(s) may supply a potential different from the constant potential. Furthermore, the two or more of the wiring VSE1 to the wiring VSE5 which supply the same constant potential may be a single wiring. For example, in the case where the wiring VSE1 and wiring VSE2 supply the same constant potential, the wiring VSE1 and the wiring VSE2 may be a single wiring.

One or more of the wiring VSE1 to the wiring VSE4 may supply a variable potential, instead of a constant potential.

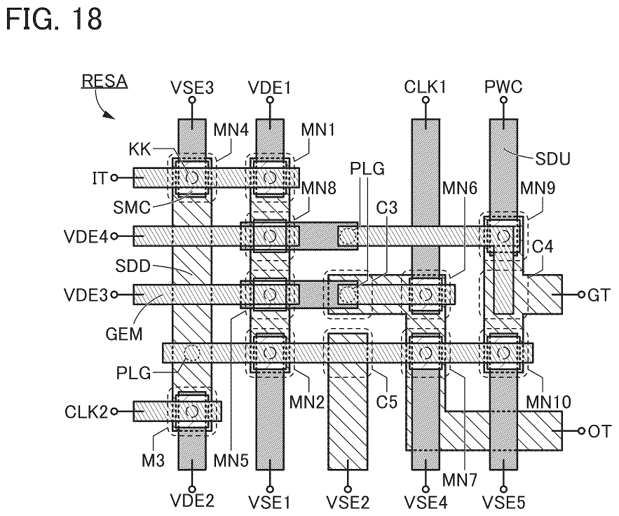

FIG. 18 is a layout diagram (plan view) of the pulse output circuit RESA in FIG. 17A. In FIG. 18, the pulse output circuit RESA includes a conductor GEM, a conductor SDD, a conductor SDU, a semiconductor SMC, and a conductor PLG. Note that an insulator included in the pulse output circuit RESA is not illustrated in FIG. 18.

The conductor SDD is positioned below the conductor SDU, for example. The conductor SDU has an opening KK in a region overlapping with the conductor SDD, for example. Note that the opening KK is denoted by a dashed line in FIG. 18. The semiconductor SMC is positioned over the conductor SDU outside the region of the opening KK and over the conductor SDD in the region of the opening KK, for example. The conductor GEM is positioned above the semiconductor SMC to fill the opening KK.

The conductor SDD corresponds to the conductor ME1 in FIG. 12A to FIG. 12C, the conductor SDU corresponds to the conductor ME2 in FIG. 12A to FIG. 12C, the semiconductor SMC corresponds to the semiconductor SC1 in FIG. 12A to FIG. 12C, and the conductor GEM corresponds to the conductor ME3 in FIG. 12A to FIG. 12C. The opening KK corresponds to the opening KK1 in FIG. 12A to FIG. 12C.

The semiconductor SMC, the conductor GEM, the conductor SDD, and the conductor SDU can be formed by a photolithography method, for example. Specifically, for example, in the case where the conductor GEM is formed, a conductive material to be the conductor GEM is formed by one or more selected from a sputtering method, a CVD (Chemical Vapor Deposition) method, a PLD (Pulsed Laser Deposition) method, and an ALD method, and then a desired pattern is shaped by a photolithography method. The semiconductor SMC, the conductor SDD, and the conductor SDU can also be formed in a manner similar to the above.

Furthermore, insulators may be provided between the semiconductor SMC and the conductor GEM, between the conductor GEM and the conductor SDU, and between the conductor SDU and the conductor SDD. In particular, the insulator provided between the semiconductor SMC and the conductor GEM functions as a gate insulating film in some cases.

The conductor PLG serving as a wiring or a plug is provided each between the conductor SDD and the conductor SDU and between the conductor SDU and the conductor GEM. The conductor PLG is formed, for example, in such a manner that an opening portion is formed in the insulator, and the opening portion is filled with a conductive material to be the conductor PLG. Note that after the formation of the conductor PLG, planarization may be performed by planarization treatment using a chemical mechanical polishing method or the like to align the levels of film surfaces of the conductor PLG and peripheral insulators.

Note that an opening may be provided in the insulator between the conductor SDU and the conductor GEM without providing the conductor PLG between the conductor SDU and the conductor GEM so that the conductor SDU and the conductor GEM come in direct contact with each other, whereby the conductor SDU and the conductor GEM are electrically connected to each other.

In the capacitor C4 in FIG. 18, part of the conductor GEM is the first terminal of the capacitor C4 and part of the conductor SDD is the second terminal of the capacitor C4. In order to increase the capacitance of the capacitor C4, the insulator between the conductor GEM and the conductor SDD in the region of the capacitor C4 in FIG. 18 may made to have a small thickness. An insulator having a high dielectric constant may be provided between the conductor GEM and the conductor SDD. Note that the description of the capacitor C4 can be referred to for the capacitor C5.

In the capacitor C3 in FIG. 18, part of the conductor SDU is the first terminal of the capacitor C3 and another part of the conductor SDD is the second terminal of the capacitor C3. Thus, although the conductor GEM and the conductor SDU are electrically connected to each other in the region of the capacitor C3 in FIG. 18, the conductor SDU and the conductor SDD are not electrically connected to each other. In order to increase the capacitance of the capacitor C3, the insulator between the conductor SDD and the conductor SDU in the region of the capacitor C3 in FIG. 18 may be made to have a small thickness. An insulator having a high dielectric constant may be provided between the conductor SDD and the conductor SDU.

### «Variation 1 of Pulse Output Circuit»

The configuration of the pulse output circuit that can be used for the pulse output circuit included in the driver circuit 11GD is not limited to the pulse output circuit RESA illustrated in FIG. 17A. For example, a pulse output circuit RESB illustrated in FIG. 17B may be used for the pulse output circuit configuration applicable to the pulse output circuit included in the driver circuit 11GD.

The pulse output circuit RESB in FIG. 17B is a variation of the pulse output circuit RESA in FIG. 17A and is different from the pulse output circuit RESA in that each transistor included in the pulse output circuit RESB is provided with a back gate.

The transistor MN1 to the transistor MN10 illustrated in FIG. 17A are each an n-channel transistor having a multi-gate structure (also referred to as a dual-gate structure) including gates above and below a channel, and the transistor MN1 to the transistor MN10 each include a back gate in addition to the gate. Note that in this specification and the like, for convenience, the gate is referred to as a first gate (sometimes referred to as a front gate) and the back gate is referred to as a second gate so that they are distinguished from each other in some cases. In this specification and the like, the first gate and the second gate can be interchanged with each other; thus, the term “gate” can be replaced with the term “back gate”. Similarly, the term “back gate” can be replaced with the term “gate”. As a specific example, a connection structure in which “a gate is electrically connected to a first wiring and a back gate is electrically connected to a second wiring” can be replaced with a connection structure in which “a back gate is electrically connected to the first wiring and a gate is electrically connected to the second wiring”.

Note that in FIG. 17B, the electrical destinations of the back gates of the transistor MN1 to the transistor MN10 can be determined at the design stage. For example, in a transistor including a back gate, a gate and the back gate may be electrically connected to each other to increase the on-state current of the transistor (corresponding to the transistor MN1, the transistor MN3, the transistor MN5, the transistor MN6, the transistor MN8, and the transistor MN9 in FIG. 17B). For another example, in a transistor having a back gate, a wiring electrically connecting the back gate of the transistor to an external circuit may be provided and a potential may be supplied to the back gate of the transistor with the external circuit to change the threshold voltage of the transistor or to reduce the off-state current of the transistor (corresponding to the transistor MN2, the transistor MN4, the transistor MN7, and the transistor MN10 in FIG. 17B).

Although the transistor MN1 to the transistor MN10 are n-channel transistors in FIG. 17A and FIG. 17B, the transistor MN1 to the transistor MN10 may be p-channel transistors depending on circumstances.

Note that the description of the transistor applies to transistors described in other parts of the specification and transistors illustrated in the drawings other than FIG. 17A and FIG. 17B in a similar manner, in some cases.

In each of the transistor MN1, the transistor MN3, the transistor MN5, the transistor MN6, the transistor MN8, and the transistor MN9, the gate is electrically connected to the back gate. A second gate of the transistor MN2 is electrically connected to a wiring BG1. A second gate of the transistor MN4 is electrically connected to a wiring BG2. The second gate of each of the transistor MN7 and the transistor MN10 is electrically connected to a wiring BG3.

Each of the wiring BG1 to the wiring BG3 functions as a wiring supplying a constant potential, for example. The constant potential can be, for example, a low-level potential, the ground potential, or a negative potential. Note that the wiring BG1 to the wiring BG3 may supply the same constant potential or different constant potentials. In the case where two or more selected from the wiring BG1 to the wiring BG3 supply the same constant potential, the two or more wirings may be a single wiring. One or more of the wiring BG1 to the wiring BG3 may supply a variable potential, not a constant potential.

In the case where the wiring BG1 to the wiring BG3 are different from one another, different constant potentials can be supplied to the back gates of the transistor MN2, the transistor MN4, the transistor MN7, and the transistor MN10. That is, the threshold voltage of the transistor MN2, the threshold voltage of the transistor MN4, the threshold voltage of the transistor MN7, and the threshold voltage of the transistor MN10 can be controlled independently of one another.

With this configuration, for example, when a negative potential is supplied to the back gate of the transistor MN4 and the ground potential or a low-level potential (a potential higher than the negative potential) is supplied to the back gates of the transistor MN7 and the transistor MN10, the amounts of off-state currents of the transistor MN7 and the transistor MN10 can be larger than the amount of an off-state current of the transistor MN4. Accordingly, when the pulse output circuit RESB in FIG. 17B is used as the pulse output circuit included in the driver circuit 11GD, the driving speed of the shift register provided in the driver circuit 11SD can be further increased.

### «Variation 2 of Pulse Output Circuit»

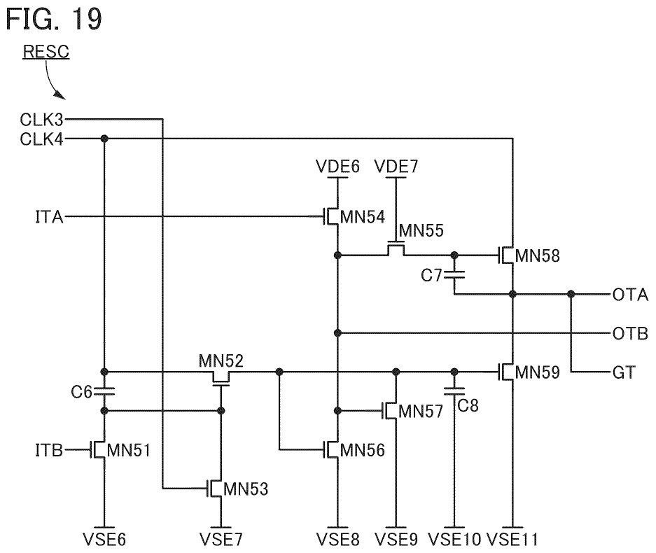

For another example, a pulse output circuit RESC illustrated in FIG. 19 may be used for the pulse output circuit configuration applicable to the pulse output circuit included in the driver circuit 11GD.

The pulse output circuit RESC includes a terminal ITA and a terminal ITB functioning as a first input terminal of the pulse output circuit and a terminal OTA and a terminal OTB functioning as a first output terminal of the pulse output circuit. That is, the pulse output circuit RESC is different from the pulse output circuit RESA in including two first input terminals and two first output terminals.

The terminal OTA of the pulse output circuit RESC in the previous stage is electrically connected to the terminal ITA of the pulse output circuit RESC in the subsequent stage, and the terminal OTB of the pulse output circuit RESC in the previous stage is electrically connected to the terminal ITB of the pulse output circuit RESC in the subsequent stage.

The pulse output circuit RESC includes a terminal CLK3 and a terminal CLK4. The terminal CLK3 and the terminal CLK4 correspond to the second input terminal of the pulse output circuit.

In particular, a wiring electrically connected to the terminal CLK3 or the terminal CLK4 and a wiring electrically connected to the terminal PWC function as wirings for supplying a pulse potential. Note that the pulse widths of the pulse potentials supplied to the terminal CLK3 and the terminal CLK4 may be different from each other.

Like the pulse output circuit RESA, the pulse output circuit RESC includes the terminal GT. The terminal GT is a terminal corresponding to the second output terminal of the pulse output circuit.

The pulse output circuit RESC includes a transistor MN51 to a transistor MN59 and a capacitor C6 to a capacitor C8, for example. As illustrated in FIG. 19, the pulse output circuit RESC is a single-polarity circuit that does not include a p-channel transistor but includes an n-channel transistor.

Although the transistor MN51 to the transistor MN59 each have a single-gate structure in the pulse output circuit RESC in FIG. 19, the transistors may each have a multi-gate structure including gates above and below a channel.

Note that in the case where a moving image is smoothly displayed on the display portion 31 including the pixel circuit PX in the semiconductor device 100, the frame frequency of the display portion 31 is preferably increased. Therefore, to increase the frame frequency, a transistor with a high driving frequency is preferably used as the pulse output circuit included in the driver circuit 11GD. That is, as each of the transistor MN51 to the transistor MN59, the transistor MTCK or the transistor MTCK2 without the insulator GI2, which is described in Embodiment 2, is preferably used.

A first terminal of the capacitor C6 is electrically connected to a first terminal of the transistor MN52 and the terminal CLK4, and a second terminal of the capacitor C6 is electrically connected to a first terminal of the transistor MN51, a gate of the transistor MN52, and a first terminal of the transistor MN53. A second terminal of the transistor MN51 is electrically connected to a wiring VSE6, and a gate of the transistor MN51 is electrically connected to a terminal ITB. A second terminal of the transistor MN53 is electrically connected to a wiring VSE7, and a gate of the transistor MN53 is electrically connected to the terminal CLK3. A second terminal of the transistor MN52 is electrically connected to a gate of the transistor MN56, a first terminal of the transistor MN57, a gate of the transistor MN59, and a first terminal of the capacitor C8. A second terminal of the transistor MN57 is electrically connected to a wiring VSE9. A second terminal of the capacitor C8 is electrically connected to a wiring VSE10.

A first terminal of the transistor MN54 is electrically connected to a wiring VDE6, and a second terminal of the transistor MN54 is electrically connected to a first terminal of the transistor MN55, a gate of the transistor MN75, a first terminal of the transistor MN56, and the terminal OTB. A second terminal of the transistor MN56 is electrically connected to a wiring VSE8. A second terminal of the transistor MN55 is electrically connected to a gate the transistor MN58 and a first terminal of the capacitor C7, and a gate of the transistor MN55 is electrically connected to a wiring VDE7. A first terminal of the transistor MN58 is electrically connected to the terminal CLK4; a second terminal of the transistor MN58 is electrically connected to a second terminal of the capacitor C7, a first terminal of the transistor MN59, the terminal OTA, and the terminal GT; and a second terminal of the transistor MN59 is electrically connected to a wiring VSE11.

Each of the wiring VDE6 and the wiring VDE7 functions as a wiring supplying a constant potential, for example. The constant potential can be a high-level potential or the like. Note that the wiring VDE6 and the wiring VDE7 may supply the same constant potential or different fixed potentials. In the case where the wiring VDE6 and the wiring VDE7 supply the same constant potential, the wiring VDE6 and the wiring VDE7 may be the same wiring.

One or both of the wiring VDE6 and the wiring VDE7 may supply a variable potential, instead of a constant potential.

Each of the wiring VSE6 to the wiring VSE11 functions as a wiring supplying a constant potential, for example. The constant potential can be, for example, a low-level potential, the ground potential, or a negative potential. Note that the wiring VSE6 to the wiring VSE11 may supply the same constant potential or different fixed potentials. Alternatively, two or more of the wiring VSE6 to the wiring VSE11 may supply the same constant potential, and the other wiring(s) may supply a potential different from the constant potential. Furthermore, the two or more of the wiring VSE6 to the wiring VSE11 which supply the same constant potential may be a single wiring. For example, in the case where the wiring VSE6 and wiring VSE7 supply the same constant potential, the wiring VSE6 and the wiring VSE7 may be a single wiring.

One or more of the wiring VSE6 to the wiring VSE11 may supply a variable potential, instead of a constant potential.

In order to increase the frame frequency of the display portion 31 in the display portion 31 including the pixel circuit PX of the semiconductor device 100, a transistor with a high driving frequency is preferably used in the pulse output circuit included in the driver circuit 11GD. Thus, as each of the transistor MN51 to the transistor MN59, the transistor MTCK or the transistor MTCK2 without the insulator GI2, which is described in Embodiment 2, is preferably used.

Note that the semiconductor device of one embodiment of the present invention is not limited to the configuration of the circuit described above. The semiconductor device of one embodiment of the present invention may have a structure in which the above-described circuits are changed as appropriate.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For example, the configurations, structures, methods, and the like described in this embodiment can be used in an appropriate combination with any of the configurations, structures, methods, and the like described in the other embodiments and the like.

### Embodiment 4

In this embodiment, a circuit configuration applicable to the pixel circuit PX described in Embodiment 1 will be described.

### <Configuration Example 1 of Pixel Circuit>

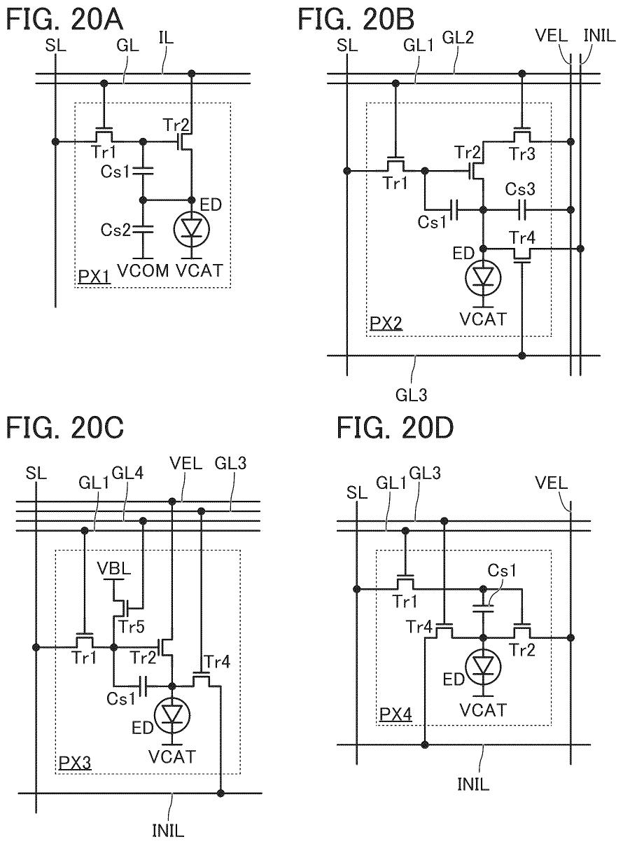

FIG. 20A is a circuit diagram illustrating a configuration example of a circuit applicable to the pixel circuit PX of the semiconductor device 100 described in Embodiment 1.

A pixel circuit PX1 illustrated in FIG. 20A includes, for example, a transistor Tr1, a transistor Tr2, a capacitor Cs1, a capacitor Cs2, and a light-emitting device ED.

Examples of the light-emitting device ED include a light-emitting device containing an organic EL material, a light-emitting device containing an inorganic EL material, and a light-emitting diode (e.g., a micro LED). The pixel circuit PX1 can be a pixel circuit using one or more selected from the above-described light-emitting devices. Note that in the description in this embodiment, the pixel PX includes a light-emitting device containing an organic EL material.

A first terminal of the transistor Tr1 is electrically connected to a wiring SL, a second terminal of the transistor Tr1 is electrically connected to a gate of the transistor Tr2 and a first terminal of the capacitor Cs1, and a gate of the transistor Tr1 is electrically connected to a wiring GL. A first terminal of the transistor Tr2 is electrically connected to a wiring IL, and a second terminal of the transistor Tr2 is electrically connected to a second terminal of the capacitor Cs1, a first terminal of the capacitor Cs2, and an anode of the light-emitting device ED. A second terminal of the capacitor Cs2 is electrically connected to a wiring VCOM. A cathode of the light-emitting device ED is electrically connected to a wiring VCAT.

The wiring SL functions as a wiring for transmitting an image signal from the driver circuit 11SD described in Embodiment 1 to the pixel circuit PX1.

The wiring GL functions as a wiring for transmitting a selection signal from the driver circuit 11GD described in Embodiment 1 to the pixel circuit PX1.

The wiring IL functions as a wiring for supplying current to the anode of the light-emitting device ED. Thus, the wiring IL is referred to as a current supply line in some cases.

The wiring VCOM functions as a wiring for supplying a constant potential to the second terminal of the capacitor Cs2. In particular, the constant potential is referred to as a common potential in some cases. The common potential can be, for example, a low-level potential, the ground potential, or a negative potential. The wiring VCOM may also supply the common potential to the second terminal of the capacitor Cs2 included in another pixel circuit PX1.

The wiring VCAT functions as a wiring for supplying a constant potential to the cathode of the light-emitting device ED. In particular, the constant potential is referred to as a cathode potential in some cases. The cathode potential can be, for example, a low-level potential, the ground potential, or a negative potential. The wiring VCAT may also supply the cathode potential to the cathode of the light-emitting device ED provided in another pixel circuit PX1.

Note that the common potential supplied from the wiring VCOM and the cathode potential supplied from the wiring VCAT may be equal to each other. In that case, the wiring VCOM and the wiring VCAT may be one wiring (not illustrated).

The transistor Tr1 functions as a write transistor of an image signal in the pixel circuit PX. In the case where a transistor having high resistance to voltages is used as the transistor Tr1, for example, it is effective to use the transistor MTCK described in Embodiment 2.

The transistor Tr2 functions as a driving transistor for controlling the amount of current flowing between the anode and the cathode of the light-emitting device ED in the pixel circuit PX. Thus, in the case where the potential corresponding to the image signal is a high potential, a transistor having high resistance to voltages is preferably used as the transistor Tr2. For example, a transistor with a thick gate insulating film is preferably used as the transistor Tr2. Specifically, the transistor MTCK2 described in the above embodiment is preferably used as the transistor Tr2, for example. The transistor MTCK2 is particularly preferable because it includes a back gate.

### <Configuration Example 2 of Pixel Circuit>

FIG. 20B is a circuit diagram illustrating a configuration example that is applicable to the pixel circuit PX of the semiconductor device 100 described in Embodiment 1 and is different from the configuration example of the pixel circuit in FIG. 20A.

A pixel circuit PX2 illustrated in FIG. 20B includes the transistor Tr1, the transistor Tr2, a transistor Tr3, a transistor Tr4, the capacitor Cs1, a capacitor Cs3, and the light-emitting device ED, for example.

For the transistor Tr1, the transistor Tr2, the capacitor Cs1, and the light-emitting device ED, the description of the transistor Tr1, the transistor Tr2, the capacitor Cs1, and the light-emitting device ED included in the pixel circuit PX1 can be referred to.

The pixel circuit PX2 has not only a function of emitting light with emission intensity corresponding to an input image signal but also a function of correcting the threshold voltage of the transistor Tr2, which is a driving transistor.

The first terminal of the transistor Tr1 is electrically connected to the wiring SL, the second terminal of the transistor Tr1 is electrically connected to the gate of the transistor Tr2 and the first terminal of the capacitor Cs1, and the gate of the transistor Tr1 is electrically connected to a wiring GL1. The first terminal of the transistor Tr2 is electrically connected to a first terminal of the transistor Tr3, and the second terminal of the transistor Tr2 is electrically connected to the second terminal of the capacitor Cs1, a first terminal of the capacitor Cs3, a first terminal of the transistor Tr4, and the anode of the light-emitting device ED. A second terminal of the transistor Tr3 is electrically connected to a wiring VEL, and a gate of the transistor Tr3 is electrically connected to a wiring GL2. A second terminal of the capacitor Cs3 is electrically connected to the wiring VEL. A second terminal of the transistor Tr4 is electrically connected to a wiring INIL, and a gate of the transistor Tr4 is electrically connected to a wiring GL3. The cathode of the light-emitting device ED is electrically connected to a wiring VCAT.

For the wiring SL and the wiring VCAT, the description of the wiring SL and the wiring VCAT electrically connected to the pixel circuit PX1 in FIG. 20A can be referred to.

The wiring GL1, the wiring GL2, and the wiring GL3 function as wirings for transmitting selection signals from the driver circuit 11GD described in Embodiment 1 to the pixel circuit PX2.

The wiring VEL functions as a wiring for supplying a potential to the anode of the light-emitting device ED.

The wiring INIL functions as a wiring for supplying a potential to the anode of the light-emitting device ED. In particular, the potential can be an initialization potential for resetting the anode potential of the light-emitting device ED, for example.

As each of the transistor Tr3 and the transistor Tr4, a transistor having high resistance to voltages is preferably used. For example, a transistor with a thick gate insulating film is preferably used as each of the transistor Tr3 and the transistor Tr4. Specifically, the transistor MTCK or the transistor MTCK2 described in the above embodiment is preferably used for each of the transistor Tr3 and the transistor Tr4, for example.

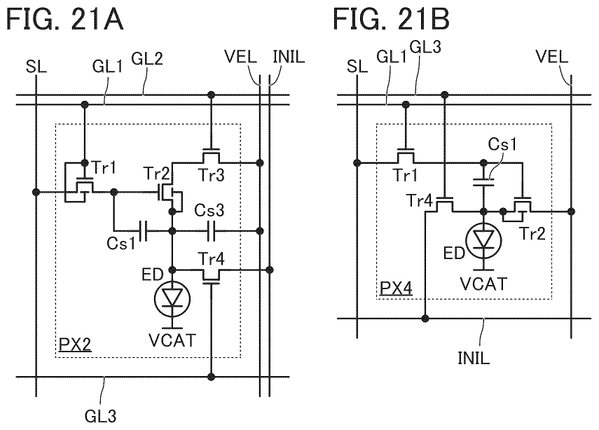

In the pixel circuit PX2, the transistor Tr1 and the transistor Tr2 may each be a transistor including a back gate. Specifically, as illustrated in FIG. 21A, the pixel circuit PX2 may have a structure in which the back gate of the transistor Tr1 is electrically connected to the gate of the transistor Tr1 and the back gate of the transistor Tr2 is electrically connected to the second terminal of the transistor Tr2. In this case, for example, the transistor MTCK2 including the back gate electrode described in Embodiment 2 is preferably used as the transistor Tr1.

### <Configuration Example 3 of Pixel Circuit>

FIG. 20C is a circuit diagram illustrating a configuration example that is applicable to the pixel circuit PX of the semiconductor device 100 described in Embodiment 1 and is different from the circuit configurations of the pixel circuits in FIG. 20A and FIG. 20B.

A pixel circuit PX3 illustrated in FIG. 20C includes the transistor Tr1, the transistor Tr2, the transistor Tr4, a transistor Tr5, the capacitor Cs1, and the light-emitting device ED, for example.

For the transistor Tr1, the transistor Tr2, the transistor Tr4, the capacitor Cs1, and the light-emitting device ED, the description of the transistor Tr1, the transistor Tr2, the transistor Tr4, the capacitor Cs1, and the light-emitting device ED included in the pixel circuit PX2 can be referred to.

Like the pixel circuit PX2, the pixel circuit PX3 has not only a function of emitting light with emission intensity corresponding to an input image signal but also a function of correcting the threshold voltage of the transistor Tr2 which is a driving transistor.

The first terminal of the transistor Tr1 is electrically connected to the wiring SL, the second terminal of the transistor Tr1 is electrically connected to the gate of the transistor Tr2, a first terminal of the transistor Tr5, and the first terminal of the capacitor Cs1, and the gate of the transistor Tr1 is electrically connected to the wiring GL1. The first terminal of the transistor Tr2 is electrically connected to the wiring VEL, and the second terminal of the transistor Tr2 is electrically connected to the second terminal of the capacitor Cs1, the first terminal of the transistor Tr4, and the anode of the light-emitting device ED. A second terminal of the transistor Tr5 is electrically connected to a wiring VBL, and a gate of the transistor Tr5 is electrically connected to a wiring GL4. The second terminal of the transistor Tr4 is electrically connected to the wiring INIL, and the gate of the transistor Tr4 is electrically connected to the wiring GL3. The cathode of the light-emitting device ED is electrically connected to the wiring VCAT.

For the wiring SL, the wiring VCAT, the wiring VEL, and the wiring INIL, the description of the wiring SL, the wiring VCAT, the wiring VEL, and the wiring INIL that are electrically connected to the pixel circuit PX2 in FIG. 20B can be referred to.

The wiring GL1, the wiring GL3, and the wiring GL4 function as wirings for transmitting selection signals from the driver circuit 11GD described in Embodiment 1 to the pixel circuit PX3.

The wiring VBL functions as a wiring for supplying a constant potential to the first terminal of the capacitor Cs1. The constant potential is preferably a potential that is input to the gate of the transistor Tr2 at the time of correcting the threshold voltage of the transistor Tr2, for example, and substantially equal to the potential supplied from the wiring VEL.

As the transistor Tr5, a transistor having high resistance to voltages is preferably used. For example, a transistor with a thick gate insulating film is preferably used as the transistor Tr5. Specifically, for example, the transistor MTCK or the transistor MTCK2 described in the above embodiment is preferably used as the transistor Tr5.

### <Configuration Example 4 of Pixel Circuit>

FIG. 20D is a circuit diagram illustrating a configuration example that is applicable to the pixel circuit PX of the semiconductor device 100 described in Embodiment 1 and is different from the circuit configurations of the pixel circuits in FIG. 20A to FIG. 20C.

A pixel circuit PX4 illustrated in FIG. 20D includes the transistor Tr1, the transistor Tr2, the transistor Tr4, the capacitor Cs1, and the light-emitting device ED, for example.

For the transistor Tr1, the transistor Tr2, the transistor Tr4, the capacitor Cs1, and the light-emitting device ED, the description of the transistor Tr1, the transistor Tr2, the transistor Tr4, the capacitor Cs1, and the light-emitting device ED included in the pixel circuit PX3 can be referred to.

Like the pixel circuit PX1, the pixel circuit PX4 has a function of emitting light with emission intensity corresponding to an input image signal.

The first terminal of the transistor Tr1 is electrically connected to the wiring SL, the second terminal of the transistor Tr1 is electrically connected to the gate of the transistor Tr2 and the first terminal of the capacitor Cs1, and the gate of the transistor Tr1 is electrically connected to the wiring GL1. The first terminal of the transistor Tr2 is electrically connected to the wiring VEL, and the second terminal of the transistor Tr2 is electrically connected to the second terminal of the capacitor Cs1, the first terminal of the transistor Tr4, and the anode of the light-emitting device ED. The second terminal of the transistor Tr4 is electrically connected to the wiring INIL, and the gate of the transistor Tr4 is electrically connected to the wiring GL3. The cathode of the light-emitting device ED is electrically connected to the wiring VCAT.

For the wiring SL, the wiring VCAT, the wiring INIL, the wiring GL1, and the wiring GL3, the description of the wiring SL, the wiring VCAT, the wiring INIL, the wiring GL1, and the wiring GL3 that are electrically connected to the pixel circuit PX3 in FIG. 20C can be referred to.

In the pixel circuit PX4, the transistor Tr2 may be a transistor including a back gate. Specifically, as illustrated in FIG. 21B, the pixel circuit PX4 may have a structure where the back gate of the transistor Tr2 is electrically connected to the second terminal of the transistor Tr2. In this case, for example, the transistor MTCK2 including the back gate electrode described in the above embodiment is preferably used as the transistor Tr2.

### <Configuration Example 5 of Pixel Circuit>

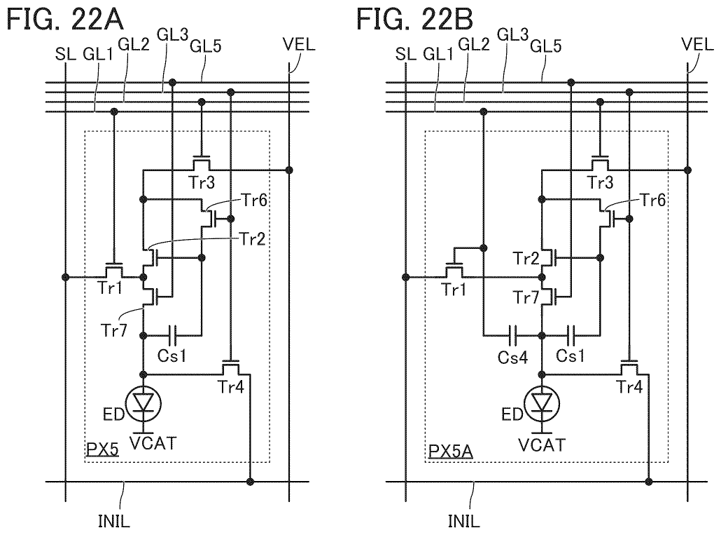

FIG. 22A is a circuit diagram illustrating a configuration example that is applicable to the pixel circuit PX of the semiconductor device 100 described in Embodiment 1 and is different from the configuration examples of the pixel circuits in FIG. 20A to FIG. 20D.

A pixel circuit PX5 illustrated in FIG. 22A includes the transistor Tr1 to the transistor Tr4, a transistor Tr6, a transistor Tr7, the capacitor Cs1, and the light-emitting device ED, for example.

For the transistor Tr1 to the transistor Tr4, the capacitor Cs1, and the light-emitting device ED, the description of the transistor Tr1 to the transistor Tr4, the capacitor Cs1, and the light-emitting device ED included in the pixel circuit PX2 can be referred to.

Like the pixel circuit PX2 and the pixel circuit PX3, the pixel circuit PX5 has not only a function of emitting light with emission intensity corresponding to an input image signal but also a function of correcting the threshold voltage of the transistor Tr2, which is a driving transistor.

The first terminal of the transistor Tr1 is electrically connected to the wiring SL, the second terminal of the transistor Tr1 is electrically connected to the first terminal of the transistor Tr2 and a first terminal of the transistor Tr7, and the gate of the transistor Tr1 is electrically connected to the wiring GL1. The second terminal of the transistor Tr2 is electrically connected to the first terminal of the transistor Tr3 and a first terminal of the transistor Tr6, and the gate of the transistor Tr2 is electrically connected to a second terminal of the transistor Tr6 and the first terminal of the capacitor Cs1. The second terminal of the transistor Tr3 is electrically connected to the wiring VEL, and the gate of the transistor Tr3 is electrically connected to the wiring GL2. A gate of the transistor Tr6 is electrically connected to the gate of the transistor Tr4 and the wiring GL3. A second terminal of the transistor Tr7 is electrically connected to the first terminal of the transistor Tr4, the second terminal of the capacitor Cs1, and the anode of the light-emitting device ED. The second terminal of the transistor Tr4 is electrically connected to the wiring INIL. The cathode of the light-emitting device ED is electrically connected to the wiring VCAT.

For the wiring SL, the wiring VCAT, the wiring VEL, and the wiring INIL, the description of the wiring SL, the wiring VCAT, the wiring VEL, and the wiring INIL that are electrically connected to the pixel circuit PX2 in FIG. 20B can be referred to.

The wiring GL1, the wiring GL2, the wiring GL3, and the wiring GL5 function as wirings for transmitting selection signals from the driver circuit 11GD described in Embodiment 1 to the pixel circuit PX5.

A transistor having high resistance to voltages is preferably used for each of the transistor Tr6 and the transistor Tr7. For example, a transistor with a thick gate insulating film is preferably used as each of the transistor Tr6 and the transistor Tr7. Specifically, for example, the transistor MTCK or the transistor MTCK2 described in Embodiment 2 is preferably used as each of the transistor Tr6 and the transistor Tr7.

Note that the configuration of the pixel circuit in the semiconductor device of one embodiment of the present invention is not limited to that of the pixel circuit PX5 illustrated in FIG. 22A, and the circuit configuration of the pixel circuit PX5 may be changed as appropriate.

For example, as in a pixel circuit PX5A illustrated in FIG. 22B, the pixel circuit PX5 in FIG. 22A may be provided with a capacitor Cs4. A first terminal of the capacitor Cs4 is electrically connected to the gate of the transistor Tr1 and the wiring GL1, and a second terminal of the capacitor Cs4 is electrically connected to the first terminal of the transistor Tr4, the second terminal of the transistor Tr7, the second terminal of the capacitor Cs1, and the anode of the light-emitting device ED.

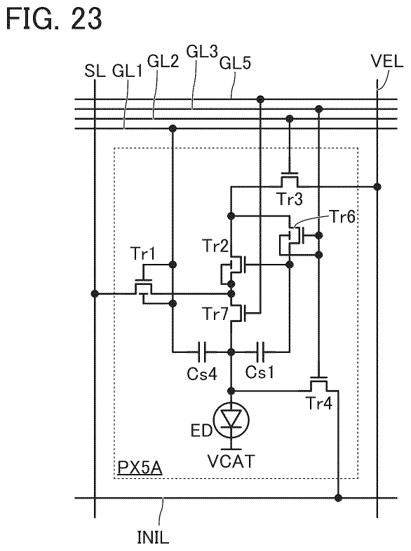

In the pixel circuit PX5A, the transistor Tr1, the transistor Tr2, and the transistor Tr6 may each be a transistor including a back gate. Specifically, as illustrated in FIG. 23, the pixel circuit PX5A may have a structure in which the back gate of the transistor Tr1 is electrically connected to the gate of the transistor Tr1, the back gate of the transistor Tr2 is electrically connected to the second terminal of the transistor Tr2, and the back gate of the transistor Tr6 is electrically connected to the gate of the transistor Tr6. In this case, for example, the transistor MTCK2 including the back gate electrode described in the above embodiment is preferably used as the transistor Tr1.

Note that this embodiment can be combined with the same embodiment and any of the other embodiments in this specification as appropriate. For example, the configurations, structures, methods, and the like described in this embodiment can be used in an appropriate combination with any of the configurations, structures, methods, and the like described in the same embodiment. For example, the configurations, structures, methods, and the like described in this embodiment can be used in an appropriate combination with any of the configurations, structures, methods, and the like described in the other embodiments and the like.

### Embodiment 5

In this embodiment, a cross-sectional structure example of the display device of one embodiment of the present invention will be described.

### <Cross-Sectional Structure Example 1 of Semiconductor Device>

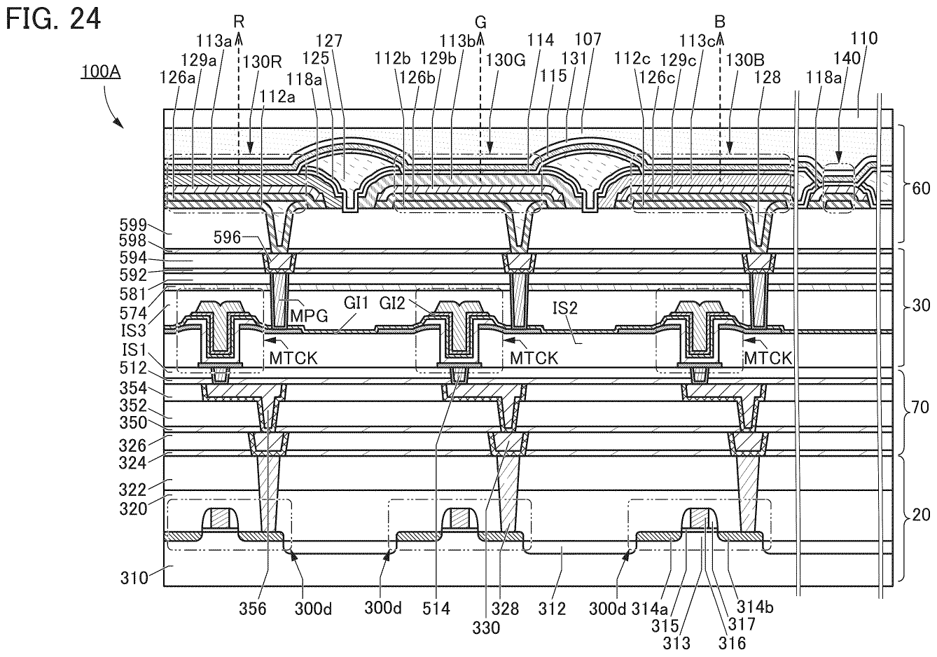

A semiconductor device 100A illustrated in FIG. 24 is a structure example of the semiconductor device 100 described in Embodiment 1 and the like in a cross-sectional view. The semiconductor device 100A has a structure provided with a pixel circuit, a driver circuit, and the like over a substrate 310. Note that in the semiconductor device 100A in FIG. 24, a wiring layer 70 is illustrated in addition to the element layer 20, the element layer 30, and the element layer 60. The wiring layer 70 is a layer provided with a wiring.

The element layer 20 includes the substrate 310, for example, and a transistor 300d is formed over the substrate 310. The wiring layer is provided above the transistor 300d, and the wiring layer 70 includes a wiring that electrically connects the transistor 300d, the transistor MTCK, a light-emitting device 130R, a light-emitting device 130G, and a light-emitting device 130B. The element layer 30 and the element layer 60 are provided above the wiring layer 70, and the element layer 30 includes the transistor MTCK and the like, for example. The element layer 60 includes the light-emitting device 130 (the light-emitting device 130R, the light-emitting device 130G, and the light-emitting device 130B in FIG. 24), for example.

The transistor 300d can be a transistor included in the element layer 20. The transistor MTCK can be a transistor included in the element layer 30. The light-emitting device 130 can be a light-emitting device included in the element layer 60.

As the substrate 310, a semiconductor substrate (e.g., a single crystal substrate containing silicon or germanium as a material) can be used, for example. Besides the semiconductor substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film containing a fibrous material can be used as the substrate 310. In this embodiment, the substrate 310 is a semiconductor substrate containing silicon as a material. Therefore, the transistor included in the element layer 20 can be a Si transistor.

The transistor 300d includes an element isolation layer 312, a conductor 316, an insulator 315, an insulator 317, a semiconductor region 313 that is part of the substrate 310, and a low-resistance region 314a and a low-resistance region 314b that function as a source region and a drain region. Thus, the transistor 300 is a Si transistor. Although FIG. 24 illustrates a structure in which one of a source and a drain of the transistor 300d is electrically connected to a conductor 330, a conductor 356, and a conductor 514, which are described later, through a conductor 328 described later, the electrical connection in the display apparatus of one embodiment of the present invention is not limited thereto. The display apparatus of one embodiment of the present invention may have a structure in which, for example, a gate of the transistor 300d is electrically connected to the conductor 514 through the conductor 328.

The transistor 300d can be a fin type when, for example, the top surface of the semiconductor region 313 and the side surface thereof in the channel width direction are covered with the conductor 316 with the insulator 315 functioning as a gate insulator therebetween. The effective channel width can be increased in the fin-type transistor 300, so that the on-state characteristics of the transistor 300 can be improved. In addition, contribution of the electric field of the gate electrode can be increased, so that the off-state characteristics of the transistor 300 can be improved. For example, the transistor 300 may have a planar structure instead of a fin-type structure.

Note that the transistor 300 may be either a p-channel transistor or an n-channel transistor. Alternatively, a plurality of the transistors 300 may be provided and both the p-channel transistor and the n-channel transistor may be used.

A region of the semiconductor region 313 where a channel is formed, a region in the vicinity thereof, and the low-resistance region 314a and the low-resistance region 314b that function as the source region and the drain region preferably contain a silicon-based semiconductor, specifically, preferably contain single crystal silicon. Alternatively, each of the regions may be formed using germanium, silicon germanium, gallium arsenide, aluminum gallium arsenide, or gallium nitride, for example. A configuration using silicon whose effective mass is controlled by applying stress to a crystal lattice and changing lattice spacing may be employed. Alternatively, the transistor 300d may be a HEMT (High Electron Mobility Transistor) using gallium arsenide and aluminum gallium arsenide, for example.

For the conductor 316 functioning as a gate electrode, a semiconductor material such as silicon containing an element that imparts n-type conductivity, such as arsenic or phosphorus, or an element that imparts p-type conductivity, such as boron or aluminum, can be used. Alternatively, for the conductor 316, a conductive material such as a metal material, an alloy material, or a metal oxide material can be used, for example.

Since a work function depends on the material of the conductor, the threshold voltage of the transistor can be adjusted by selecting the material of the conductor. Specifically, it is preferable to use one or both of titanium nitride and tantalum nitride as the material of the conductor. Moreover, in order to ensure both conductivity and embeddability, it is preferable to use stacked layers of metal materials of one or both of tungsten and aluminum for the conductor, and it is particularly preferable to use tungsten in terms of heat resistance.

The element isolation layer 312 is provided to separate a plurality of transistors formed on the substrate 310 from each other. The element isolation layer can be formed by, for example, a LOCOS (Local Oxidation of Silicon) method, an STI (Shallow Trench Isolation) method, or a mesa isolation method.

Over the transistor 300 illustrated in FIG. 24, an insulator 320 and an insulator 322 are sequentially stacked from the substrate 310 side.

For the insulator 320 and the insulator 322, one or more selected from silicon oxide, silicon oxynitride, silicon nitride oxide, silicon nitride, aluminum oxide, aluminum oxynitride, aluminum nitride oxide, and aluminum nitride can be used, for example.

Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

The insulator 322 may have a function of a planarization film for eliminating a level difference caused by the transistor 300 or the like covered with the insulator 320 and the insulator 322. For example, the top surface of the insulator 322 may be planarized by planarization treatment using a chemical mechanical polishing (CMP) method to improve planarity.

The conductor 328 connected to the transistor MTCK and the like provided above the insulator 322 is embedded in the insulator 320 and the insulator 322. Note that the conductor 328 functions as a plug or a wiring. Thus, a material that is usable for the conductor MPG can be used for the conductor 328.

In the semiconductor device 100A, the wiring layer 70 is provided over the transistor 300d. The wiring layer 70 includes, for example, an insulator 324, an insulator 326, a conductor 330, an insulator 350, an insulator 352, an insulator 354, and a conductor 356.

Over the insulator 322 and the conductor 328, the insulator 324 and the insulator 326 are stacked in this order. An opening is formed in the insulator 324 and the insulator 326 in a region overlapping with the conductor 328. In addition, the conductor 330 is embedded in the opening.

The insulator 350, the insulator 352, and the insulator 354 are stacked sequentially over the insulator 326 and the conductor 330. An opening is formed in the insulator 350, the insulator 352, and the insulator 354 in a region overlapping with the conductor 330. The conductor 356 is embedded in the opening.

The conductor 330 and the conductor 356 have a function of a plug or a wiring that is connected to the transistor 300d. Note that the conductor 330 and the conductor 356 can be provided using a material similar to that for the conductor 328 or the conductor 596. Note that like an insulator 592, for example, the insulator 324 and the insulator 350 are preferably formed using an insulator having a barrier property against one or more selected from hydrogen, oxygen, and water. Like an insulator 594, each of the insulator 326, the insulator 352, and the insulator 354 is preferably formed using an insulator having a relatively low dielectric constant to reduce parasitic capacitance generated between wirings. Each of the insulator 326, the insulator 352, and the insulator 354 has a function of an interlayer insulating film and a planarization film. Furthermore, each of the insulator 326, the insulator 352, and the insulator 354 preferably includes a conductor having a barrier property against one or more selected from hydrogen, oxygen, and water.

For the conductor having a barrier property against hydrogen, tantalum nitride is preferably used, for example. The use of a stack including tantalum nitride and tungsten that has high conductivity can inhibit diffusion of hydrogen from the transistor 300d while the conductivity of a wiring is kept. In that case, a tantalum nitride layer having a barrier property against hydrogen is preferably in contact with the insulator 350 having a barrier property against hydrogen.

An insulator 512 is provided over the insulator 354 and the conductor 356. An insulator IS1 is provided over the insulator 512. The conductor 514 functioning as a plug or a wiring is embedded in the insulator IS1 and the insulator 512. Accordingly, one of a source and a drain of the transistor MTCK is electrically connected to one of the source and the drain of the transistor 300d. Note that the conductor 514 can be formed using any of the materials usable for the conductor MPG, for example.

The transistor MTCK is provided over the insulator IS1 and the conductor 514. An insulator 574 is formed over the transistor MTCK, and an insulator 581 is formed over the insulator 574. The conductive layer MPG functioning as a plug or a wiring is embedded in the insulator IS3, the insulator 574, and the insulator 581. Embodiment 2 can be referred to for the insulator, the conductor, and the semiconductor around the transistor MTCK.

The insulator IS3 is formed above the transistor MTCK. The insulator 574 and the insulator 581 are stacked in this order over the insulator IS3.

It is preferable that the insulator 574 have a function of inhibiting diffusion of impurities such as water and hydrogen (e.g., one or both of a hydrogen atom and a hydrogen molecule). In other words, the insulator 574 preferably functions as a barrier insulating film that inhibits the entry of the impurities into the transistor MTCK. In addition, it is preferable that the insulator 574 have a function of inhibiting diffusion of oxygen (e.g., one or both of an oxygen atom and an oxygen molecule). For example, the insulator 574 preferably has the property of being less likely to transmit oxygen than the insulator IS2 and the insulator IS3.

Thus, the insulator 574 preferably functions as a barrier insulating film that inhibits diffusion of impurities such as water and hydrogen. Accordingly, it is preferable to use, for the insulator 574, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the impurities are unlikely to pass). Alternatively, it is preferable to use an insulating material having a function of inhibiting diffusion of oxygen (e.g., one or both of an oxygen atom and an oxygen molecule) (an insulating material through which the oxygen is unlikely to pass).

An insulator having a function of inhibiting the passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides containing aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the insulator 574. Accordingly, it is possible to inhibit diffusion of impurities such as water and hydrogen to the transistor MTCK from a portion above the insulator 574. Alternatively, it is possible to inhibit diffusion of oxygen contained in the insulator IS3 and the like to a portion above the insulator 574.

The insulator 581 is preferably a film functioning as an interlayer film and having a lower permittivity than the insulator 574. When a material with low permittivity is used for an interlayer film, parasitic capacitance generated between wirings can be reduced. For example, the dielectric constant of the insulator 581 is preferably lower than 4, further preferably lower than 3. The dielectric constant of the insulator 581 is, for example, preferably 0.7 times or less, further preferably 0.6 times or less the dielectric constant of the insulator 574. When a material with a low dielectric constant is used for the insulator 581, the parasitic capacitance generated between wirings can be reduced.

The concentration of impurities such as water and hydrogen in the insulator 581 is preferably reduced. In such a case, the insulator 581 can be formed using silicon oxide, silicon oxynitride, silicon nitride oxide, or silicon nitride, for example. For the insulator 581, for example, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Moreover, for the insulator 581, a resin can be used. A material combined with any of the above insulating materials as appropriate may be used for the insulator 581.

The insulator 592 and the insulator 594 are sequentially stacked over the insulator 574 and the insulator 581.

For the insulator 592, it is preferable to use an insulating film having a barrier property (referred to as a barrier insulating film) which prevents diffusion of impurities such as water and hydrogen from the substrate 310 or the transistor MTCK to a region above the insulator 592 (e.g., the region where the light-emitting device 130R, the light-emitting device 130G, the light-emitting device 130B, and the like are provided). Accordingly, for the insulator 592, it is preferable to use an insulating material that has a function of inhibiting diffusion of impurities such as a hydrogen atom, a hydrogen molecule, and a water molecule (through which the above impurities are less likely to pass). Furthermore, depending on the situation, for the insulator 592, it is preferable to use an insulating material that has a function of inhibiting diffusion of impurities such as a nitrogen atom, a nitrogen molecule, a nitrogen oxide molecule (e.g., N₂O, NO, and NO₂), and a copper atom (through which the above oxygen is less likely to pass). It is preferable that the insulator 592 have a function of inhibiting diffusion of oxygen (e.g., one or both of an oxygen atom and an oxygen molecule).

For the film having a barrier property against hydrogen, silicon nitride formed by a CVD method can be used, for example.

The amount of released hydrogen can be analyzed by thermal desorption spectroscopy (TDS), for example. The amount of hydrogen released from the insulator 324 that is converted into hydrogen atoms per area of the insulator 324 is less than or equal to 10×10¹⁵ atoms/cm², preferably less than or equal to 5×10¹⁵ atoms/cm² in the TDS in a film-surface temperature range of 50° C. to 500° C., for example.

Like the insulator 581, the insulator 594 is preferably an interlayer film with a low permittivity. Thus, the insulator 594 can be formed using any of the materials usable for the insulator 581.

Note that the permittivity of the insulator 594 is preferably lower than that of the insulator 592. For example, the dielectric constant of the insulator 594 is preferably lower than 4, further preferably lower than 3. The dielectric constant of the insulator 594 is, for example, preferably 0.7 times or less, further preferably 0.6 times or less the dielectric constant of the insulator 592. When a material with a low permittivity is used for the insulator 594, the parasitic capacitance generated between wirings can be reduced.

The conductor MPG functioning as a plug or a wiring is embedded in the insulator GI1 and the insulator IS3, and the conductor 596 functioning as a plug or a wiring is embedded in the insulator 592 and the insulator 594. In particular, the conductor MPG and the conductor 596 are electrically connected to the light-emitting device or the like provided above the insulator 594. A plurality of conductors each having a function of a plug or a wiring are collectively denoted by the same reference numeral in some cases. Moreover, in this specification and the like, a wiring and a plug connected to the wiring may be a single component. That is, part of a conductor functions as a wiring in some cases and part of the conductor functions as a plug in other cases.

As a material of each of plugs and wirings (e.g., the conductor MPG and the conductor 596), a single layer or a stacked layer of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used for formation. The use of a low-resistance conductive material can reduce wiring resistance.

An insulator 598 and an insulator 599 are sequentially formed over the insulator 594 and the conductor 596.

Like the insulator 592, for example, the insulator 598 is preferably formed using an insulator having a barrier property against one or more selected from hydrogen, oxygen, and water. Like the insulator 594, the insulator 599 is preferably formed using an insulator having a relatively low dielectric constant to reduce parasitic capacitance generated between wirings. The insulator 599 has functions of an interlayer insulating film and a planarization film.

The light-emitting device 130 and a connection portion 140 are formed over the insulator 599.

The connection portion 140 is referred to as a cathode contact portion in some cases, and is electrically connected to cathode electrodes of the light-emitting device 130R, the light-emitting device 130G, and the light-emitting device 130B. The connection portion 140 in FIG. 24 includes one or more conductors selected from a conductor 112a to a conductor 112c to be described later, at least one of a conductor 126a to a conductor 126c to be described later, one or more conductors selected from a conductor 129a to a conductor 129c to be described later, a common layer 114 to be described later, and a common electrode 115 to be described later.

Note that the connection portion 140 may be provided to surround four sides of the display portion in the plan view, or may be provided in the display portion (e.g., between adjacent light-emitting devices 130) (not illustrated).

The light-emitting device 130R includes the conductor 112a, the conductor 126a over the conductor 112a, and the conductor 129a over the conductor 126a. All of the conductor 112a, the conductor 126a, and the conductor 129a can be referred to as a pixel electrode, or one or two of them can be referred to as a pixel electrode. The light-emitting device 130G includes the conductor 112b, the conductor 126b over the conductor 112b, and the conductor 129b over the conductor 126b. As in the light-emitting device 130R, all of the conductor 112b, the conductor 126b, and the conductor 129b can be referred to as a pixel electrode, or one or two of them can be referred to as a pixel electrode. The light-emitting device 130B includes the conductor 112c, the conductor 126c over the conductor 112c, and the conductor 129c over the conductor 126c. As in the light-emitting device 130R and the light-emitting device 130G, all of the conductor 112c, the conductor 126c, and the conductor 129c can be referred to as a pixel electrode, or one or two of them can be referred to as a pixel electrode.

For the conductor 112a to the conductor 112c and the conductor 126a to the conductor 126c, a conductive layer functioning as a reflective electrode can be used, for example. For the conductive layer functioning as a reflective electrode, a conductor with high visible-light reflectance such as silver, aluminum, or an alloy film of silver (Ag), palladium (Pd), and copper (Cu) (an Ag—Pd—Cu (APC) film) can be used. The conductor 112a to the conductor 112c and the conductor 126a to the conductor 126c can each be a stacked-layer film in which a pair of titanium films sandwich aluminum (a film in which Ti, Al, and Ti are stacked in this order), or a stacked-layer film in which a pair of indium tin oxide films sandwich silver (a film in which ITO, Ag, and ITO are stacked in this order).

For example, a conductive layer functioning as a reflective electrode may be used for the conductor 112a to the conductor 112c, and a conductor with a high light-transmitting property may be used for the conductor 126a to the conductor 126c. Examples of the conductor with a high light-transmitting property include an alloy of silver and magnesium and indium tin oxide (sometimes referred to as ITO).

A conductive layer functioning as a transparent electrode can be used for the conductor 129a to the conductor 129c. For the conductive layer functioning as a transparent electrode, for example, the above-described conductor with a high light-transmitting property can be used.

A microcavity structure may be provided in the light-emitting device 130 to be described in detail later. The microcavity structure refers to a structure in which the distance between the bottom surface of the light-emitting layer and the top surface of a lower electrode is set to a thickness depending on a wavelength of color of light emitted from the light-emitting layer. In that case, a light-transmitting and light-reflective conductive material is preferably used for the conductor 129a to the conductor 129c serving as an upper electrode, and a light-reflective conductive material is preferably used for the conductor 112a to the conductor 112c and the conductor 126a to the conductor 126c which serve as lower electrodes.

The microcavity structure refers to a structure in which the optical distance between the lower electrode and the light-emitting layer is adjusted to be (2n−1)λ/4 (n is a natural number greater than or equal to 1, and 2 is a wavelength of emitted light to be amplified). Thus, light that is reflected back by the lower electrode (reflected light) considerably interferes with light that directly enters the upper electrode from the light-emitting layer (incident light). Accordingly, the phases of the reflected light and the incident light each having the wavelength λ can be aligned with each other, and the light emitted from the light-emitting layer can be further amplified. Meanwhile, in the case where the reflected light and the incident light each have a wavelength other than the wavelength λ, their phases are not aligned with each other, resulting in attenuation without resonation.

The conductor 112a is connected to the conductor 596 embedded in the insulator 594 through an opening formed in the insulator 599. The end portion of the conductor 126a is positioned on the outer side of the end portion of the conductor 112a. The end portion of the conductor 126a and the end portion of the conductor 129a are aligned or substantially aligned with each other.

Since the conductor 112b, the conductor 126b, and the conductor 129b of the light-emitting device 130G and the conductor 112c, the conductor 126c, and the conductor 129c of the light-emitting device 130B are similar to the conductor 112a, the conductor 126a, and the conductor 129a of the light-emitting device 130R, detailed description is omitted.

Depression portions are formed in the conductor 112a, the conductor 112b, and the conductor 112c to cover the openings provided in the insulator 599. A layer 128 is embedded in the depression portions.

The layer 128 has a function of filling the depression portions of the conductor 112a to the conductor 112c. The conductor 126a to the conductor 126c electrically connected to the conductor 112a to the conductor 112c, respectively, are provided over the conductor 112a to the conductor 112c and the layer 128. Thus, regions overlapping with the depression portions of the conductor 112a to the conductor 112c can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used for the layer 128. For the layer 128, an acrylic resin, a polyimide resin, an epoxy resin, a polyamide resin, a polyimide-amide resin, a siloxane resin, a benzocyclobutene-based resin, a phenol resin, or a precursor of any of these resins can be used, for example. A photosensitive resin can also be used for the layer 128. As the photosensitive resin, a positive material or a negative material is given.

When a photosensitive resin is used, the layer 128 can be formed through only light-exposure and development steps, reducing the influence of dry etching or wet etching on the surfaces of the conductor 112a, the conductor 112b, and the conductor 112c. When the layer 128 is formed using a negative photosensitive resin, the layer 128 can sometimes be formed using the same photomask (light-exposure mask) as the photomask used for forming the opening in the insulator 599.

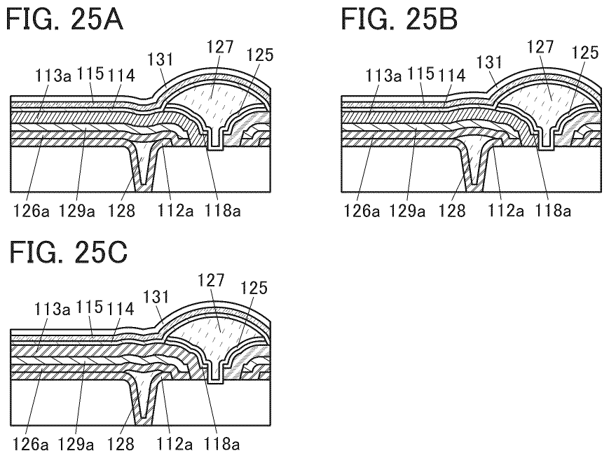

Although FIG. 24 illustrates an example where the top surface of the layer 128 includes a flat portion, the shape of the layer 128 is not particularly limited. As illustrated in FIG. 25A, the middle and the vicinity of the top surface of the layer 128 may be concave in the cross section. Alternatively, as illustrated in FIG. 25B, the middle and the vicinity of the layer 128 may be convex in the cross section. As illustrated in FIG. 25C, the middle and the vicinity of the layer 128 may be concave and convex in the cross section.

The light-emitting device 130R includes a first layer 113a, the common layer 114 over the first layer 113a, and the common electrode 115 over the common layer 114. The light-emitting device 130G includes a second layer 113b, the common layer 114 over the second layer 113b, and the common electrode 115 over the common layer 114. The light-emitting device 130B includes a third layer 113c, the common layer 114 over the third layer 113c, and the common electrode 115 over the common layer 114.

The first layer 113a is formed to cover the top surface and side surface of the conductor 126a and the top surface and side surface of the conductor 129a. Similarly, the second layer 113b is formed to cover the top surface and side surface of the conductor 126b and the top surface and side surface of the conductor 129b. Similarly, the third layer 113c is formed to cover the top surface and side surface of the conductor 126c and the top surface and side surface of the conductor 129c. Accordingly, regions provided with the conductor 126a, the conductor 126b, and the conductor 126c can be entirely used as the light-emitting regions of the light-emitting device 130R, the light-emitting device 130G, and the light-emitting device 130B, respectively, increasing the aperture ratio of the pixels.

In the light-emitting device 130R, the first layer 113a and the common layer 114 can be collectively referred to as an EL layer. Similarly, in the light-emitting device 130G, the second layer 113b and the common layer 114 can be collectively referred to as an EL layer. Similarly, in the light-emitting device 130B, the third layer 113c and the common layer 114 can be collectively referred to as an EL layer.

There is no particular limitation on the structure of the light-emitting device in this embodiment, and the light-emitting device can have a single structure or a tandem structure.

The first layer 113a, the second layer 113b, and the third layer 113c each have an island shape after being processed by a photolithography method. At each of end portions of the first layer 113a, the second layer 113b, and the third layer 113c, an angle between the top surface and side surface is approximately 90°. By contrast, for example, an organic film formed using an FMM (Fine Metal Mask) tends to have a thickness that gradually decreases with decreasing distance to an end portion, and has the top surface forming a slope in an area extending greater than or equal to 1 μm and less than or equal to 10 μm from the end portion, for example; thus, such an organic film has a shape whose top surface and side surface cannot be easily distinguished from each other.

The top surface and side surface of each of the first layer 113a, the second layer 113b, and the third layer 113c are clearly distinguished from each other. Accordingly, as for the first layer 113a and the second layer 113b which are adjacent to each other, one of the side surfaces of the first layer 113a and one of the side surfaces of the second layer 113b face to each other. This applies to a combination of any of the first layer 113a, the second layer 113b, and the third layer 113c.

The first layer 113a, the second layer 113b, and the third layer 113c each include at least a light-emitting layer. For example, a structure is preferable in which the first layer 113a includes a light-emitting layer that emits red light, the second layer 113b includes a light-emitting layer that emits green light, and the third layer 113c includes a light-emitting layer that emits blue light. Other than the above colors, cyan, magenta, yellow, or white can be employed for the light-emitting layers.

The first material layer 113a, the second material layer 113b, and the third material layer 113c each preferably include a light-emitting layer and a carrier-transport layer (an electron-transport layer or a hole-transport layer) over the light-emitting layer. Since surfaces of the first layer 113a, the second layer 113b, and the third layer 113c may be exposed in the manufacturing process of the display apparatus, providing the carrier-transport layer over the light-emitting layers inhibits the light-emitting layers from being exposed on the outermost surface, so that damage to the light-emitting layers can be reduced. Accordingly, the reliability of the light-emitting devices can be improved.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting device 130R, the light-emitting device 130G, and the light-emitting device 130B.

The common electrode 115 is shared by the light-emitting device 130R, the light-emitting device 130G, and the light-emitting device 130B. As illustrated in FIG. 24, the common electrode 115 shared by the plurality of light-emitting devices is electrically connected to a conductor included in the connection portion 140.

The insulator 125 preferably has a function of a barrier insulating layer against one or both of water and oxygen. Alternatively, the insulator 125 preferably has a function of inhibiting diffusion of one or both of water and oxygen. Alternatively, the insulator 125 preferably has a function of capturing or fixing (also referred to as gettering) one or both of water and oxygen. When the insulator 125 has a function of a barrier insulating layer or a gettering function, entry of impurities (typically, one or both of water and oxygen) that would diffuse into the light-emitting devices from the outside can be inhibited. With this structure, a highly reliable light-emitting device and a highly reliable display panel can be provided.

The insulator 125 preferably has a low impurity concentration. Accordingly, degradation of the EL layer, which is caused by entry of impurities into the EL layer from the insulator 125, can be inhibited. In addition, when the impurity concentration is reduced in the insulator 125, a barrier property against one or both of water and oxygen can be increased. For example, it is desirable that one or both of the hydrogen concentration and the carbon concentration in the insulator 125 be sufficiently low.

As the insulator 127, an insulating layer containing an organic material can be favorably used. As the organic material, a photosensitive organic resin is preferably used; for example, a photosensitive resin composition containing an acrylic resin may be used. The viscosity of the material of the insulator 127 is greater than or equal to 1 cP and less than or equal to 1500 cP, and is preferably greater than or equal to 1 cP and less than or equal to 12 cP. By setting the viscosity of the material of the insulator 127 in the above-described range, the insulator 127 having a tapered shape, which is to be described later, can be formed relatively easily. Note that in this specification and the like, an acrylic resin refers to not only a polymethacrylic acid ester or a methacrylic resin, but also all the acrylic-based polymers in a broad sense in some cases.

In this specification and the like, a tapered shape refers to a shape such that at least part of a side surface of a component is inclined to a substrate surface. For example, a tapered shape preferably includes a region where the angle between the inclined side surface and the substrate surface (such an angle is also referred to as a taper angle) is less than 90°.

Note that the organic material that can be used for the insulator 127 is not limited to the above as long as the insulator 127 has a tapered side surface as described later. For the insulator 127, an acrylic resin, a polyimide resin, an epoxy resin, an imide resin, a polyamide resin, a polyimide-amide resin, a silicone resin, a siloxane resin, a benzocyclobutene-based resin, a phenol resin, or precursors of these resins can be used in some cases, for example. Alternatively, an organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be employed for the insulator 127 in some cases. For the insulator 127, for example, a photoresist can be used as the photosensitive resin in some cases. Note that as the photosensitive resin, a positive material or a negative material can be used.

For the insulator 127, a material absorbing visible light may be used. When the insulator 127 absorbs light from the light-emitting device, leakage of light (stray light) from the light-emitting device to the adjacent light-emitting device through the insulator 127 can be inhibited. Thus, the display quality of the display panel can be improved. Since the display quality of the display panel can be improved without using a polarizing plate, the weight and thickness of the display panel can be reduced.

Examples of the material absorbing visible light include materials containing pigment of black or the like, materials containing dye, light-absorbing resin materials (e.g., polyimide), and resin materials that can be used for color filters (color filter materials). A resin material obtained by stacking or mixing color filter materials of two colors or three or more colors is particularly preferably used to enhance the effect of blocking visible light. Specifically, mixing color filter materials of three or more colors enables formation of a black or nearly black resin layer.

For example, the insulator 127 can be formed by a wet deposition method such as spin coating, dipping, spray coating, ink-jetting, dispensing, screen printing, offset printing, doctor blade coating, slit coating, roll coating, curtain coating, or knife coating. Specifically, an organic insulating film that is to be the insulator 127 is preferably formed by spin coating.

The insulator 127 is formed at a temperature lower than the heat resistance temperature of the EL layer. The typical substrate temperature in formation of the insulator 127 is lower than or equal to 200° C., preferably lower than or equal to 180° C., further preferably lower than or equal to 160° C., still further preferably lower than or equal to 150° C., yet still further preferably lower than or equal to 140° C.

The description is made below on the structure of the insulator 127 or the like using the structure of the insulator 127 between the light-emitting device 130R and the light-emitting device 130G as an example. Note that the same applies to the insulator 127 between the light-emitting device 130G and the light-emitting device 130B, the insulator 127 between the light-emitting device 130B and the light-emitting device 130R, and the like. The description made below sometimes using an end portion of the insulator 127 over the second layer 113b as an example applies to an end portion of the insulator 127 over the first layer 113a and an end portion of the insulator 127 over the third layer 113c.

In a cross-sectional view of the display apparatus, the side surface of the insulator 127 preferably has a tapered shape with the taper angle θ1. The taper angle θ1 is an angle formed by the side surface of the insulator 127 and the substrate surface. Note that the taper angle θ1 is not limited to the angle with the substrate surface, and may be an angle formed by the side surface of the insulator 127 and the top surface of the flat portion of the insulator 125 or the top surface of the flat portion of the second layer 113b. When the side surface of the insulator 127 has a tapered shape, the side surface of the insulator 125 and the side surface of the mask layer 118a also have a tapered shape in some cases.

The taper angle θ1 of the insulator 127 is less than 90°, preferably less than or equal to 60°, and further preferably less than or equal to 45°. Such a tapered shape of the end portion of the side surface of the insulator 127 can prevent disconnection, local thinning, or the like from occurring in the common layer 114 and the common electrode 115 which are provided over the end portion of the side surface of the insulator 127, leading to film formation with good coverage. The common layer 114 and the common electrode 115 can have improved in-plane thickness uniformity in this manner, whereby the display apparatus can have improved display quality.

The top surface of the insulator 127 preferably has a convex shape in a cross-sectional view of the display apparatus. The top surface of the insulator 127 preferably has a convex shape that bulges gradually toward the center. The insulator 127 preferably has a shape such that the projecting portion at the center portion of the top surface is connected smoothly to the tapered portion of the end portion of the side surface. When the insulator 127 has such a shape, the common layer 114 and the common electrode 115 can be deposited with good coverage over the whole the insulator 127.

The insulator 127 is formed in a region between two EL layers (e.g., a region between the first layer 113a and the second layer 113b). At this time, part of the insulator 127 is placed at a position sandwiched between an end portion of the side surface of one of the EL layers (e.g., the first layer 113a) and an end portion of the side surface of the other of the EL layers (e.g., the second layer 113b).

One end portion of the insulator 127 preferably overlaps with the conductor 126a serving as a pixel electrode, and the other end portion of the insulator 127 preferably overlaps with the conductor 126b serving as a pixel electrode. With such a structure, the end portion of the insulator 127 can be formed over a substantially flat region of the first layer 113a (the second layer 113b). This makes it relatively easy to process the tapered shape of the insulator 127 as described above.

By providing the insulator 127 and the like in the above manner, a disconnected portion and a locally thinned portion can be prevented from being formed in the common layer 114 and the common electrode 115 from a substantially flat region in the first layer 113a to a substantially flat region in the second layer 113b. Thus, between the light-emitting devices, a connection defect caused by the disconnected portion and an increase in electric resistance caused by the locally thinned portion can be inhibited from occurring in the common layer 114 and the common electrode 115.

In the display apparatus of this embodiment, the distance between the light-emitting devices can be short. Specifically, the distance between the light-emitting devices, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where a distance between two adjacent island-shaped EL layers is less than or equal to 1 μm, preferably less than or equal to 0.5 μm (500 nm), further preferably less than or equal to 100 nm. The distance between light-emitting devices is shortened in this manner, whereby a display apparatus with high resolution and a high aperture ratio can be provided.

A protective layer 131 is provided over the light-emitting device 130. The protective layer 131 is a film serving as a passivation film for protecting the light-emitting devices 130. Provision of the protective layer 131 covering the light-emitting device can inhibit an impurity such as water and oxygen from entering the light-emitting device, and increase the reliability of the light-emitting device 130. For the protective layer 131, aluminum oxide, silicon nitride, or silicon nitride oxide can be used, for example.

The protective layer 131 and a substrate 110 are bonded to each other with an adhesive layer 107. A solid sealing structure, a hollow sealing structure, or the like can be employed to seal the light-emitting devices. In FIG. 24, a solid sealing structure is employed in which a space between the substrate 310 and the substrate 110 is filled with the adhesive layer 107. Alternatively, a hollow sealing structure may be employed, in which the space is filled with an inert gas (e.g., nitrogen or argon). Here, the adhesive layer 107 may be provided not to overlap with the light-emitting devices. The space may be filled with a resin other than the frame-shaped adhesive layer 107.

For the adhesive layer 107, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. A two-liquid-mixture-type resin may be used. An adhesive sheet may be used.

The semiconductor device 100A has a top-emission structure. Light from the light-emitting device is emitted toward the substrate 110 side. Thus, for the substrate 110, a material having a high visible-light-transmitting property is preferably used. For example, a substrate having a high visible-light-transmitting property may be selected as the substrate 110 from substrates usable as the substrate 310. The pixel electrode contains a material that reflects visible light, and a counter electrode (the common electrode 115) contains a material that transmits visible light.

Note that the display apparatus of one embodiment of the present invention may be not a top-emission display apparatus but a bottom-emission display apparatus where light from the light-emitting device is emitted to the substrate 310 side. In that case, a substrate having a high visible-light-transmitting property is selected as the substrate 310.

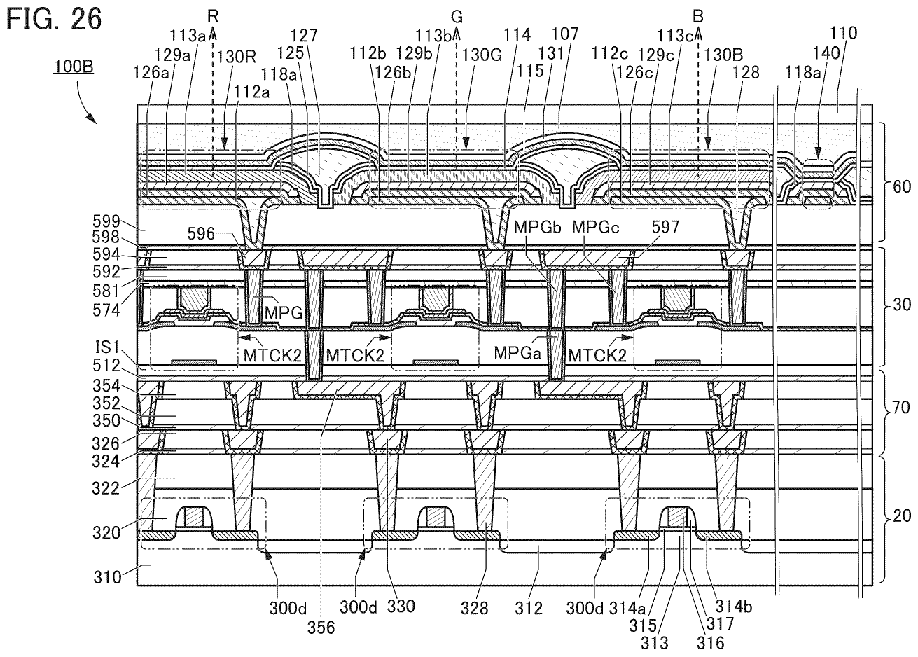

Although the element layer 30 of the semiconductor device 100A in FIG. 24 includes the transistor MTCK, the display device of one embodiment of the present invention may include the transistor MTCK2 instead of the transistor MTCK as in the semiconductor device 100B illustrated in FIG. 26.

In the semiconductor device 100B illustrated in FIG. 26, in order to electrically connect the transistor MTCK2 and the transistor 300d, a conductor MPGa, a conductor MPGb, a conductor MPGc, and a conductor 597 functioning as plugs or wirings are embedded in insulators around the transistor MTCK2. Specifically, the conductor MPGa is embedded in the insulator IS1, the conductor MPGb and the conductor MPGc are embedded in the insulator GI1, and the conductor 597 is embedded in the insulator 592 and the insulator 594. Thus, the transistor 300d and the transistor MTCK2 are electrically connected to each other through the conductor 328, the conductor 330, the conductor 356, the conductor MPGa, the conductor MPGb, the conductor 597, and the conductor MPGc.

Note that the conductor MPGa to the conductor MPGc can be formed using any of the materials usable for the conductors MPG. A material that is usable for the conductor 596 can be used for the conductor 597, for example.

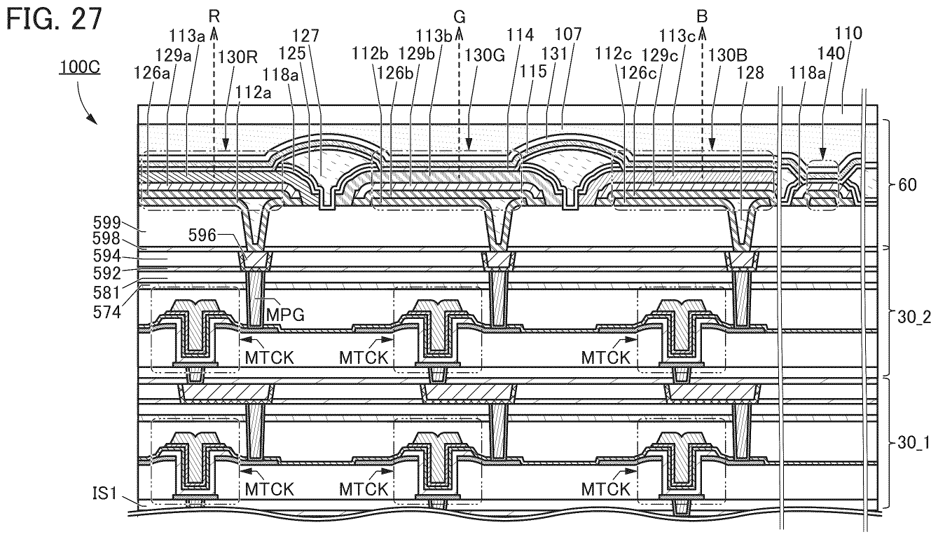

The element layer 30 of the semiconductor device 100A in FIG. 24 has a structure in which the transistor MTCK is included in one layer; however, the display device of one embodiment of the present invention may have a structure, as in a semiconductor device 100C illustrated in FIG. 27, in which the element layer 30_1 and the element layer 30_2 corresponding to a plurality of element layers 30 are provided and the transistor MTCK is included in each of the plurality of element layers 30.

Although the element layers 30_1 and 30_2 and the element layer 60 are selectively illustrated in the semiconductor device 100C in FIG. 27 where the element layer 20 and the like are omitted, the wiring layer 70 and the element layer 20 are provided below the element layer 30_1.

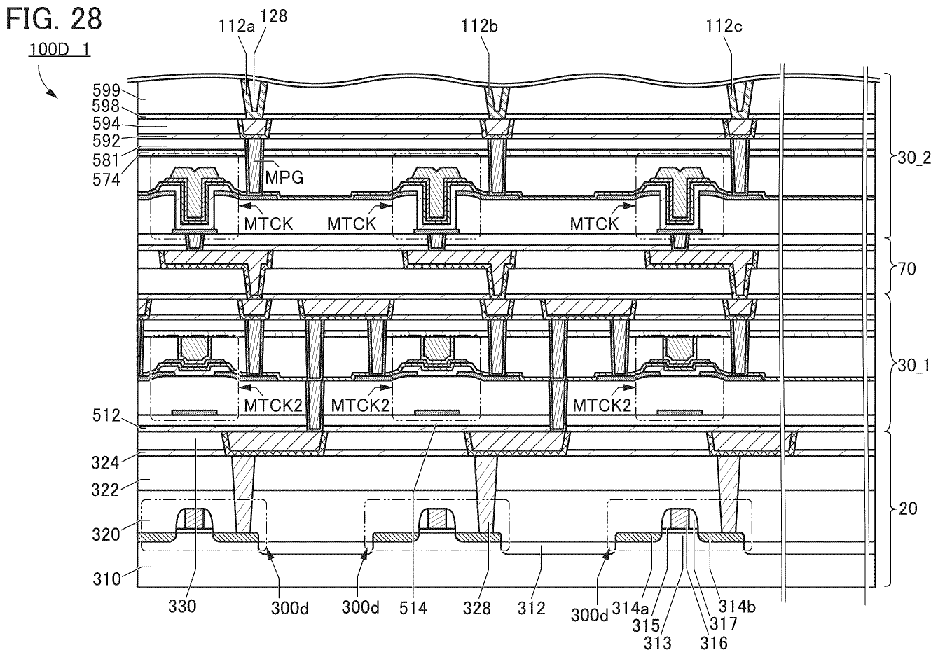

The element layer 30 of the semiconductor device 100A in FIG. 24 can be provided in a plurality of layers. For example, as in a semiconductor device 100D_1 illustrated in FIG. 28, the element layer 30_1 including the transistor MTCK2 may be provided above the element layer 20, and the element layer 30_2 including the transistor MTCK may be provided thereover with the wiring layer 70 sandwiched therebetween.

Although the element layers 30_1 and 30_2 and the element layer 20 are selectively illustrated in the semiconductor device 100D_1 in FIG. 28 where the element layer 60 and the like are omitted, the element layer 60 is provided above the element layer 30_2.

The structure illustrated in FIG. 28 enables the density of transistors per unit area to be increased. Accordingly, the display quality of the semiconductor device 100 can be increased. In addition, element layers including transistors with different transistor shapes can be stacked with use of the element layer 30_1 and the element layer 30_2. Furthermore, element layers including transistors having a difference in size such as a channel length and a channel width can be stacked with use of the element layer 30_1 and the element layer 30_2.

For example, the element layer 30_1 is an element layer that includes a transistor functioning as a switch among transistors included in the pixel circuit, and the element layer 30_2 is a transistor that allows current to flow through the light-emitting device among the transistors included in the pixel circuit. In that case, in the transistor MTCK included in the element layer 30_2, a conductor functioning as one of a source electrode and a drain electrode is placed on the side (on the lower layer side) where the element layer 30_1 is provided, and a conductor functioning as the other of the source electrode and the drain electrode is placed on the side (on the upper layer side) where the element layer 60 (not illustrated) is provided. Thus, electrical connection between elements included in the display portion can be facilitated.

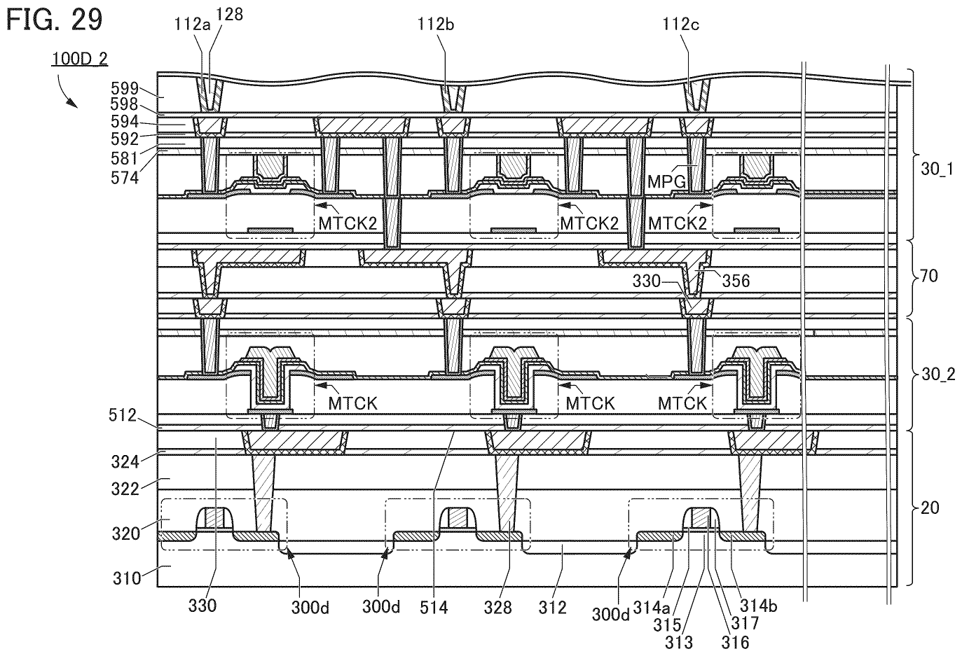

The element layer 30 of the semiconductor device 100A in FIG. 24 may have a structure as in a semiconductor device 100D_2 illustrated in FIG. 29 in which the element layer 30_2 including the transistor MTCK is provided above the element layer 20 and the element layer 30_1 including the transistor MTCK2 is provided over the element layer 30_2 with the wiring layer 70 sandwiched therebetween.

Although the element layers 30_1 and 30_2 and the element layer 20 are selectively illustrated in the semiconductor device 100D_2 in FIG. 29 where the element layer 60 and the like are omitted, as in the case of FIG. 28, the element layer 60 is provided above the element layer 30_1.

The structure in FIG. 29 enables the density of transistors per unit area to be increased. Accordingly, the display quality of the semiconductor device 100D_2 can be increased. In addition, element layers including transistors with different transistor shapes can be stacked with use of the element layer 30_1 and the element layer 30_2. Furthermore, element layers including transistors having a difference in size such as a channel length and a channel width can be stacked with use of the element layer 30_1 and the element layer 30_2.

For example, the element layer 30_1 is a transistor (driving transistor) that allows current to flow through the light-emitting device among the transistors included in the pixel circuit, and the element layer 30_2 is an element layer that includes a transistor (switching transistor) functioning as a switch among the transistors included in the pixel circuit. In this case, the transistor MTCK2 included in the element layer 30_1 is placed on the side (on the upper layer side) where the element layer 60 (not illustrated) is provided. Thus, electrical connection between elements included in the display portion can be facilitated.

Note that in the structure example of the semiconductor device illustrated in FIG. 28 and FIG. 29, the wiring layer 70 is provided between the element layer 30_1 and the element layer 30_2. With this structure, a clock signal, a power supply potential, and the like that are supplied to the element layer 30_1 and the element layer 30_2 above and below the wiring layer 70 can be supplied through a common wiring or the like.

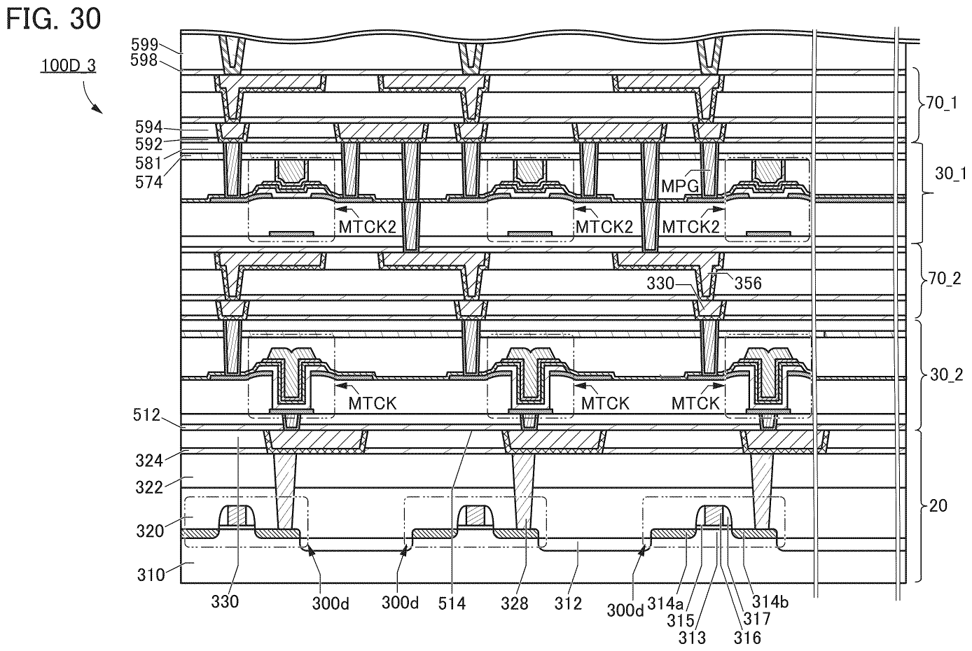

As another structure example of the semiconductor device, the element layer 30_1 and the element layer 30_2 of the semiconductor device 100D_1 illustrated in FIG. 28 may have a structure, as in a semiconductor device 100D_3 illustrated in FIG. 30, in which the element layer 30_1 is provided with the wiring layer 70_1 thereabove and the element layer 30_2 is provided with the wiring layer 70_2 thereabove. With this structure, wirings for supplying signals can be provided separately for the element layer 30_1 and the element layer 30_2.

The transistors included in the element layer 30_1 and the element layer 30_2 may have the same structure; transistors even provided in the same element layer may have different structures depending on the circuit configuration.

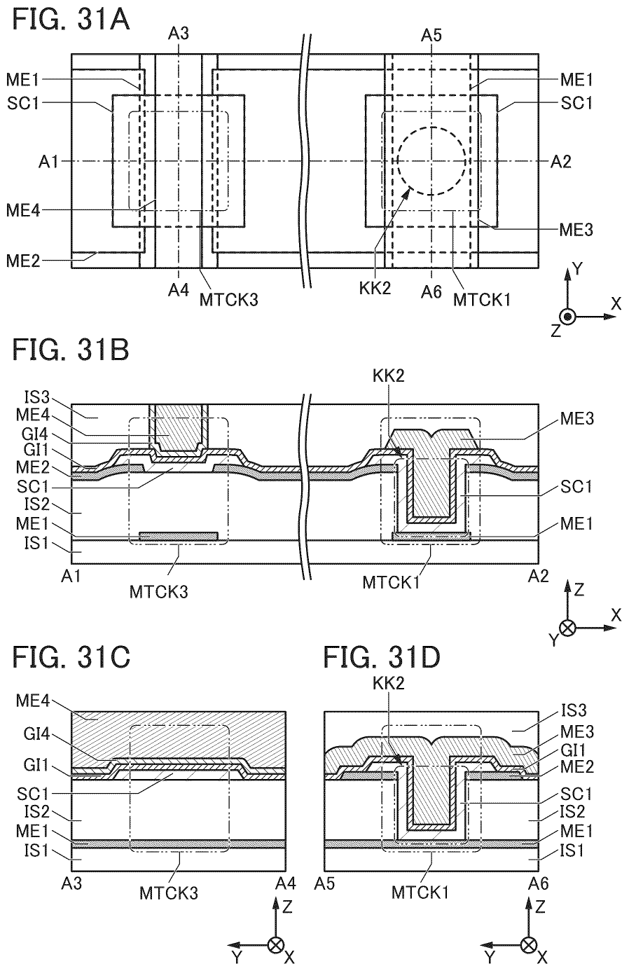

Note that the transistor MTCK illustrated in FIG. 12A to FIG. 12C can be formed concurrently with the transistor MTCK2 illustrated in FIG. 13A to FIG. 13C. The transistor MTCK1 illustrated in FIG. 31A to FIG. 31D is a variation of the transistor MTCK illustrated in FIG. 12A to FIG. 12C and has a structure in which the insulator GI2 as the gate insulating film is not provided; thus, the gate insulating film has a smaller thickness than that of the gate insulating film of the transistor MTCK2. Thus, it can be said that the transistor MTCK1 is a transistor with a high driving frequency. A transistor MTCK3 is a variation of the transistor MTCK2 illustrated in FIG. 13A to FIG. 13C and includes the insulator GI1 and the insulator GI4; thus, the gate insulating film has a larger thickness than that of the transistor MTCK2. Thus, it can be said that the transistor MTCK3 has high resistance to voltages.

Like in the manufacturing process of the transistor MTCK2, for example, the conductor ME3 is not formed in a method for manufacturing the transistor MTCK3 illustrated in FIG. 31A to FIG. 31C, and the insulator IS3 is formed over the insulator GI1. After that, an opening is formed in a region of the insulator IS3 overlapping with the conductor ME1 and the semiconductor SC1, and the insulator GI4 and the conductor ME4 are formed in this order in the opening. Then, planarization treatment such as a CMP method is performed and polishing is performed until the insulator IS3 is exposed. Through the process, the transistor MTCK3 can be obtained.

Unlike in the manufacturing process of the transistor MTCK, the insulator GI2 is not formed in a method for manufacturing the transistor MTCK1 illustrated in FIG. 31A to FIG. 31D, and the conductor ME3 is formed over the insulator GI1, whereby the transistor MTCK1 can be obtained.

The insulating film GI4 is an insulator functioning as part of the gate insulating film of the transistor MTCK3. For the insulating film GI4, any of the materials usable for the insulator GI1 or the insulator GI2 can be used. Since the insulator GI4 is formed on the side surface of the opening in the insulator IS3, an ALD method achieving high coverage is preferably used for the formation of the insulator GI4.

The insulator GI4 functions as a film that prevents diffusion of impurities such as oxygen contained in the insulator IS3 into the conductor ME4 and oxidation of the conductor ME4, for example. That is, the insulator GI4 functions as a barrier insulating film. Note that in the case where it is not necessary to prevent the diffusion of impurities from the insulator IS3 into the conductor ME4, the insulator GI4 is not necessarily provided in the transistor MTCK3.

The conductor ME4 is a conductor functioning as a gate electrode of the transistor MTCK3. Thus, for the conductor ME4, any of the materials usable for the conductor ME3 can be used, for example.

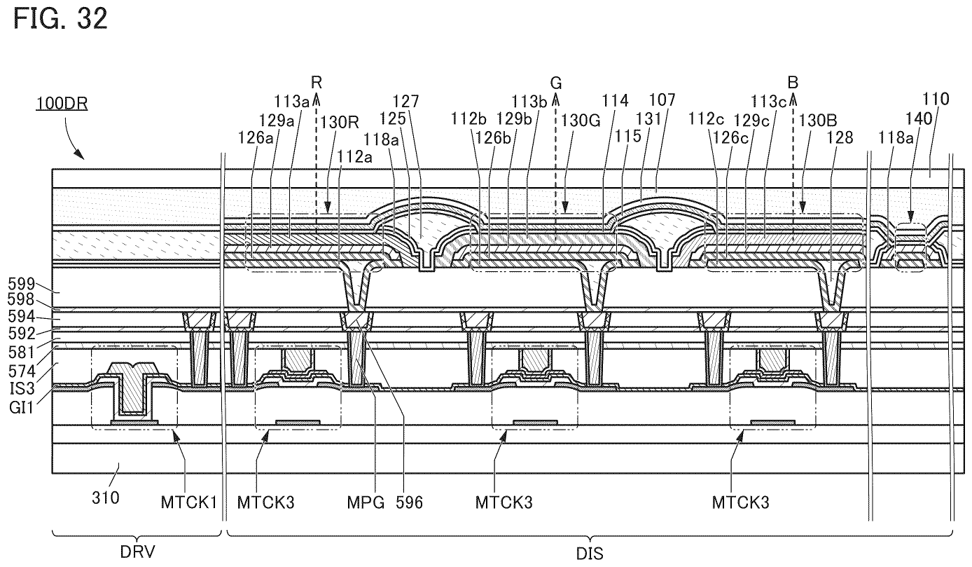

FIG. 32 illustrates a structure example different from that of the semiconductor device 100A in FIG. 24. A semiconductor device 100DR illustrated in FIG. 32 is a variation of the semiconductor device 100A and is different from the semiconductor device 100A in the structure of a transistor provided over the substrate 310. The semiconductor device 100DR has a structure provided with a pixel circuit, a driver circuit, and the like over the substrate 310. FIG. 32 illustrates a region DRV provided with the driver circuit and a region DIS provided with the pixel circuit, which are in the semiconductor device 100DR.

In the semiconductor device 100DR in FIG. 32, the transistor MTCK1 and the transistor MTCK3 described with reference to FIG. 31A to FIG. 31D are formed over the substrate 310.

For the light-emitting devices 130 (the light-emitting device 130R, the light-emitting device 130G, and the light-emitting device 130B in FIG. 32) above the transistor MTCK1 and the transistor MTCK3, the description of the light-emitting devices 130 in FIG. 24 can be referred to.

The insulator 574 is formed over the transistor MTCK1 and the transistor MTCK3, and the insulator 581 is formed over the insulator 574. The insulator IS3, the insulator 574, and the insulator 581 has an opening where the conductor MPG is embedded. Note that the insulator 574 and the insulator 581 are described later. For the conductor MPG, the description of the conductor MPG in FIG. 24 can be referred to.

The insulator 592, the insulator 594, and the conductor 596 are formed over the insulator 581 and the conductor MPG. For the insulator 592, the insulator 594, and the conductor 596, the description of the insulator 592, the insulator 594, and the conductor 596 in FIG. 24 can be referred to.

For the description of the light-emitting device 130 and the like over the insulator 594 and the conductor 596, the description of the semiconductor device 100A in FIG. 24 can be referred to.

In the structure illustrated in FIG. 32, the region DRV where the driver circuit is provided and the region DIS where the pixel circuit is provided can be arranged in the same element layer. Note that in the case where the driver circuit 11GD is provided in the element layer 30_1 or the element layer 30_2, the driver circuit 11GD and the pixel circuit PX are preferably provided in the same layer.

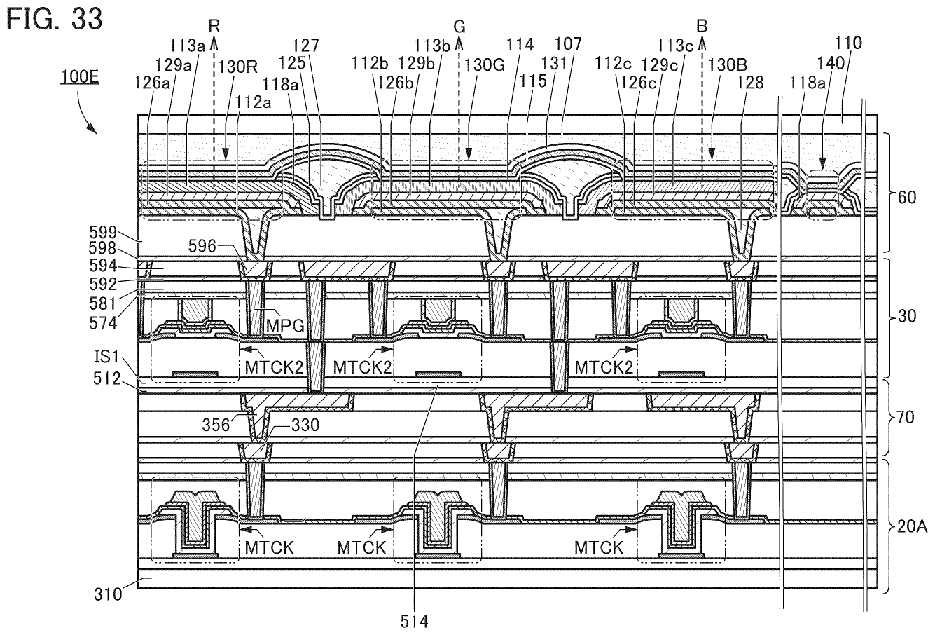

The structure of the transistor 300d in the semiconductor device 100B in FIG. 26 may be modified into the structure of the transistor MTCK, for example. A semiconductor device 100E illustrated in FIG. 33 is a variation of the semiconductor device 100B in FIG. 26. The element layer 20A of the semiconductor device 100E has a structure including the transistor MTCK.

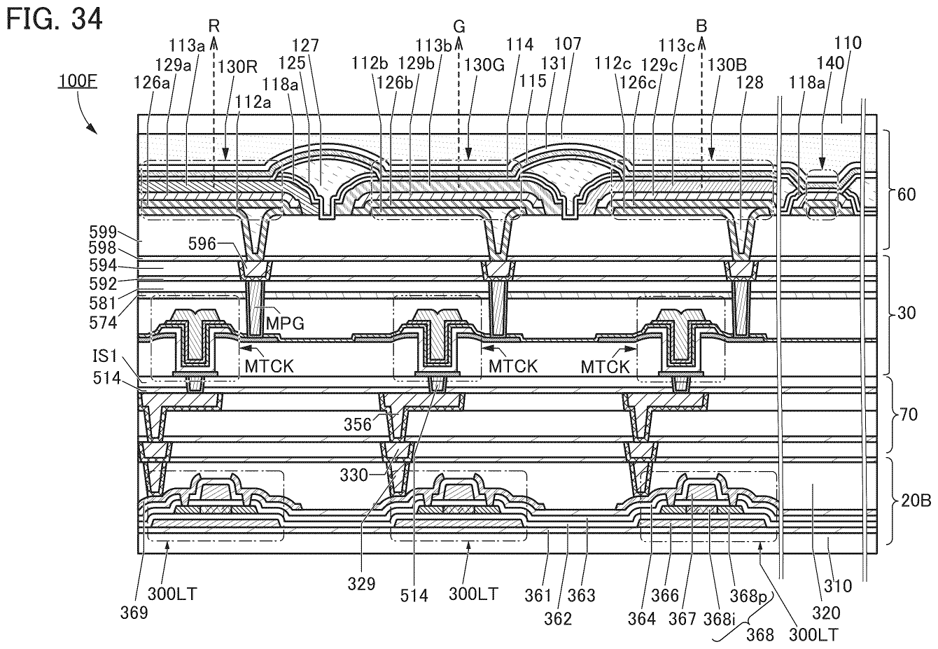

The transistor 300d in the semiconductor device 100A in FIG. 24 may be a transistor containing low-temperature polysilicon in its channel formation region (hereinafter referred to as an LTPS transistor), for example. A semiconductor device 100F illustrated in FIG. 34 is a variation of the semiconductor device 100A in FIG. 24. An element layer 20B of the semiconductor device 100F has a structure of a transistor 300LT that is an LTPS transistor.

The transistor 300LT is provided over the substrate 310. The transistor 300LT includes an insulator 361, an insulator 362, an insulator 363, an insulator 364, a conductor 366, a conductor 367, a low-resistance region 368p, a semiconductor region 368i, and a conductor 369. Here, a plurality of layers obtained by processing the same conductive film are shown with the same hatching pattern. In this specification and the like, the low-resistance region 368p and the semiconductor region 368i are collectively referred to as a semiconductor layer 368. In particular, when, for example, low-temperature polysilicon is used as a semiconductor material contained in the semiconductor layer 368, the transistor 300LT can be an LTPS transistor. The LTPS transistor has high field-effect mobility and excellent frequency characteristics.

In FIG. 34, the conductor 367 functions as a first gate (sometimes referred to as one of a gate and a back gate) of the transistor 300LT. The conductor 366 functions as a second gate (sometimes referred to as the other of the gate and the back gate) of the transistor 300LT. One of the pair of low-resistance regions 368p in the semiconductor layer 368 serves as one of a source and a drain of the transistor 300LT, and the other of the pair of low-resistance regions 368p in the semiconductor layer 368 serves as the other of the source and the drain of the transistor 300LT. The insulator 363 functions as a first gate insulating film in the transistor 300LT, and the insulator 362 functions as a second gate insulating film in the transistor 300LT.

In FIG. 34, the insulator 361 is formed over the substrate 310. The conductor 366 is formed in a region over the insulator 361. The insulator 362 is formed to cover the insulator 361 and the conductor 366. The semiconductor layer 368 is formed in a region overlapping with the conductor 366 and the insulator 362 and being over the insulator 362. The insulator 363 is formed to cover the insulator 362 and the semiconductor layer 368. The conductor 367 is formed in a region overlapping with the conductor 366, the insulator 362, the semiconductor layer 368, and the insulator 363 and being over the insulator 363. The insulator 364 is formed to cover the insulator 363 and the conductor 367. An opening portion is formed in the insulator 363 and the insulator 364 in regions overlapping with the low-resistance region 368p, and the conductor 369 is formed over the insulator 364 to fill the opening portion.

For the insulator 361, the insulator 362, the insulator 363, and the insulator 364, one or more selected from silicon oxide, silicon oxynitride, silicon nitride oxide, silicon nitride, aluminum oxide, aluminum oxynitride, aluminum nitride oxide, or aluminum nitride may be used.

In particular, a barrier insulating film that inhibits diffusion of impurities (e.g., a metal ion, a metal atom, an oxygen atom, an oxygen molecule, a hydrogen atom, a hydrogen molecule, and a water molecule) from a region below the insulator 361 (e.g., the substrate 310) is preferably used as the insulator 361.

The low-resistance region 368p is a region containing an impurity element. For example, in the case where the transistor 300LT is an n-channel transistor, phosphorus or arsenic is added to the low-resistance region 368p. In contrast, in the case where the transistor 300LT is a p-channel transistor, boron or aluminum is added to the low-resistance region 368p. In addition, in order to control the threshold voltage of the transistor 300, the above-described impurity may be added to the semiconductor region 368i.

Note that the transistor 300LT may be either a p-channel transistor or an n-channel transistor. Alternatively, a plurality of the transistors 300LT may be provided in the element layer 20B and both the p-channel transistor and the n-channel transistor may be used.

For the conductor 366 and the conductor 367, a metal such as aluminum, titanium, chromium, nickel, copper, yttrium, zirconium, molybdenum, silver, tantalum, or tungsten can be used, for example. Alternatively, for the conductor 366 and the conductor 367, an alloy containing two or more selected from the above metals as its main components can be used. Alternatively, for the conductor 366 and the conductor 367, a light-transmitting conductive material such as indium oxide, indium tin oxide (ITO), indium oxide containing tungsten, indium zinc oxide containing tungsten, indium oxide containing titanium, ITO containing titanium, indium zinc oxide, zinc oxide (ZnO), ZnO containing gallium, or indium tin oxide containing silicon can be used. Alternatively, for the conductor 366 and the conductor 367, silicide (e.g., nickel silicide) or a semiconductor whose resistance is lowered by, for example, containing an impurity element may (e.g., polycrystalline silicon or an oxide semiconductor) be used. Alternatively, for the conductor 366 and the conductor 367, a film containing graphene can be used. The film containing graphene can be formed, for example, by reducing a film containing graphene oxide. Alternatively, a conductive paste (e.g., a conductive paste containing silver, carbon, or copper) or a conductive polymer (e.g., polythiophene) may be used for forming the conductor 366 and the conductor 367. A conductive paste is preferable because it is inexpensive. A conductive polymer is preferable because it is easily applied. Alternatively, the conductor 366, the conductor 367, or both can have a single-layer structure containing any of the above materials or a structure (a stacked structure) in which two or more selected from the above materials overlap each other.

The conductor 369 functions as a wiring electrically connected to the low-resistance region 368p of the transistor 300LT. That is, the conductor 369 functions as a source or a drain of the transistor 300LT. Note that for the conductor 369, any of the materials usable for the conductor 366 and the conductor 367 can be used.

A conductor 329 functioning as a plug or a wiring is embedded in the insulator 320. Thus, the transistor 300LT and the transistor MTCK can be electrically connected to each other. For the conductor 329, a material usable for the conductor 330 can be used.

Note that the display apparatus of one embodiment of the present invention is not limited to the structures of the semiconductor device 100A in FIG. 24, the semiconductor device 100B in FIG. 26, the semiconductor device 100C in FIG. 27, the semiconductor device 100DR in FIG. 32, the semiconductor device 100E in FIG. 33, and the semiconductor device 100F in FIG. 34. The structure of the display apparatus of one embodiment of the present invention may be the structure of the display apparatus which is modified as appropriate.

For example, the display apparatus of one embodiment of the present invention may have a structure in which a plurality of substrates are bonded to each other. Specifically, for example, a structure may be employed in which a first substrate provided with the element layer 60 and the element layer 30 is bonded over a second substrate provided with the element layer 20 by Cu-to-Cu (copper-to-copper) direct bonding technique or the like (not illustrated).

### <Cross-Sectional Structure Example 2 of Semiconductor Device>

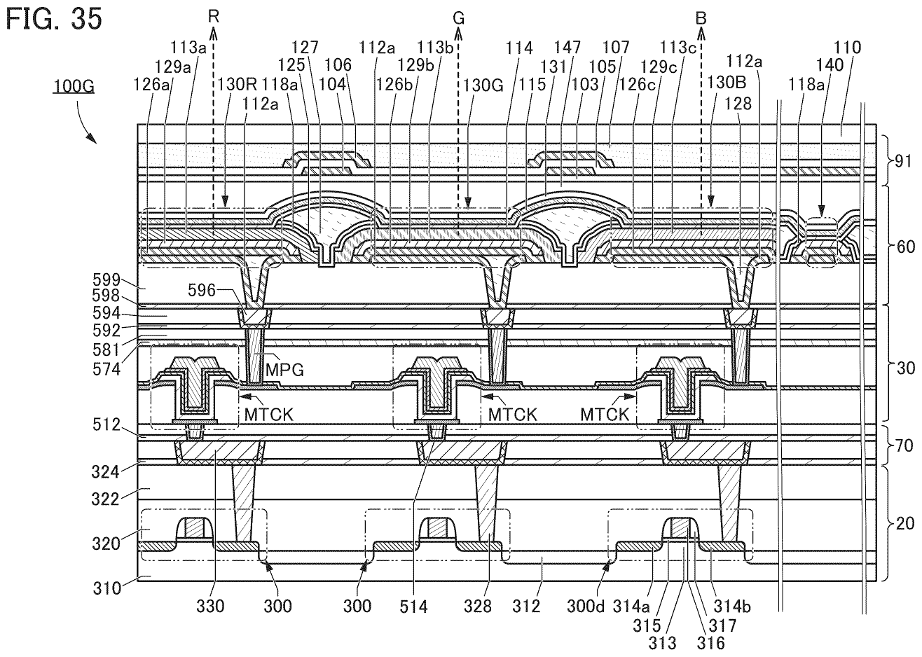

The semiconductor device 100A illustrated in FIG. 24 may be provided with a panel having a touch sensor function (sometimes referred to as a touch panel), for example. In a semiconductor device 100G illustrated in FIG. 35, a resin layer 147, an insulator 103, a conductor 104, an insulator 105, and a conductor 106 are formed in this order over the protective layer 131, for example. A layer 91 where the resin layer 147, the insulator 103, the conductor 104, the insulator 105, and the conductor 106 are formed is a functional layer functioning as a touch sensor.

The resin layer 147 preferably contains an organic insulating material. Examples of the organic insulating material include an acrylic resin, a polyimide resin, an epoxy resin, a polyamide resin, a polyimide-amide resin, a siloxane resin, a benzocyclobutene-based resin, a phenol resin, and precursors of these resins.

The insulator 103 preferably contains an inorganic insulating material. Examples of the inorganic insulating material include oxide and nitride such as silicon oxide, silicon oxynitride, silicon nitride oxide, silicon nitride, aluminum oxide, aluminum oxynitride, and hafnium oxide.

The conductor 104 and the conductor 106 function as electrodes of a touch sensor. In the case of using a mutual capacitive touch sensor, a pulse potential may be supplied to one of the conductor 104 and the conductor 106, and an analog-digital (A-D) converter circuit or a sensing circuit such as a sense amplifier may be electrically connected to the other of the conductor 104 and the conductor 106, for example. In that case, capacitance is formed between the conductor 104 and the conductor 106. When a finger or the like approaches the conductor 104 and the conductor 106, the capacitance changes (specifically, the capacitance is reduced). This change in the capacitance appears, when a pulse potential is supplied to one of the conductor 104 and the conductor 106, as a change in the amplitude of a signal that occurs in the other of the conductor 104 and the conductor 106. Accordingly, the touch and approach of the finger or the like can be sensed.

For the insulator 105, an inorganic insulating film or an organic insulating film can be used, for example. Specifically, for the insulator 105, a resin such as an acrylic resin or an epoxy resin can be used, for example. Alternatively, for the insulator 105, an inorganic insulating material such as silicon oxide, silicon oxynitride, silicon nitride oxide, silicon nitride, or aluminum oxide can be used, for example. Note that the insulator 105 may have either a single-layer structure or a stacked-layer structure.

Note that although FIG. 35 illustrates the structure in which the electrode of the touch sensor is provided above the light-emitting device 130, the touch sensor may be provided in the same layer as the light-emitting device 130 (not illustrated). For example, when formed concurrently with the light-emitting device 130, the touch sensor can be provided in the same layer as the light-emitting device 130.

### <Cross-Sectional Structure Example 3 of Semiconductor Device>

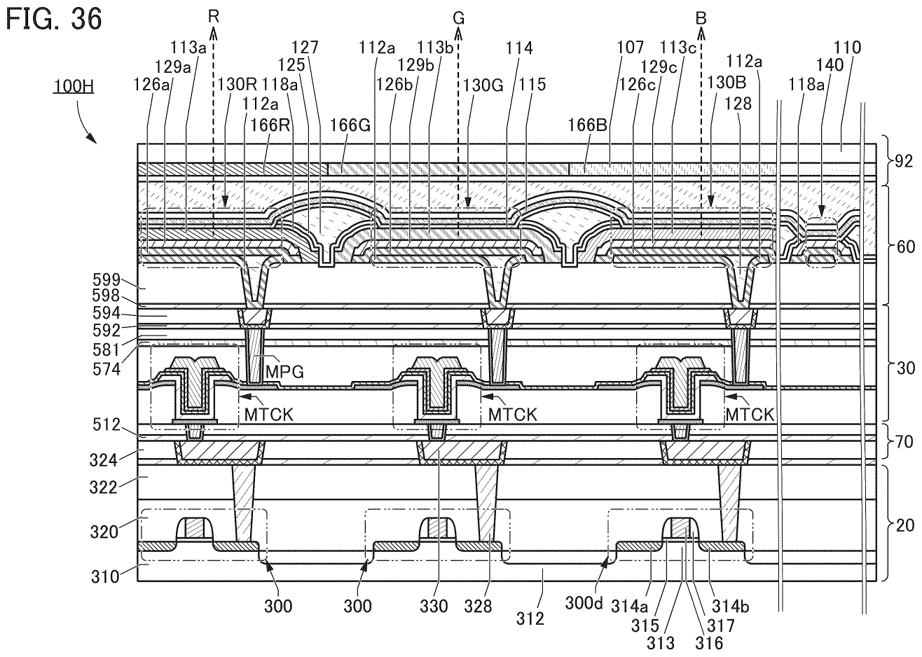

The semiconductor device 100A in FIG. 24 may include, for example, a coloring layer (a color filter) or the like. A semiconductor device 100H illustrated in FIG. 36 includes a coloring layer 166R, a coloring layer 166G, and a coloring layer 166B between the adhesive layer 107 and the substrate 110, for example. Note that the coloring layer 166R, the coloring layer 166G, and the coloring layer 166B can be formed on the substrate 110, for example. In the case where the light-emitting device 130R includes a light-emitting layer that emits red (R) light, the light-emitting device 130G includes a light-emitting layer that emits green (G) light, and the light-emitting device 130B includes a light-emitting layer that emits blue (B) light, the coloring layer 166R is a red coloring layer, the coloring layer 166G is a green coloring layer, and the coloring layer 166B is a blue coloring layer. A layer 92 where the coloring layer 166R, the coloring layer 166G, and the coloring layer 166B are formed is a functional layer functioning as a color filter.

Note that a black matrix (not illustrated) may be provided between the coloring layer 166R and the coloring layer 166G, between the coloring layer 166G and the coloring layer 166B, and between the coloring layer 166G and the coloring layer 166B. Providing a black matrix in the semiconductor device 100H can prevent light emitted from the light-emitting device from entering the coloring layer included in the adjacent pixel. This can enhance the display contrast, improving the display quality of the semiconductor device 100H.

When one of the above structure examples is applied to a display apparatus, the display apparatus having high screen resolution and high definition can be achieved in some cases. Specifically, for example, a display apparatus with a resolution of HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320) can be achieved in some cases. Furthermore, specifically, for example, a display apparatus with a definition greater than or equal to 100 ppi, greater than or equal to 300 ppi, greater than or equal to 500 ppi, greater than or equal to 1000 ppi, greater than or equal to 2000 ppi, greater than or equal to 3000 ppi, greater than or equal to 5000 ppi, or greater than or equal to 6000 ppi can be achieved in some cases.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For example, the configurations, structures, methods, and the like described in this embodiment can be used in an appropriate combination with any of the configurations, structures, methods, and the like described in the other embodiments and the like.

### Embodiment 6

In this embodiment, a display module that can be used for the electronic device of one embodiment of the present invention will be described.

### <Structure Example of Display Module>

First, a display module including a semiconductor device that can be used for the electronic device of one embodiment of the present invention will be described.

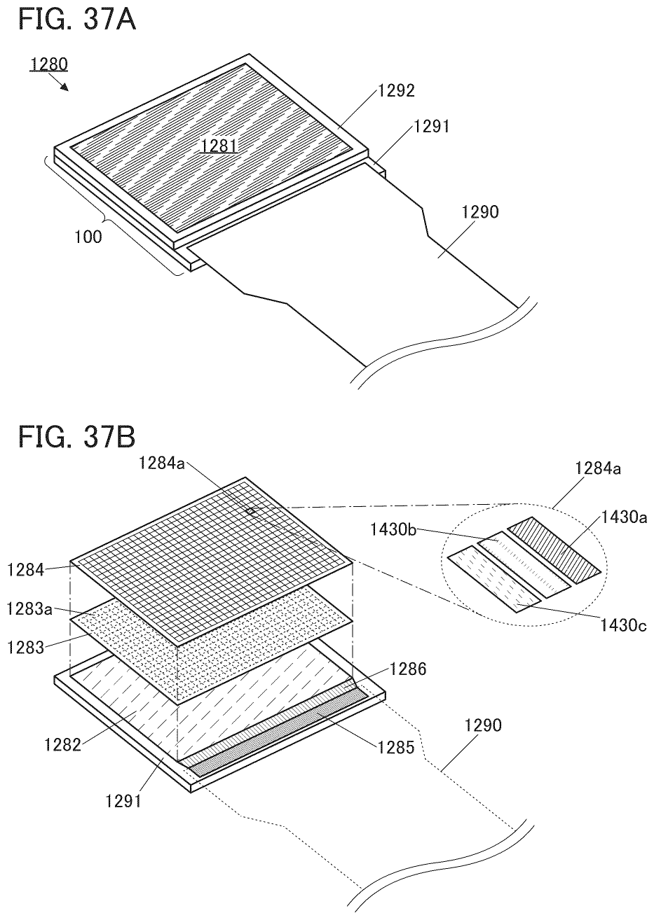

FIG. 37A is a perspective view of a display module 1280. The display module 1280 includes the semiconductor device 100 and an FPC 1290.

The display module 1280 includes a substrate 1291 and a substrate 1292. The display module 1280 includes a display portion 1281. The display portion 1281 is a region of the display module 1280 where an image is displayed, and is a region where light emitted from pixels provided in a pixel portion 1284 described later can be seen.

FIG. 37B is a perspective view schematically illustrating a structure on the substrate 1291 side. A circuit portion 1282, a pixel circuit portion 1283 over the circuit portion 1282, and the pixel portion 1284 over the pixel circuit portion 1283 are stacked over the substrate 1291. In addition, a terminal portion 1285 for connection to the FPC 1290 is provided in a portion not overlapping with the pixel portion 1284 over the substrate 1291. The terminal portion 1285 and the circuit portion 1282 are electrically connected to each other through a wiring portion 1286 formed of a plurality of wirings.

Note that the pixel portion 1284 and the pixel circuit portion 1283 correspond to the above-described structures provided in the element layer 30 and the element layer 60, for example. The circuit portion 1282 corresponds to the above-described structure provided in the element layer 20, for example.

The pixel portion 1284 includes a plurality of pixels 1284a arranged periodically. An enlarged view of one pixel 1284a is illustrated on the right side of FIG. 37B. The pixel 1284a includes a light-emitting device 1430a, a light-emitting device 1430b, and a light-emitting device 1430c that emit light of different colors. Note that the light-emitting device 1430a, the light-emitting device 1430b, and the light-emitting device 1430c correspond to the light-emitting device 130R, the light-emitting device 130G, and the light-emitting device 130B described above, for example. The above-described light-emitting devices may be arranged in a stripe pattern as illustrated in FIG. 37B. For example, various arrangements such as S-stripe arrangement, matrix arrangement, delta arrangement, Bayer arrangement, and PenTile arrangement can be employed.

The pixel circuit portion 1283 includes a plurality of pixel circuits 1283a arranged periodically.

One pixel circuit 1283a is a circuit that controls light emission from three light-emitting devices included in one pixel 1284a. One pixel circuit 1283a may be provided with three circuits each of which controls light emission from one light-emitting device. For example, the pixel circuit 1283a can include at least one selection transistor, one current control transistor (driving transistor), and a capacitor for one light-emitting device. In that case, a gate signal is input to a gate of the selection transistor, and a source signal is input to one of a source and a drain of the selection transistor. Thus, an active-matrix display apparatus is achieved.

The circuit portion 1282 includes a circuit for driving the pixel circuits 1283a in the pixel circuit portion 1283. For example, the circuit portion 1282 preferably includes one or both of a gate line driver circuit and a source line driver circuit. In addition, one or more selected from an arithmetic circuit, a memory circuit, and a power supply circuit may be included.

The FPC 1290 functions as a wiring for supplying a video signal or a power supply potential to the circuit portion 1282 from the outside. In addition, an IC may be mounted on the FPC 1290.

The display module 1280 can have a structure in which one or both of the pixel circuit portion 1283 and the circuit portion 1282 are stacked below the pixel portion 1284; thus, the aperture ratio (the effective display area ratio) of the display portion 1281 can be significantly high. For example, the aperture ratio of the display portion 1281 can be higher than or equal to 40% and lower than 100%, preferably higher than or equal to 50% and lower than or equal to 95%, further preferably higher than or equal to 60% and lower than or equal to 95%.

The display module 1280 can also be favorably used for an electronic device having a relatively small display portion. For example, the display module 1280 can be suitably used in a display portion of a wearable electronic device, such as a wristwatch.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For example, the configurations, structures, methods, and the like described in this embodiment can be used in an appropriate combination with any of the configurations, structures, methods, and the like described in the other embodiments and the like.

### Embodiment 7

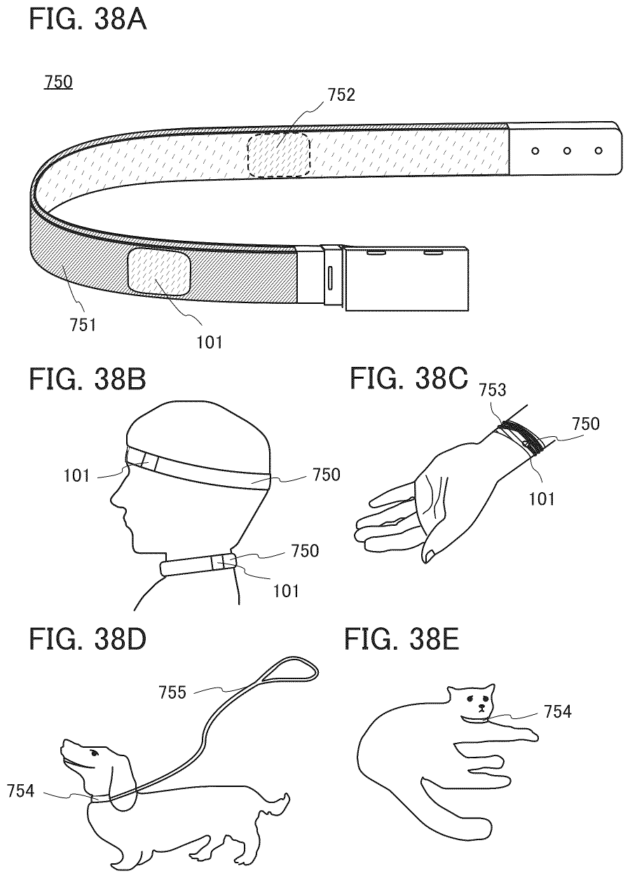

In this embodiment, electronic devices each including a display apparatus fabricated using one embodiment of the present invention will be described with reference to FIG. 38A to FIG. 38E. Electronic devices described in this embodiment as examples are each provided with a display apparatus of one embodiment of the present invention in a display portion. Thus, the electronic devices achieve high definition.

Examples of electronic devices including the display apparatus of one embodiment of the present invention include display apparatuses of televisions, monitors, and the like; lighting devices; desktop or laptop personal computers; word processors; image reproduction devices that reproduce still images or moving images stored in recording media such as DVD (Digital Versatile Disc); portable CD players; radios; tape recorders; headphone stereos; stereos; table clocks; wall clocks; cordless phone handsets; transceivers; mobile phones; car phones; portable game machines; tablet terminals; large-sized game machines such as pachinko machines; calculators; portable information terminals; electronic notebooks; e-book readers; electronic translators; audio input devices; video cameras; digital still cameras; electric shavers; high-frequency heating appliances such as microwave ovens; electric rice cookers; electric washing machines; electric vacuum cleaners; water heaters; electric fans; hair dryers; air-conditioning systems such as air conditioners, humidifiers, and dehumidifiers; dishwashers; dish dryers; clothes dryers; futon dryers; electric refrigerators; electric freezers; electric refrigerator-freezers; freezers for preserving DNA; flashlights; tools such as chain saws; smoke detectors; and medical equipment such as dialyzers. Other examples include industrial equipment such as guide lights, traffic lights, conveyor belts, elevators, escalators, industrial robots, power storage systems, and power storage devices for leveling the amount of power supply and smart grid.

In addition, moving objects and the like driven by electric motors using electric power from the power storage devices are also included in the category of electronic devices. Examples of the moving objects include electric vehicles (EVs), hybrid electric vehicles (HEVs) that include both an internal-combustion engine and a motor, plug-in hybrid electric vehicles (PHEVs), tracked vehicles in which caterpillar tracks are substituted for wheels of these vehicles, motorized bicycles including motor-assisted bicycles, motorcycles, electric wheelchairs, golf carts, boats, ships, submarines, helicopters, aircraft, rockets, artificial satellites, space probes, planetary probes, and spacecraft.

The electronic devices may include a sensor (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), for example.

The electronic device can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication mean, and a function of reading out a program or data stored in a recording medium.

FIG. 38A illustrates an example of a band-type information terminal. An information terminal 750 includes a housing 751, a semiconductor device 101, a sensor 752, and the like. The information terminal 750 may include a secondary battery, a display apparatus, and the like inside. The semiconductor device of one embodiment of the present invention is used for the information terminal 750, whereby the information terminal 750 can function as a shock-resistant IoT device that is sufficiently reduced in size and power consumption.

FIG. 38B is a diagram illustrating an example of a usage mode of the information terminal 750 illustrated in FIG. 38A. The information terminal 750 can be used while being wound around a user's head, neck, or the like. For example, a structure can be employed in which a sensor (not illustrated) is provided inside the band-type information terminal 750 and information obtained by the sensor is processed with a semiconductor device. With this structure, convenience of a shock-resistant IoT device that is sufficiently reduced in size and power consumption can be improved.

FIG. 38C is a diagram illustrating another example of a usage mode of the information terminal 750 illustrated in FIG. 38A. The information terminal 750 can be used while being wound around a user's arm portion or the like. For example, a structure can be employed in which a sensor (not illustrated) is provided inside the band-type information terminal 750, information obtained from the sensor is processed with a semiconductor device, and obtained data is transmitted and received to and from an external communication device through an antenna 753 or the like provided in the band-type information terminal 750. With this structure, convenience of a shock-resistant IoT device that is sufficiently reduced in size and power consumption can be improved.

The usage mode of the electronic device of one embodiment of the present invention described with reference to FIG. 38B and FIG. 38C may employ a structure in which the electronic device is attached to an animal such as a dog or a cat. For example, in FIG. 38D and FIG. 38E, a dog and a cat to which the information terminal 750 is attached are illustrated. Like the information terminal 750 described with reference to FIG. 38B and FIG. 38C, collars 754 and a lead 755 illustrated in FIG. 38D and FIG. 38E include a sensor, the semiconductor device 101, and the like. With this structure, convenience of a shock-resistant IoT device that is sufficiently reduced in size and power consumption can be improved.

One embodiment of the present invention can be applied to a display panel of an electronic device or the like including a display portion.

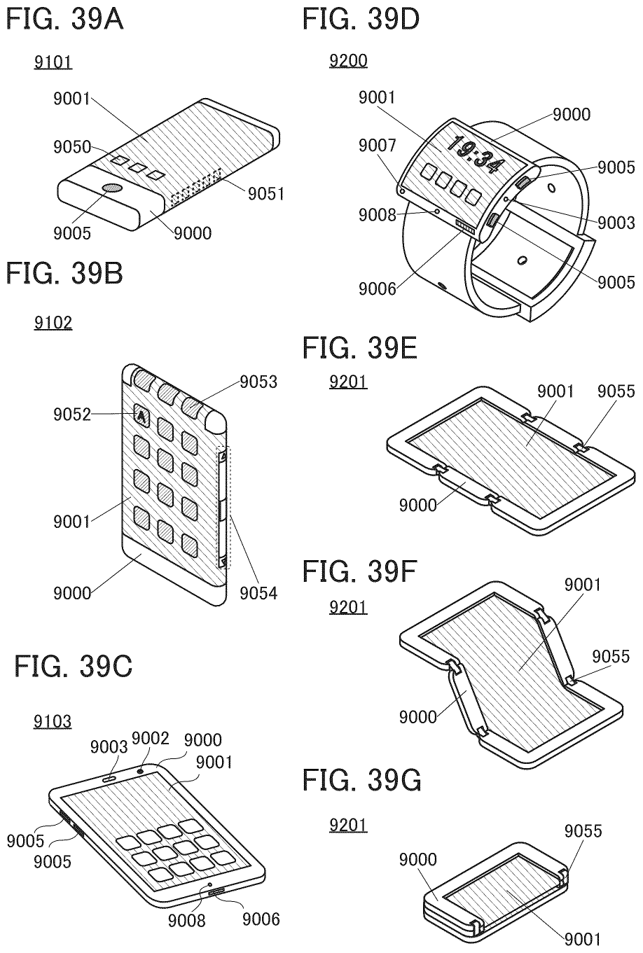

Electronic devices illustrated in FIG. 39A to FIG. 39G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 39A to FIG. 39G have a variety of functions. For example, the electronic devices can have a function of displaying a variety of information (a still image, a moving image, a text image, and the like) on the display portion, a touch panel function, a function of displaying a calendar, date, time, or the like, a function of controlling processing with use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may each be provided with a camera or the like and have a function of taking a still image or a moving image, a function of storing the taken image in a storage medium (an external storage medium or a storage medium incorporated in the camera), a function of displaying the taken image on the display portion, or the like.

The electronic devices illustrated in FIG. 39A to FIG. 39G are described in detail below.

FIG. 39A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 39A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 39B is a perspective view illustrating a portable information terminal 9102. The portable information terminal 9102 has a function of displaying information on three or more surfaces of the display portion 9001. Here, information 9052, information 9053, and information 9054 are displayed on different surfaces. For example, a user can check the information 9053 displayed such that it can be seen from above the portable information terminal 9102, with the portable information terminal 9102 put in a breast pocket of their clothes. The user can see the display without taking out the portable information terminal 9102 from the pocket and decide whether to answer the call, for example.

FIG. 39C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 39D is a perspective view illustrating a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 39E to FIG. 39G are perspective views illustrating a foldable portable information terminal 9201. FIG. 39E is a perspective view of an opened state of the portable information terminal 9201, FIG. 39G is a perspective view of a folded state thereof, and FIG. 39F is a perspective view of a state in the middle of change from one of FIG. 39E and FIG. 39G to the other. The portable information terminal 9201 is highly portable when folded. When the portable information terminal 9201 is opened, a seamless large display region is highly browsable.

The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

The structures, configurations, methods, and the like described in this embodiment can be used in combination as appropriate with the structures, configurations, methods, and the like described in the other embodiments.

(Supplementary Notes on the Description in this Specification and the Like)

The description of the above embodiments and each configuration in the embodiments are noted below.

One embodiment of the present invention can be constituted by combining, as appropriate, the configuration described in each embodiment with the configurations described in the other embodiments. In addition, in the case where a plurality of configuration examples are described in one embodiment, the configuration examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, content described in the embodiment is content described using a variety of diagrams or content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In addition, in this specification and the like, components are classified on the basis of the functions, and shown as blocks independent of one another in block diagrams. However, in an actual circuit or the like, it is difficult to separate components on the basis of the functions, and there is such a case where one circuit is associated with a plurality of functions or a case where a plurality of circuits are associated with one function. Therefore, blocks in the block diagrams are not limited by the components described in this specification, and the description can be changed appropriately depending on the situation.

Furthermore, in the drawings, the size, the layer thickness, or the region is shown with given magnitude for description convenience. Therefore, the size, the layer thickness, or the region is not limited to the illustrated scale. Note that the drawings are schematically shown for clarity, and embodiments of the present invention are not limited to shapes, values or the like shown in the drawings. For example, variation in signal, voltage, or current due to noise, variation in signal, voltage, or current due to difference in timing, or the like can be included.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In addition, in this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

Furthermore, in this specification and the like, “voltage” and “potential” can be interchanged with each other as appropriate. The voltage refers to a potential difference from a reference potential, and when the reference potential is a ground voltage, for example, the voltage can be rephrased into the potential. The ground potential does not necessarily mean 0 V. Note that potentials are relative values, and a potential applied to a wiring or the like is sometimes changed depending on the reference potential.

Note that in this specification and the like, the terms such as “film” and “layer” can be interchanged with each other depending on the case or according to circumstances. For example, the term “conductive layer” can be replaced with the term “conductive film” in some cases. As another example, the term “insulating film” can be changed into the term “insulating layer” in some cases.

In this specification and the like, a switch has a function of controlling whether current flows or not by being in a conduction state (an ON state) or a non-conduction state (an OFF state). Alternatively, a switch has a function of selecting and changing a current path.

In this specification and the like, channel length refers to, for example, the distance between a source and a drain in a region where a semiconductor (or a portion where current flows in a semiconductor when a transistor is in an ON state) and a gate overlap each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an ON state) and a gate electrode overlap each other or a region where a channel is formed.

In this specification and the like, the expression “A and B are connected” means the case where A and B are electrically connected as well as the case where A and B are directly connected. Here, the expression “A and B are electrically connected” means the case where electric signals can be transmitted and received between A and B when an object having any electric action is present between A and B.

### REFERENCE NUMERALS

10: arithmetic circuit, 11: driver circuit, 15: sensor circuit, 16: communication circuit, 17: control circuit, 18: input/output circuit, 19: terminal portion, 20: element layer, 30: element layer, 31: display portion, 32: storage portion, 40: sealing substrate, 50: region, 51: scan flip-flop, 52: backup circuit, 60: element layer, 70: wiring layer, 80: flip-flop, 100: semiconductor device, 1000: electronic device

1. An electronic device comprising:
a semiconductor device,
wherein the semiconductor device has a structure where a first element layer, a second element layer, and a third element layer are stacked,
wherein the first element layer comprises a first transistor comprising a semiconductor layer comprising silicon in a channel formation region,
wherein the second element layer comprises a second transistor comprising a semiconductor layer comprising a metal oxide in a channel formation region,
wherein the third element layer comprises a light-emitting device,
wherein the first element layer comprises an arithmetic circuit comprising a scan flip-flop, and
wherein the second element layer comprises a backup circuit electrically connected to the scan flip-flop and a pixel circuit electrically connected to the light-emitting device.

2. An electronic device comprising:
a semiconductor device,
wherein the semiconductor device has a structure where a first element layer, a second element layer, and a third element layer are stacked,
wherein the first element layer comprises a first transistor comprising a semiconductor layer comprising silicon in a channel formation region,
wherein the second element layer comprises a second transistor comprising a semiconductor layer comprising a metal oxide in a channel formation region,
wherein the third element layer comprises a light-emitting device,
wherein the first element layer comprises an arithmetic circuit comprising a scan flip-flop and a first driver circuit configured to drive a pixel circuit electrically connected to the light-emitting device, and
wherein the second element layer comprises a backup circuit electrically connected to the scan flip-flop, the pixel circuit, and a second diver circuit configured to drive the pixel circuit.

3. An electronic device comprising a semiconductor device,
wherein the semiconductor device has a structure where a first element layer, a second element layer, a third element layer, and a fourth element layer are stacked,
wherein the first element layer comprises a first transistor comprising a semiconductor layer comprising silicon in a channel formation region,
wherein the second element layer comprises a second transistor comprising a first semiconductor layer comprising a metal oxide in a channel formation region,
wherein the third element layer comprises a third transistor comprising a second semiconductor layer comprising a metal oxide in a channel formation region,
wherein the fourth element layer comprises a light-emitting device,
wherein the first element layer comprises an arithmetic circuit comprising a scan flip-flop and a first driver circuit configured to drive a pixel circuit electrically connected to the light-emitting device,
wherein the second element layer comprises a backup circuit electrically connected to the scan flip-flop and a second driver circuit for driving configured to drive the pixel circuit, and
wherein the third element layer comprises the pixel circuit.

4. The electronic device according to claim 3, wherein the second transistor and the third transistor have different shapes from each other.

5. The electronic device according to claim 3, wherein the second transistor and the third transistor have different channel lengths and different channel widths from each other.

6. The electronic device according to claim 1, wherein the backup circuit is configured to retain data stored in the scan flip-flop in a state where supply of a power supply voltage is stopped when the arithmetic circuit is in a non-activated state.

7. The electronic device according to claim 1, wherein the metal oxide comprises In, Ga, and Zn.

8. The electronic device according to claim 2, wherein the backup circuit is configured to retain data stored in the scan flip-flop in a state where supply of a power supply voltage is stopped when the arithmetic circuit is in a non-activated state.

9. The electronic device according to claim 2, wherein the metal oxide comprises In, Ga, and Zn.

10. The electronic device according to claim 3, wherein the backup circuit is configured to retain data stored in the scan flip-flop in a state where supply of a power supply voltage is stopped when the arithmetic circuit is in a non-activated state.

11. The electronic device according to claim 3, wherein the metal oxide comprises In, Ga, and Zn.
